(19) United States
(12) Patent Application Publication
(10) Pub. No.: US 2006/0248427 A1
(43) Pub. Date: Nov. 2, 2006

(54) Optical disk device and data randomizing method for optical disk drive

(76) Inventors: Yukari Katayama, Chigasaki (JP); Takeshi Maeda, Kokubunji (JP); Harukazu Miyamoto, Higashimurayama (JP); Takushi Nishiya, Yawata (JP); Takatoshi Kato, Yokohama (JP); Shigeki Taira, Yokohama (JP); Osamu Kawamae, Yokohama (JP); Taku Hoshizawa, Kawasaki (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/455,630

(22) Filed: Jun. 20, 2006

Related U.S. Application Data
(62) Division of application No. 10/316,875, filed on Dec. 12, 2002.

(30) Foreign Application Priority Data
Dec. 20, 2001 (JP) 2001-387285
Dec. 13, 2001 (JP) 2001-380332
Dec. 13, 2001 (JP) 2001-380331

(51) Int. Cl. H03M 13/00; H04L 1/00; G08C 25/00; G06F 11/00; G06F 11/30

(52) U.S. Cl. 714/746

(57) ABSTRACT

A random seed scramble for preventing the deterioration of a medium is applied to the next generation optical disk. A seed is stored to a BIS area. ID or an EDC is checked to hold interchangeability before and after scramble release. When no error is generated in data before the scramble release, it is recognized as an unscrambled disk. In contrast to this, when no error is generated in data after the scramble release, it is recognized as a scrambled disk. An information storing area showing an area to be rewritten by performing the scramble and an area to be rewritten without performing the scramble is arranged.

### CROSS-REFERENCE TO RELATED APPLICATION

This application is a Divisional application of application Ser. No. 10/316,875, filed Dec. 12, 2002, which claims priority from Japanese patent applications JP 2001-380331 and 2001-380332, both filed on Dec. 13, 2001, and JP 2001-387285, filed on Dec. 20, 2001, the contents of which are incorporated herein by reference in their entirety.

### BACKGROUND OF THE INVENTION

The present invention relates to a scramble coding-decoding method to be executed in a memory device (particularly an optical disk device such as a DVD, etc.) for recording data to a memory medium (particularly DVD) such as an optical disk, etc. able to rewrite (overwrite and overlap-write) the data, and regenerating the data from such a memory medium, and its circuit. Further, the present invention relates to a recording-regenerating method having such a scramble coding-decoding method or its circuit, and its device (particularly an optical disk device such as a DVD, etc.). Further, the present invention relates to a memory medium (particularly an optical disk medium such as a DVD, etc.) for storing data recorded by such a recording method or its device.

In a memory device using a rewritable phase changing type optical disk such as a DVD-RAM, data are generally written onto a track of the disk by generating a recording mark by the power of light. Concretely, the data can be recorded by changing a memory layer to one of two states, i.e., a crystal state (recording mark) and a noncrystal state (a portion having no mark) by irradiating the light beam at a high power level sufficient to change the state of the memory layer (film) to the memory medium while this light beam is controlled. Since light reflectivities in the crystal state and the noncrystal state are different from each other, the memory device can regenerate the recorded data by irradiating the light beam to the memory medium and detecting reflected light of the light beam. The light beam is a sufficiently low power level so that no memory device changes the state of the memory layer

When the same data are recorded many times to the same place of the memory medium by many rewritings, the light beam at the high power level is irradiated to this place in the same situation every time. This causes physical deviation of the memory layer such as the flowage of a substance constituting the memory layer, a change in film thickness, etc. The physical deviation of the memory layer greatly changes its light reflectivity. Therefore, it is difficult to regenerate data with sufficient reliability in the memory device. As this result, it is necessary to limit the number of rewritable times of the memory medium to a small value.

There is a technique disclosed in Japanese Patent Laid-Open No. 150725/1991 as the technique for solving this problem. In this technique, when data are recorded in the memory device, the data are recorded by shifting the recording place of the data on the memory medium within a predetermined range. Thus, even when the same data are recorded, it is possible to avoid the same data from being recorded in the same place at any time so that the number of recording times of the same data to the same place can be reduced. As this result, the number of rewritable times of the memory medium can be increased. Further, in the DVD-RAM, a so-called groove is formed on the disk, and data density is increased by writing the data to both the groove and a portion (land) constituting no groove.

In the recording regenerator using the memory medium of a disk type, control for accurately locating a head onto the track is called tracking. In the DVD-RAM, the land and the groove are formed by making a very small vibration called a wobble, and the tracking is performed by utilizing this wobble. However, when the same data are written to an adjacent track, a tracking signal becomes weak. Therefore, a problem exists in that the tracking is easily missed. In the DVD for treating an image, a voice, etc., the same data such as an unsound portion, etc., are often written in large quantities. To solve this problem various devices were made so as not to set the writing data of the adjacent track to the same even when the same data were written in large quantities by a user.

For example, as shown in Japanese Patent Laid-Open No. 274885/1994, there is a method for changing the start of a sector every one track as to whether the sector is started from a mark or a portion constituting no mark. Further, as described in STANDARD-ECMA-272, the DVD-RAM adopts a method in which an Maximum length sequence (random series) is generated with ID information of each frame as an initial value (seed), and is added to user data and is then written to the disk, etc. Such randomization of the data is generally called scramble.

On the other hand, in the field of optical communication, a method called a guided scramble was used to make a run length limit code having flat frequency characteristics and suitable for the optical communication. In this method, data of many kinds are made by adding data having a sufficiently large space to the head of data desirous to make the run length limit code, and one of data close to required characteristics is selected from data made by randomizing these data of many kinds. For example, such a technique is described in detail in “CODES FOR MASS DATA STORAGE SYSTEMS” K. A. S. IMMINK, SHANNON FOUNDATION PUBLISHER, 1999. Further, such a technique is described in “POLYNOMIALS FOR GUIDED SCRAMBLING LINE CODE”, IEEE JOURNAL ON SELECTED AREAS IN COMMUNICATIONS, Vol. 13, NO. 3, APRIL, 1995, etc. in theses.

Further, a high density optical disk using a blue purple laser is proposed in recent years. For example, such a technique is described in “OPTICAL DISC SYSTEM FOR DIGITAL VIDEO RECORDING”, TATSUYA NARAHARA JPN. J. APPL. PHYS. VOL. 39 (2000) PP. 912-919 PART 1, NO. 2B, FEBRUARY 2000, etc.

FIG. 10 shows a format method of the optical disk described in this thesis. User data are changed to an error correcting code in a unit of 64 K bytes, and are written onto a disk medium. In the optical disk, data are read and written in a unit of 2048 bytes in the DVD-RAM, etc. in the present situation, and this is called a logic sector. An error check code EDC of 4 bytes is added to the inputted user data so that the user data become 2052 bytes. This logic sectors added with the EDC thereto are collected into groups of 8 sectors, and is divided into 76 pieces of 216 bytes each. Each piece is coded to [248, 216, 33] Reed Solomon code, and is collected as 8 sectors and is arranged in an area (38 bytes×496 bytes) of (A) 1001 shown by half-tone dot meshing in FIG. 10. This area of 38 bytes×496 bytes is called LDC. Similarly, each piece is collected as 8 sectors each, and the areas of (B) 1002, (C) 1003 and (D) 1004 are buried by the logic sectors. Hereinafter, the Reed Solomon code is called an RS code.

Next, addresses, copy protection information, substitution sector information, etc. of 8×4=32 sectors are divided of 30 bytes each, and are changed to twenty-four [62, 30, 33] RS codes. These RS codes are written to three BIS areas 1005 to 1007 in FIG. 10 of 8 RS codes each. A synchronous signal 1008 is added to this format, and data are taken out of this format in the transversal direction and are written onto the optical disk medium as shown by an arrow 1009. At a data regenerating time, the data read from the optical disk medium are arranged in the order shown by the arrow 1009, and are also arranged so as to form the format shown in FIG. 10, and error correction processing, etc. are then performed.

In the above technique (Japanese Patent Laid-Open No. 150725/1991), while the recording place of data on the memory medium is shifted within a predetermined range and the data of an object on the memory medium are rewritten, these rewritten data are set to be not overlapped with data existing before and after these rewritten data on the memory medium. Therefore, at least an area of the above predetermined range is required. This causes the problem of a reduction in format efficiency of the memory device and the memory medium, in its turn, a reduction in memory capacity.

Further, when the number of rewritable times of the memory medium is further increased by applying the above technique, it is considered to increase the above predetermined range and a shifting kind. However, if the above predetermined range is increased, the format efficiency of the memory device and the memory medium is reduced. For example, there are four shifting kinds by shifting channel data of two bits each (200 nm in the case of e.g., a channel data bit pitch 100 nm) from 0 bit (0 nm in this case) of the channel data on the memory medium to 6 bits (600 nm in this case). The condition of these four shifting kinds is set to a condition of 8 shifting kinds in which the channel data are shifted of one bit each (100 nm) from 0 bit (0 nm) to 7 bits (700 nm). Thus, the shifting kinds are doubled so that the number of rewritable times of the memory medium is further increased on trial. However, the predetermined range is changed from 7 bits (0 to 6 bits) to 8 bits (0 to 7 bits) and is not greatly changed. Therefore, it is doubtful whether a notable improvement is obtained.

### SUMMARY OF THE INVENTION

Since the optical disk is a commutative medium, interchangeability is important. When a new technique is introduced, it is necessary that reading and writing operations can be easily performed even when the conventional optical disk medium introducing no new technique thereto is used.

A main object of the present invention is to provide a scramble coding-decoding method to be executed in a memory device for recording data to a rewritable memory medium and regenerating the data from this memory medium, and its circuit. In the scramble coding-decoding method and its circuit, the number of rewritable times of the memory medium can be increased by a slight reduction in format efficiency. Even when there is an error in the data of an object in descramble, this error is diffused to only limited slight data by the descramble so that the scramble coding-decoding method and its circuit are cheaply provided in view of the calculating amount and the circuit scale in execution. Another main object of the present invention is to provide a recording-regenerating method and its device having such a scramble coding-decoding method or its circuit. A still another main object of the present invention is to provide a memory medium for storing data recorded by such a recording method or its device.

In the scramble method in the present invention, data are scrambled by using an arbitrary seed to solve the above problem. Arbitrary seed data for performing randomization are preferably added to the original data to be recorded onto the disk. Additional information such as a sector number, copy protection, etc. is more preferably added to the original data to be recorded onto the disk, and an address is together scrambled. Thus, if the seed is different even in the same data, the data after the scramble are different. Namely, even when the same data should be recorded, the data actually recorded are different when the seed is different. Accordingly, the number of rewritable times of the memory medium can be increased. The randomized data, the additional information and the seed data are changed to different error correcting codes. Since the size of the data is increased by the seed by the scramble, format efficiency is reduced, but this reduction is slight.

When the present invention is used in the next generation high density optical disk introduced in the prior art, data are divisionally stored to an LDC area and the additional information and the seed are divisionally stored to a BIS area. Further, in accordance with the scramble method of the present invention, the randomized data of 1 bit are determined by a calculation using the original data of 1 bit or the seed data and the past randomized data of plural bits. In accordance with another mode of the present invention, a descramble method requiring no seed data is provided. Concretely, the present invention is characterized in that randomization release data of 1 bit are determined by the calculation using the randomized data of plural bits at a data regenerating time. In accordance with another mode of the present invention, a descramble method requiring no seed data is provided. Concretely, the present invention is characterized in that the randomization release data of 1 bit are determined by the calculation using the randomized data of plural bits at the data regenerating time. Further, in accordance with another mode of the present invention, even when a randomized area and an unrandomized area are mixed and exist in one disk, reading and writing operations can be performed by the same device without any problem even in a disk corresponding to the randomization and a disk not corresponding to the randomization. Concretely, with respect to the reading operation, an error detection code of data, position information, etc. are detected. When an error is detected, it is judged that the scramble is performed, and the descramble is performed. With respect to the writing operation, an area for storing discriminating information is arranged within the disk. Further, an area to be written without performing the scramble and an area to be written by performing the scramble are arranged in the optical disk medium to get access in a device not corresponding to the scramble.

Further, to achieve such objects, in the scramble coding method and its circuit in the present invention, when the seed and the data to be recorded before the scramble are continuously connected and are interpreted as a polynomial expression and a polynomial divisional calculation is made with respect to this polynomial with a predetermined scramble polynomial as a divisional polynomial, a quotient polynomial of this calculation result is set to data after the scramble. Thus, even when an error exists in the data of a descramble object in the descramble, this error is diffused only until an order of said predetermined scramble polynomial at most.

Further, to achieve such objects, in the scramble coding method and its circuit of the present invention, when its order is set to M, a polynomial of xˆM+1 is used as the predetermined scramble polynomial. Here, xˆy shows the y-th power of x, and xˆM means the M-th power of x. Thus, the scramble is really performed by the polynomial divisional calculation as an accumulative calculation using an exclusive logical sum of bits each separated by M-bits. Thus, the present invention can be cheaply constructed in view of the calculating amount and the circuit scale in execution.

Further, the descramble (which is an operation reverse to the scramble and is scramble decoding) corresponding to the above scramble coding method or its circuit is performed to achieve such objects in the scramble decoding method and its circuit of the present invention. Further, the recording-regenerating method and its device of the present invention have the above scramble coding-decoding method or its device to achieve such objects. Further, the memory medium of the present invention stores data recorded by the above recording method or its device to achieve such objects.

### BRIEF DESCRIPTION OF THE DRAWINGS

FIG. 1 is a view showing a scramble circuit of the present invention.

FIG. 2 is a view showing a descramble circuit of the present invention.

FIG. 3 is a schematic block diagram of a first embodiment mode of the present invention.

FIG. 4 is a detailed block diagram of the scramble circuit of the first embodiment mode of the present invention.

FIG. 5 is a detailed circuit diagram of an Maximum length sequence generator of the first embodiment mode of the present invention.

FIG. 6 is a detailed circuit diagram of a secondary scramble circuit of the first embodiment mode of the present invention.

FIG. 7 is a detailed block diagram of the descramble circuit of the first embodiment mode of the present invention.

FIG. 8 is a detailed circuit diagram of a secondary descramble circuit of the first embodiment mode of the present invention.

FIG. 9 is a conceptual view of the first embodiment mode of the present invention.

FIG. 10 is a recording format view of the next generation optical disk.

FIG. 11 is a data sector format view of a second embodiment mode of the present invention.

FIG. 12 is a recording format view of the second embodiment mode of the present invention.

FIG. 13 is a recording format view of a fourth embodiment mode of the present invention.

FIG. 14 is a system block diagram of the second embodiment mode of the present invention.

FIG. 15 is a processing flow chart at a recording time of the second embodiment mode of the present invention.

FIG. 16 is a processing flow chart at a regenerating time of the second embodiment mode of the present invention.

FIG. 17 is a schematic block diagram of the fourth embodiment mode of the present invention.

FIG. 18 is a block diagram of an optical disk system of the fourth embodiment mode of the present invention.

FIG. 19 is a detailed block diagram of a seed generator of the second embodiment mode of the present invention.

FIG. 20 is a block diagram of the scramble circuit of the second embodiment mode of the present invention.

FIG. 21 is a block diagram of the descramble circuit of the second embodiment mode of the present invention.

FIG. 22 is a view showing a recording format of a third embodiment mode of the present invention.

FIG. 23 is a block diagram of a rewriting number recording memory of the third embodiment mode of the present invention.

FIG. 24 is one portion of a processing flow chart at a recording time of the third embodiment mode of the present invention.

FIG. 25 is a processing flow-chart at a regenerating time of the third embodiment mode of the present invention.

FIG. 26 is a block diagram of an optical disk system of a fifth embodiment mode of the present invention.

FIG. 27 is a block diagram of an optical disk system of a sixth embodiment mode of the present invention.

FIG. 28 is a block diagram of an optical disk system of the third embodiment mode of the present invention.

FIG. 29 is a typical view of an optical disk medium of the second embodiment mode of the present invention.

FIG. 30 is a typical view of an optical disk medium of the third embodiment mode of the present invention.

FIG. 31 is a processing flow chart at a partial rewriting time of the second embodiment mode of the present invention.

FIG. 32 is a processing flow chart at a power turning-on time and an optical disk insertion time of the third embodiment mode of the present invention.

FIG. 33 is one portion of the processing flow chart at the recording time of the third embodiment mode of the present invention.

FIG. 34 is one portion of the processing flow chart at the recording time of the third embodiment mode of the present invention.

FIG. 35 is a block diagram of an optical disk system of a seventh embodiment mode of the present invention.

FIG. 36 is one portion of the processing flow chart at a power turning-off time and an optical disk taking out time of the third embodiment mode of the present invention.

FIG. 37 is a typical view of an optical disk medium of an eighth embodiment mode of the present invention.

FIG. 38 is a typical view of an optical disk medium of an eleventh embodiment mode of the present invention.

FIG. 39 is a block diagram of an optical disk system of each of the eighth to eleventh embodiment modes of the present invention.

FIG. 40 is a detailed block diagram of a seed generator of each of the eighth to eleventh embodiment modes of the present invention.

FIG. 41 is a flow chart showing processing at a recording time of the eighth embodiment mode of the present invention.

FIG. 42 is a typical view of an optical disk medium of a ninth embodiment mode of the present invention.

FIG. 43 is a flow chart showing processing at a power turning-on time or a disk exchanging time of a tenth embodiment mode of the present invention.

FIG. 44 is a flow chart showing processing at the power turning-on time or the disk exchanging time of the ninth embodiment mode of the present invention.

FIG. 45 is a detailed block diagram of a scrambler of each of the eighth to eleventh embodiment modes of the present invention.

FIG. 46 is a detailed block diagram of a descrambler of each of the eighth to eleventh embodiment modes of the present invention.

FIG. 47 is a block diagram showing the construction of a scramble coding circuit of a 1-bit input-output type in a twelfth embodiment mode of the present invention.

FIG. 48 is a block diagram showing the construction of the scramble coding circuit of an M-bit input-output type in the twelfth embodiment mode of the present invention.

FIG. 49 is a block, diagram showing the construction of a scramble decoding circuit of a 1-bit input-output type in the twelfth embodiment mode of the present invention.

FIG. 50 is a block diagram showing the construction of the scramble decoding circuit of an M-bit input-output type in the twelfth embodiment mode of the present invention.

FIG. 51 is a view showing a memory medium of a disk type used in a memory device in the twelfth embodiment mode of the present invention.

FIG. 52 is a view showing the memory medium of an array type used in, the memory device in the twelfth embodiment mode of the present invention.

FIG. 53 is a block diagram showing the construction of an optical disk device having a scramble coding-decoding section for storing host data in the twelfth embodiment mode of the present invention.

FIG. 54 is a view showing the transition of data generated in a recording process by a recorder in the twelfth embodiment mode of the present invention.

FIG. 55 is a block diagram showing the construction of the optical disk device in which a processor executes a scramble coding method and a scramble decoding method to store host data in the twelfth embodiment mode of the present invention.

FIG. 56 is a block diagram showing the construction of the optical disk device for storing data of a voice and a dynamic image in broadcast in the twelfth embodiment mode of the present invention.

FIG. 57 is a block diagram showing the construction of the optical disk device of a camera type for storing the voice dynamic image data in the twelfth embodiment mode of the present invention.

FIG. 58 is a view showing a data arrangement in the optical disk device of a first literature.

### DESCRIPTION OF THE PREFERRED EMBODIMENTS

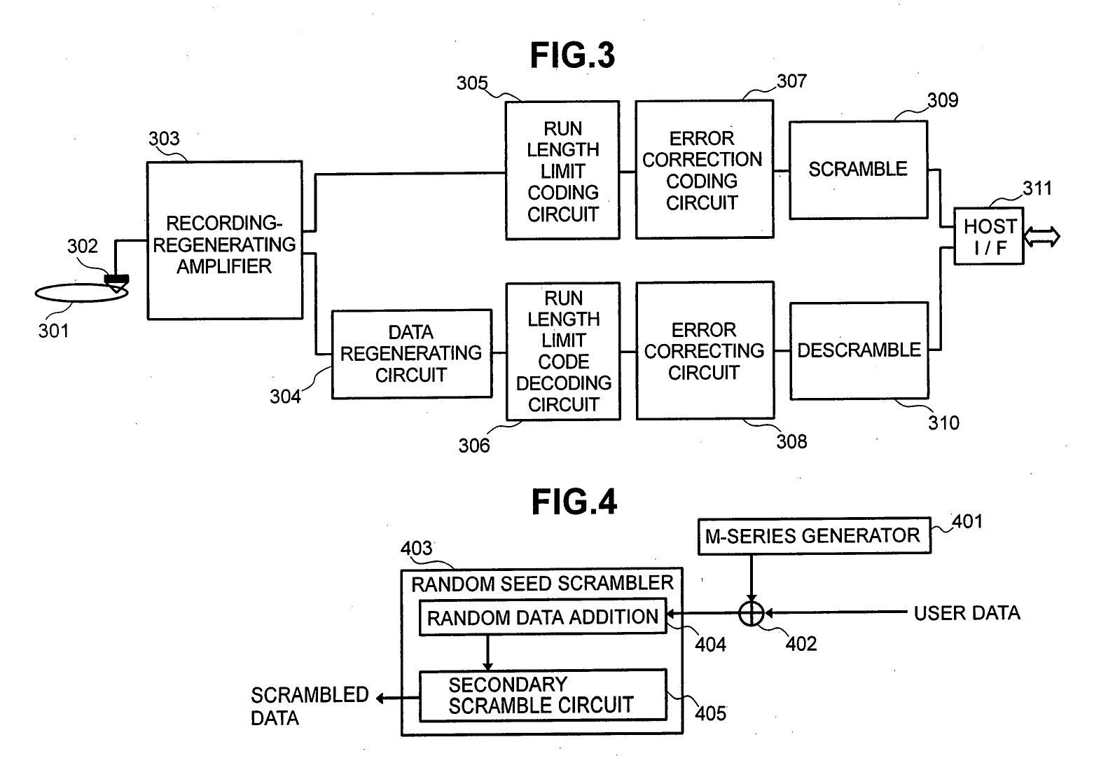

With respect to the embodiment modes of the present invention, a first embodiment mode will first be explained by using FIGS. 3 to 9. FIG. 3 is a schematic block diagram showing the construction of an optical disk device of this embodiment mode. The embodiment modes explained below do not limit the present invention. There is also a case in which the optical disk device of the present invention is used as a recording regenerator such as a stationary type image and voice recording regenerator connected to a television, a portable video camera, a portable voice regenerator, etc. in addition to a memory device used in a computer system as in this embodiment mode.

In FIG. 3, a host interface (host I/F) 311 controls data transfer between the optical disk device and a host computer such as an unillustrated personal computer, etc. A scramble circuit 309 randomizes data. An error correction coding circuit 307 adds an error correcting code to the randomized data. A run length limit coding circuit 305 modulates the data added with the error correcting code thereto in accordance with a rule determined in advance, and converts the modulated data to data able to be recorded to an optical disk 301 as a recording medium. A recording-regenerating amplifier 303 receives the coded data from the run length limit coding circuit 305, and converts the coded data to a voltage waveform suitable for a recording-regenerating head 302. The recording-regenerating head 302 converts the received voltage waveform to a laser beam, and writes a mark onto the optical disk 301 by power of the laser beam. At a reading time of the data, the recording-regenerating head 302 irradiates the laser beam to the optical disk 301, and reads the data by reflected light by utilizing the difference in reflection intensity of the light between the mark and a non-mark, and converts the read information to an electric signal.

This electric signal is amplified to a suitable degree by the recording-regenerating amplifier 303, and is then outputted to a data regenerating circuit 304. The data regenerating circuit 304 converts the read analog signal to a digital information series of 0 and 1. The obtained data series is demodulated in a run length limit code decoding circuit 306 reversely to the run length limit coding circuit 305. In an error correcting circuit 308, an error position and an error value are calculated on the basis of the error correcting code added by the error correction coding circuit 307, and the error is corrected. The data corrected with respect to the error are restored to the original data in a descramble circuit 310. In the optical disk device, the data are recorded and regenerated by the above procedure.

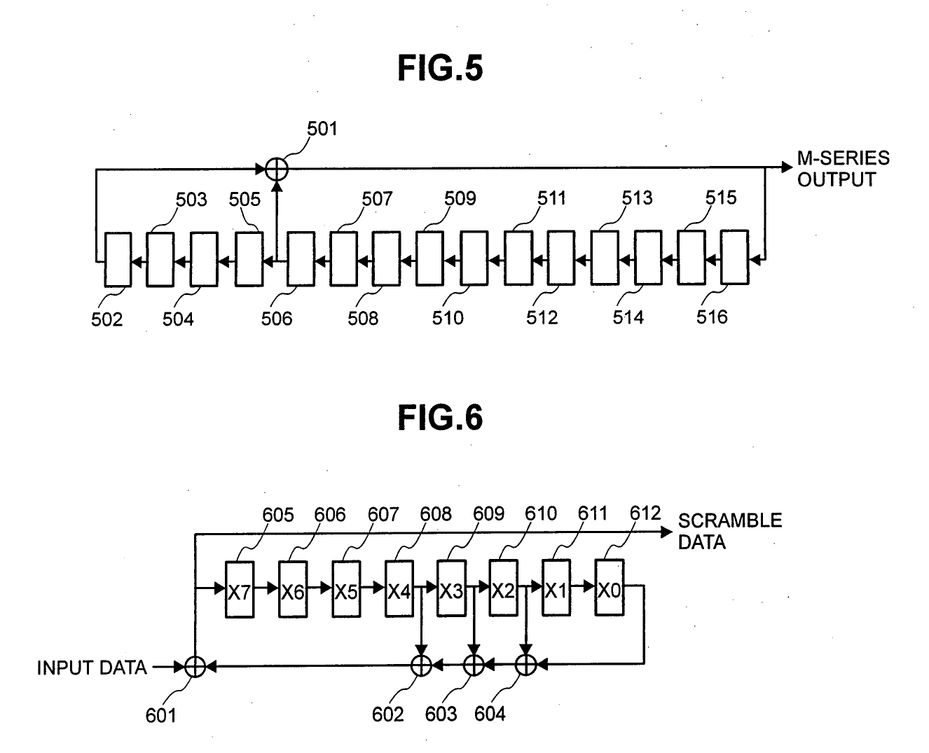

The scramble circuit 309 will be explained in detail. FIG. 4 is a detailed block diagram of the scramble circuit 309. A fixing random series made by an Maximum length sequence generator 401 is added to user data sent from the host I/F 311 by an EOR circuit 402, and these user data are then inputted to a random seed scrambler 403. FIG. 5 is a detailed circuit diagram of the Maximum length sequence generator 401. Reference numerals 502 to 516 designate registers for storing data in one bit unit. These registers 502 to 516 perform a shift operation in synchronization with the inputted user data. Reference numeral 501 designates an exclusive logical sum circuit. In an initial state, only the register 516 is set to 1, and registers 502 to 515 are set to 0. In this embodiment mode, the Maximum length sequence generator using a 15-th order polynomial shown by the following formula 1 is supposed.

Hereinafter, all the polynomials used in this embodiment mode are polynomials on Galois field (GF(2)), and “+” shows the exclusive logical sum.
x¹⁵+x⁴+1 [Formula 1]

The series generated by this Maximum length sequence generator 401 is a pseudo random series having a period of 2ˆ15−1=32767. Here, aˆb is defined as the b-th power of a. In the following description, the b-th power of a is noted as aˆb. In this embodiment mode, no Maximum length sequence generator 401 is necessarily required, and only the random seed scrambler 403 may be arranged. However, in this embodiment mode, the Maximum length sequence generator 401 is also used to preferably give random performance.

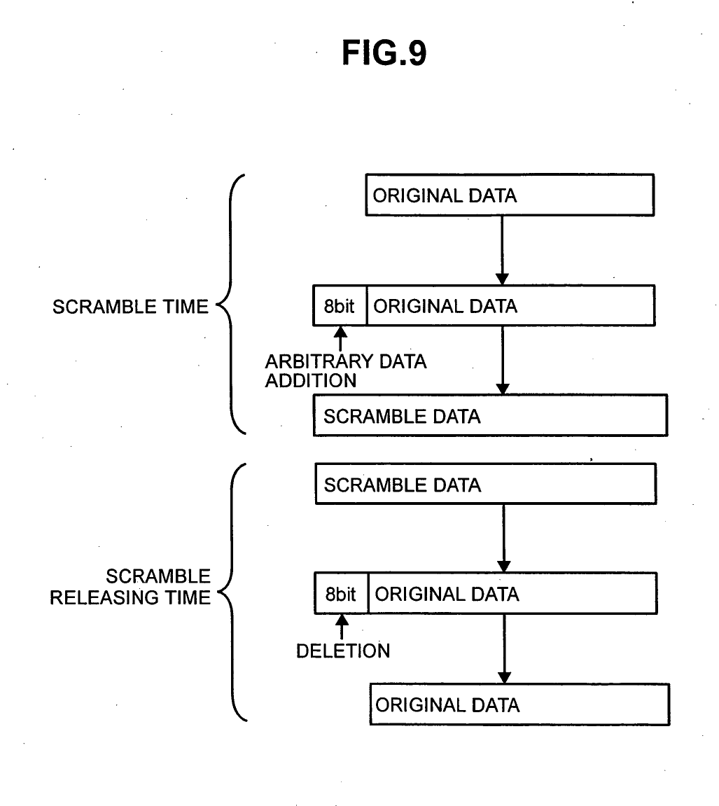

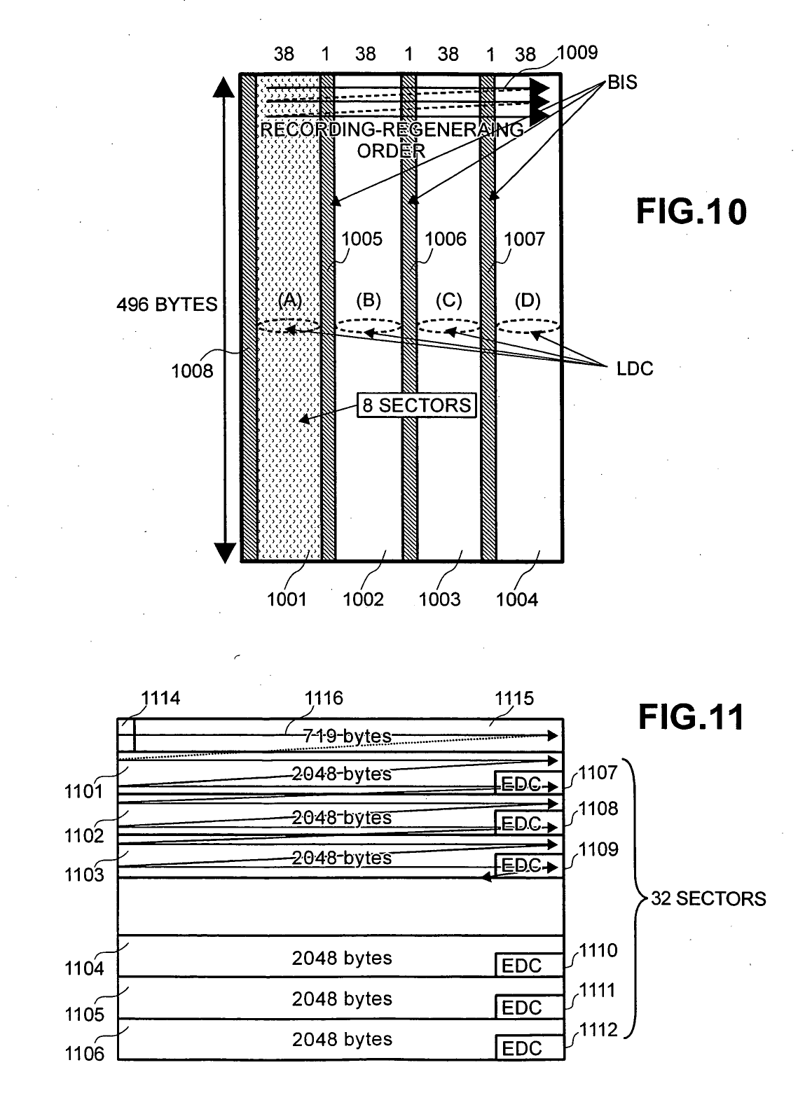

In the random seed scrambler 403, data of 8 bits are first added to the head of data as shown in FIG. 9. These data of 8 bits are arbitrary data of 8 bits, and may be set to data made on the basis of a time for performing a writing operation, etc., and may be also a value incremented one by one by an increment counter of 8 bits at every one writing operation. These added bits of 8 bits are set to a seed for randomization. In this embodiment mode, since the data of 8 bits are added, the randomization of 2ˆ8=256 combinations from “00000000” to “11111111” can be performed. Namely, when the same user data are physically recorded to the same place, the probability of setting the really written data to the same is 1/256. This probability is similarly formed when the same user data are written to an adjacent track. Thus, deterioration of the optical disk 301 can be avoided and a tracking error can be also reduced by performing such randomization. The added data are not necessarily set to 8 bits, but may be also set to bits greater or smaller than 8 bits. Further, the added bits (initial value) are not necessarily added to the head of the user data, but may be also inserted into any place of the user data. A portion after the added portion of the data (initial value) is generated as a series different at every initial value. In this embodiment mode, the added data are located in the head able to most efficiently perform the randomization.

FIG. 6 is a detailed circuit diagram of a secondary scramble circuit 405. Reference numerals 601 to 604 designate exclusive logical sum circuits. Reference numerals 605 to 612 designate registers for storing data in a one-bit unit. The registers 605 to 612 are set to 0 in the initial state. The secondary scramble circuit 405 performs the shift operation in synchronization with input data. The scramble shown by the following formula 2 is performed by this circuit.
cᵢ=bᵢ+cᵢ₋₄+cᵢ₋₅+cᵢ₋₅+cᵢ₋₈ [Formula 2]

Here, bᵢ is i-th bit data are inputted to the secondary scramble circuit. Cᵢ₋ⱼ is data located by j-bits before with respect to the i-th bit data outputted from the secondary scramble circuit. As can be seen from this formula, Cᵢ is made from data of 1 bit before the scramble, and past data of plural bits after the scramble. Thus, the data are scrambled in this way and are then sent to the error correction coding circuit 307.

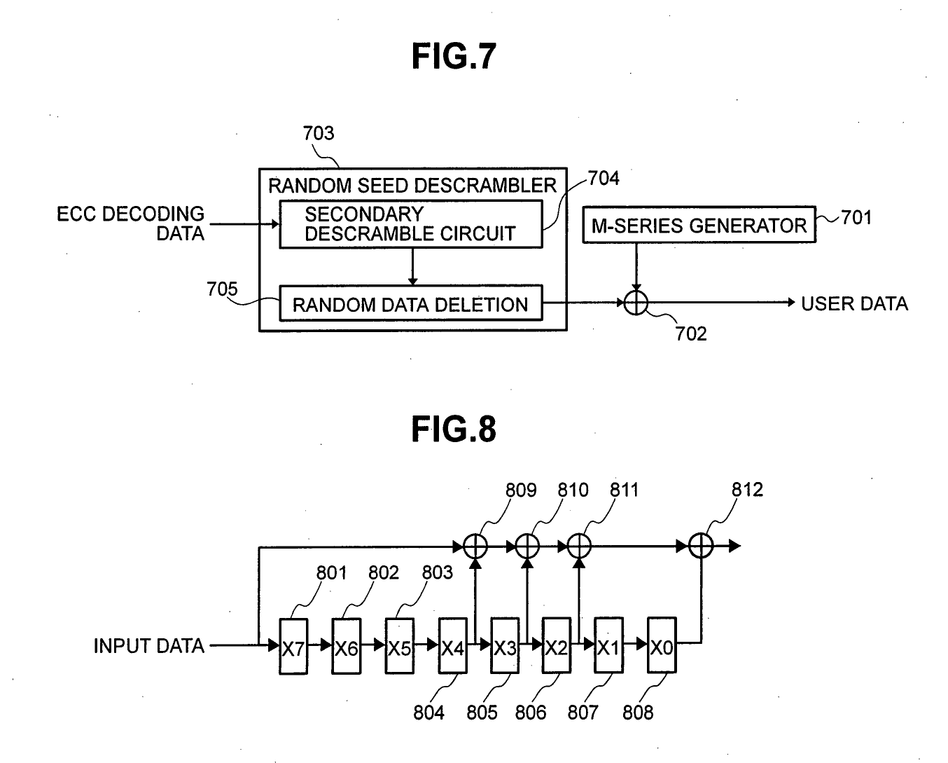

The descramble circuit 310 will next be explained in detail. FIG. 7 is a detailed block diagram of the descramble circuit 310. FIG. 8 is a detailed circuit diagram of a secondary descramble circuit 704 of FIG. 7. Reference numerals 801 to 808 designate registers for storing data in a one-bit unit. Reference numerals 809 to 812 designate exclusive logical sum circuits. Similar to the secondary scramble circuit 405, the secondary descramble circuit 704 also performs the shift operation in synchronization with input data.

The operation of the descramble circuit 310 will next be explained. Data corrected by the error correcting circuit 308 with respect to an error are inputted to the secondary descramble circuit 704 of a random seed descrambler 703. The descramble shown by the following formula 3 is performed by the secondary descramble circuit 704.
bᵢ=cᵢ+Cᵢ₋₄+cᵢ₋₅+cᵢ₋₆+cᵢ₋₈ [Formula 3]

Here, bᵢ is descrambled user data of an i-th bit, and cᵢ₋ⱼ is data located by j-bits before with respect to the i-th bit inputted from the error correcting circuit 308. As can be seen from this formula, when the descramble is performed, the descramble can be performed even when no initial value of the scramble is already known. When an error unable to be corrected is generated in the error correcting circuit 308, the error is widened by 8 bits in the descrambled user data. However, the error is propagated by only 8 bits, but is not widened any more.

As shown in FIG. 9, the added bits of 8 bits added by a random data adding circuit 404 are next deleted by a random data deleting circuit 705.

An Maximum length sequence generator 701 is the same as the Maximum length sequence generator 401, and is shown in FIG. 5. The user data are decoded by adding the same object by an exclusive logical sum circuit 702.

In this embodiment mode, the scramble circuit is constructed by using the shift register for shifting bits, but may be also realized by an equivalent circuit operated in a byte unit.

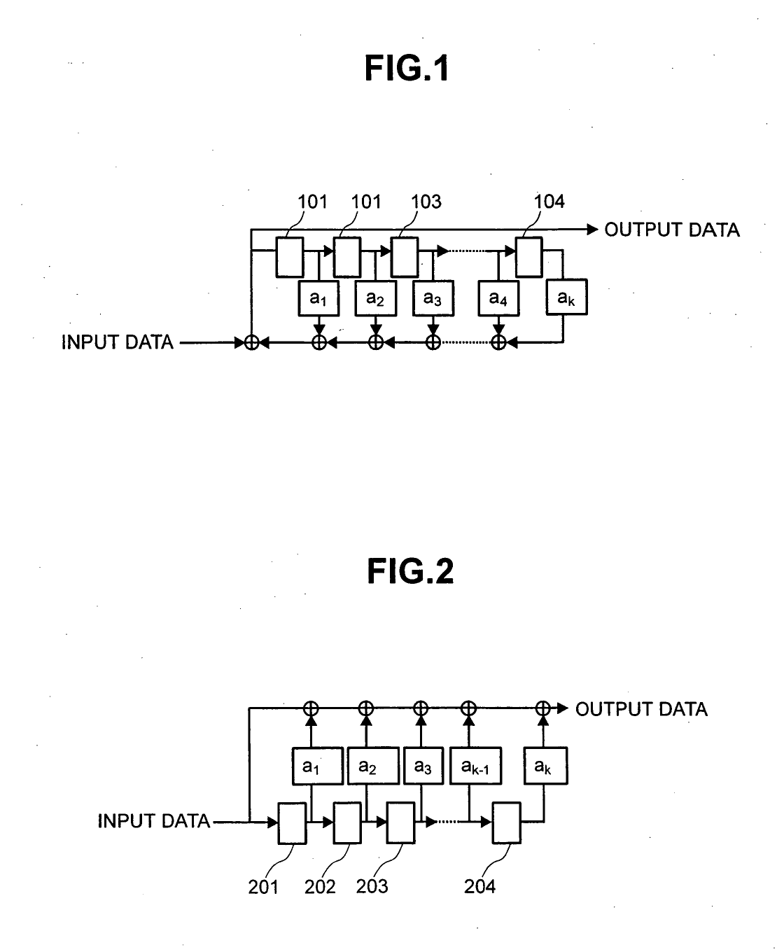

In this embodiment mode, the random seed scramble is performed by using a primitive polynomial of 8 bits represented as follows.
x⁸+x⁴+x³+x²+1 [Formula 4]
However, any polynomial may be here used. The scramble circuit can be realized by FIG. 1 and the descramble circuit can be realized by FIG. 2 with respect to the following general formula of the polynomial.

$${\sum }_{i = 0}^{n} {a}_{i} {x}^{i} \qquad [ Formula 5 ]$$

When the primitive polynomial is used in the polynomial, the period can be set to be long so that a more random series can be obtained. Here, aᵢ is set to 1 or 0. When aᵢ is 1, a signal line is connected. In contrast to this, when aᵢ is 0, no signal line is connected. In this embodiment mode, the polynomial can be also expressed as the following primitive polynomial of 8 bits.
x⁸+x⁶+x⁵+x⁴+1 [Formula 6]

In this case, the scramble circuit can be realized by FIG. 1 and the descramble circuit can be realized by FIG. 2 with respect to the following general formula of the polynomial.

$${\sum }_{i = 0}^{n} {a}_{i} {x}^{n - i} \qquad [ Formula 7 ]$$

Here, aᵢ is set to 1 or 0. When aᵢ is 1, the signal line is connected. In contrast to this, when aᵢ is 0, no signal line is connected. The relation of formulas 5 and 7 is generally called a reciprocal polynomial. Since the reciprocal polynomial of the primitive polynomial is a primitive polynomial, there is particularly no problem in view of the use of the primitive polynomial. When the definition of the formula 7 is used, output data has a meaning in which output data is a quotient provided by dividing input data by the polynomial (here formula 7) for defining the scramble circuit. However, any one of the formulas 5 and 7 may be used in the definition.

In this embodiment mode, the scramble circuit 309/descramble circuit 310 in FIG. 3 are arranged between the error correction coding circuit 307/error correcting circuit 308 and the host I/F in the above explanation, but may be also arranged between the run length limit coding circuit 305/decoding circuit 306 and the error correction coding circuit 307/decoding circuit 308. Further, in FIGS. 4 and 7, in this embodiment mode, the Maximum length sequence generator 401/701 is arranged on the host I/F 311 side from the random seed scramble circuit 403/descramble circuit 703, but may be also arranged on the optical disk 301 side from the random seed scramble circuit 403/descramble circuit 703. The arrangement of the above scramble circuit 310 or the Maximum length sequence generator 401/701 is one embodiment, and the present invention is not limited to this arrangement. Namely, the scramble circuit 301 or the Maximum length sequence generator 401/701 can be arranged in an arbitrary position able to obtain the effects of the present invention. Further, in FIG. 3, all or one portion of the scramble circuit 309, the error correction coding circuit 307, the run length limit coding circuit 305, the descramble circuit 310, the error correcting circuit 308, the run length limit code decoding circuit 306, etc. can be constructed by one chip.

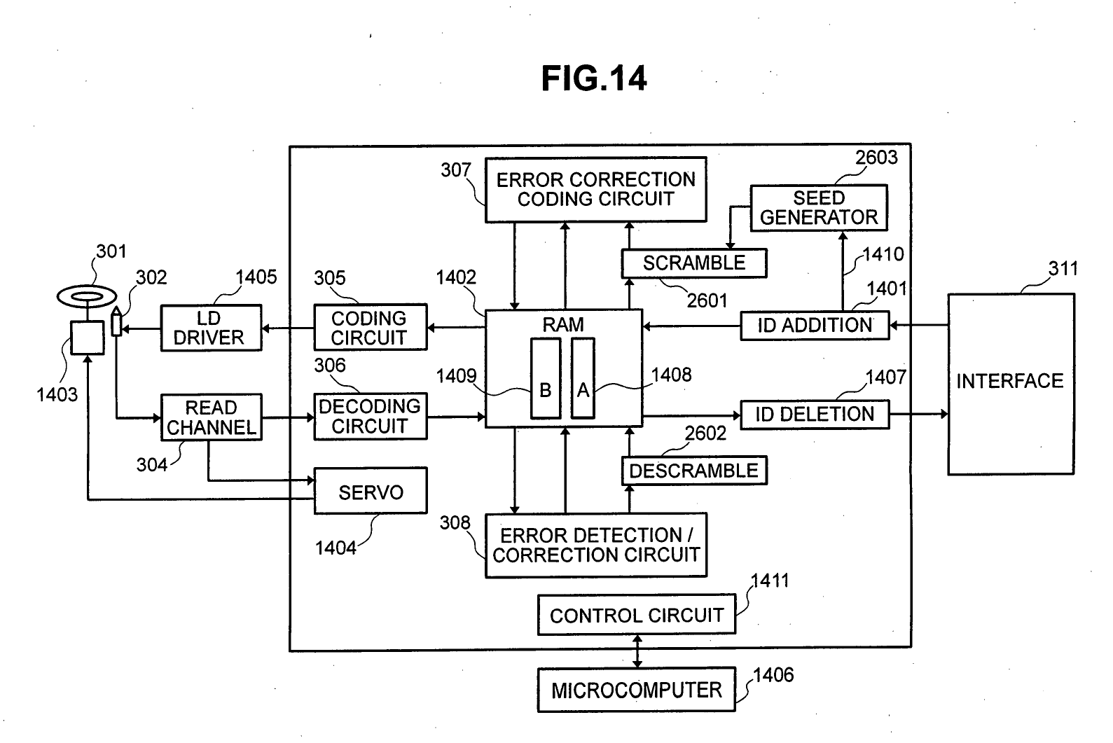

An application case of the random seed scramble explained in the first embodiment mode to the next generation DVD format will next be explained further in detail as a second embodiment mode. FIG. 14 is a schematic block diagram of a DVD device in this second embodiment mode. Reference numeral 311 designates an interface for performing input-output control of data with respect to an upper device. Reference numeral 1406 designates a microcomputer for generalizing a system. The microcomputer 1406 is connected to a control circuit 1411 within the system. This control circuit 1411 controls the operations of a seed generator 2603, the error correction coding circuit 307, a scrambler 2601, etc. through an unillustrated control line. Reference numeral 1401 designates an ID adder for adding additional information such as ID, etc. required to make a record to the user data given by the interface 311. Reference numeral 1402 designates a memory (RAM) for temporarily storing data. Reference numeral 2601 designates a scrambler for randomizing data.

This scrambler is a scrambler shown in FIG. 20, and includes the random seed scrambler 403 explained in the first embodiment mode. Reference numeral 2603 designates a seed generator for giving a different seed to the random seed scrambler within the scrambler 2601 every writing. Reference numeral 307 designates an error correction coding circuit for adding an error correcting code to the scrambled user data. Reference numeral 305 designates a coding circuit for converting the user data adding the error correcting code thereto to a run length limit code suitable for the record to the optical disk 301. Reference numeral 302 designates a pickup for recording/regenerating data of the optical disk 301. Reference numeral 1403 designates a spindle motor for rotating the disk. Reference numeral 1404 designates a servo for controlling the operation of the optical pickup 302, etc. Reference numeral 304 designates a read channel for performing waveform equalization processing of an analog regenerating signal read from the optical disk 301, a binary operation and synchronous clock generation. Reference numeral 306 designates a decoder for decoding the read run length limit code. Reference numeral 308 designates an error detection-correction circuit for detecting an error on the basis of the error correcting code added by the error correction coding circuit 307, and correcting the error. Reference numeral 2602 designates a descramble circuit for releasing the randomization performed by the scrambler 2601 and returning the user data to the original user data and shown in FIG. 21. The descramble circuit 2602 includes the random seed descrambler 703 explained in the first embodiment mode. Reference numeral 1407 designates an ID deleting device for deleting the additional information required to record the ID, etc. added by the ID adder 1401, and setting the data to only the user data.

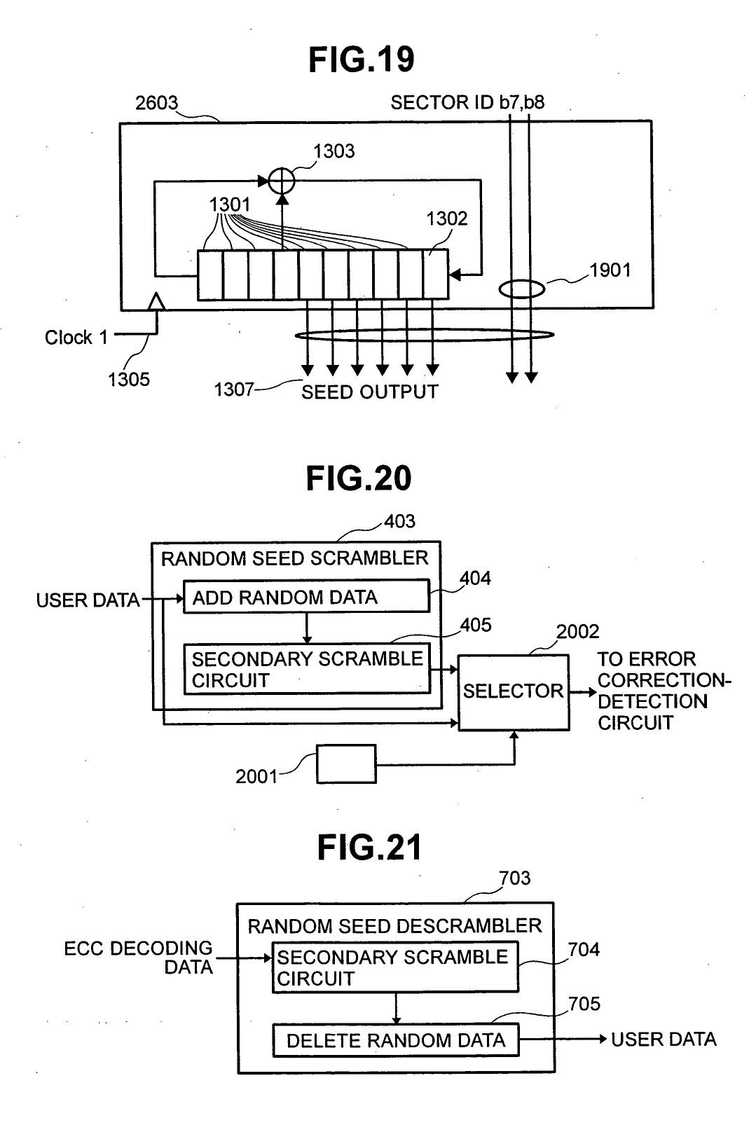

FIG. 19 is a view showing the seed generator 2603 of this second embodiment mode. Each of reference numerals 1301, 1302 designates a 1-bit shift register, and reference numeral 1303 designates an exclusive logical sum circuit. A suitable value except for all zero is inputted to each 1-bit shift register 1301 in the initial state. When the seed is required at a data writing time, a clock (1305) is inputted and the values of the 1-bit shift registers 1301, 1302 are leftward shifted. An output value of the exclusive logical sum circuit 1303 is inputted to the 1-bit shift register 1302. Thereafter, 6 bits of the seed value inputted to the 1-bit shift registers 1301, 1302 and a sector ID (b7 and b8 of the sector number) (1901) given by the ID adder 1401 are outputted as the seed to the scramble circuit 2601 through a seed output line 1307. Here, b7 and b8 of the sector ID correspond to eighth and ninth bits from the lower order of the sector ID, and a bit for absolutely giving no same value in an adjacent track is selected.

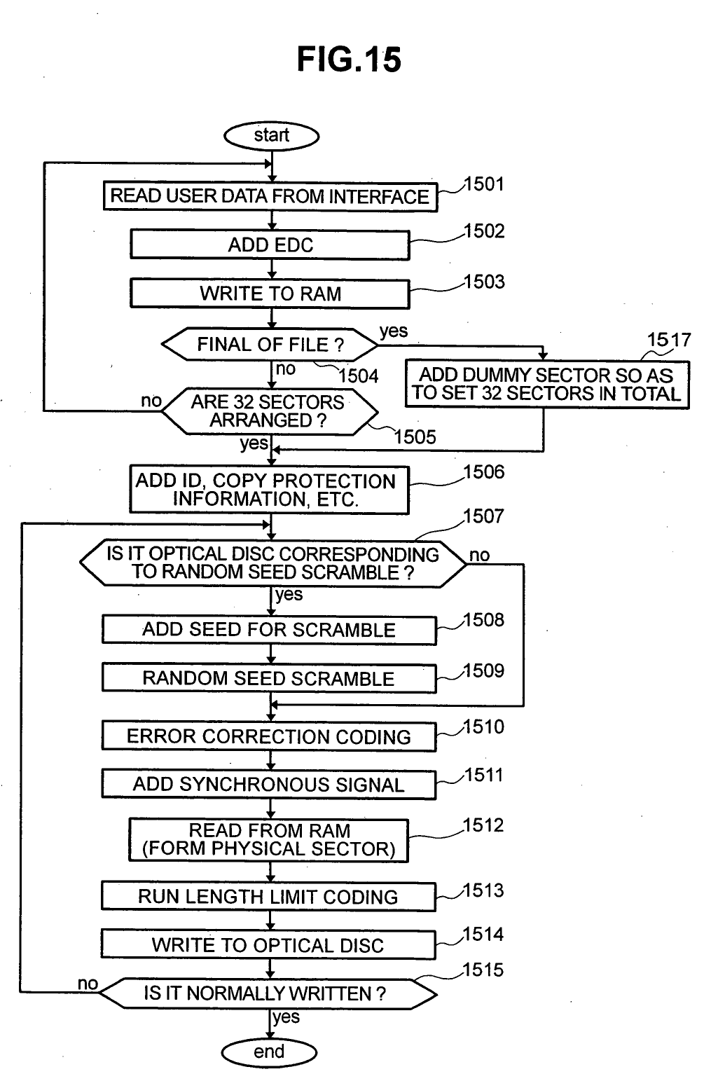

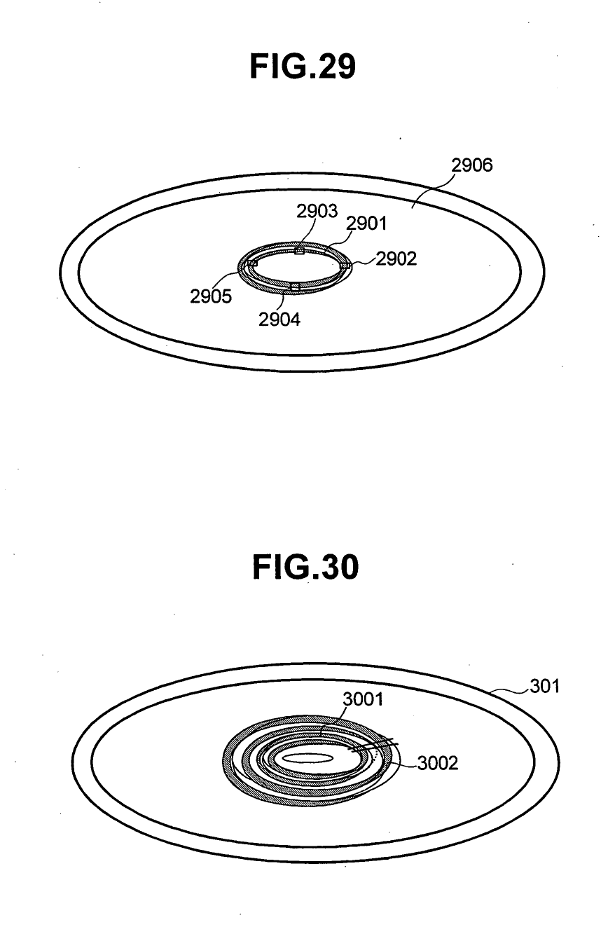

The operation of the DVD device shown in FIG. 14 will next be explained. The operation of the DVD device at a recording time will first be explained with reference to the optical disk shown in FIG. 29, the format shown in FIG. 11 and the processing procedure shown in FIG. 15 at the recording time. In the optical disk shown in FIG. 29, scramble mode information showing whether this optical disk corresponds to a random seed scramble, is written to an innermost circumferential track 2901. The same information as 2902, 2903, 2904, 2905 is written to four places so as to provide reliability for the scramble mode information. As shown in this embodiment mode, the reliability of data can be highly held by writing the above information to the innermost circumference since no innermost circumference is easily damaged. This scramble mode information is read into the optical disk device at a power turning-on time of the optical disk device or an optical disk insertion time, and is stored into a mode bit 2001 within the scramble circuit 2601. When different information is obtained from the four places, a value largely read by decision by majority is written to the mode bit 2001. In this embodiment mode, the writing position of the scramble mode information is limited to only the inner circumference. However, when no track near the outer circumference or the center instead of the inner circumference is easily damaged, the writing position may be also arranged in the track near the outer circumference or the center.

Further, the writing operation may be also performed by dividing the track into plural tracks as in the innermost circumference and a circumference near the center. In this case, it takes time to read the scramble mode information, but the scramble mode information can be more reliably stored. Further, in this embodiment mode, the writing position of the scramble mode information is set to four places, but may be also set to places greater than four places. In this case, the scramble mode information can be more reliably stored. Further, the scramble mode information can be also written by adding a strong error correcting code to more reliably write the scramble mode information. When the writing position of the scramble mode information is set to odd places, but there is a merit in that the writing position is determined by decision by majority at any time and processing is easily performed. In accordance with the present invention, it is possible to provide a disk having the above characters and a device for recording data to this disk.

First, user data 1101 of 2048 bytes (corresponding to logic sector) are inputted from the interface 311 (step 1501). In the ID adder 1401, an error detection code (EDC) 1107 of four bytes is added to the user data 1101 inputted from the interface 311 (step 1502), and these user data are written to an area A 1408 of a RAM 1402 (step 1503). It is then confirmed whether a file is terminated (step 1504). When it is the termination of the file, the remaining sectors constructed by dummy data are added so as to provide 32 sectors in total (step 1517). In contrast to this, when it is not the end of the file, it is confirmed whether the 32 sectors are completed (step 1505), and steps 1501 to 1505 are repeated until the 32 sectors are completed. When the 32 sectors are completed, additional information 719 byte 1115 such as identification address information of data such as ID, etc., copy protection information, reserve information, etc. Is further added to the 32 logic sectors 1101 to 1106 and EDCs 1107 to 1112 in the ID adder 1401 as shown in FIG. 11 (step 1506). Next, a mode bit 2001 is inspected, and it is judged whether the disk to be written at present corresponds to the random seed scramble (step 1507.).

When this disk does not correspond to the random seed scramble, a selector 2002 transfers unscrambled user data to the error correction-detection circuit. In contrast to this, when the disk corresponds to the random seed scramble, the scramble is performed by the scramble circuit 2601. In the scramble circuit 2601, a seed 1114 of 1 byte given by the seed generator 2603 is added to the head of the additional in-formation 719 byte (step 1508), and the random seed scramble explained in the first embodiment mode is performed (step 1509). As shown by an arrow 1116 of FIG. 11, the scramble is sequentially performed in the order of the seed 1114, the additional information 1115, the user data 1101 from the left upper portion, and the scrambled data are transferred to the error correction coding circuit 307.

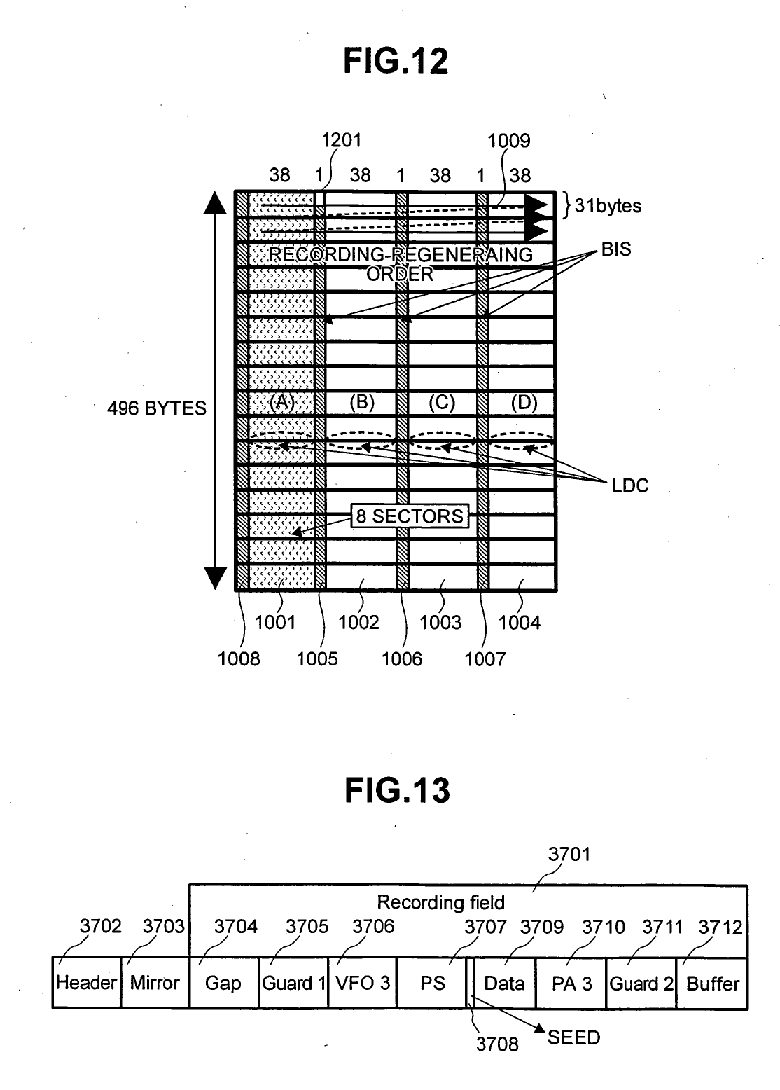

Next, in the error correction coding circuit 307, the scrambled data of the additional information 1115 of 719 bytes and the seed 1114 of 1 byte for the random seed scramble stored to an area A 1408 within the RAM 1402 are divided into 24 pieces of 30 bytes each. In the error correction coding circuit 307, these data of 30 bytes each are changed to [62, 30, 33] RS codes, and are respectively stored to three BIS areas 1005, 1006, 1007 within an area B(1409) of the RAM 1402 shown in FIG. 12 of 8 code words each. Next, the logic sectors added with the EDC are collected into groups of 8 sectors each, and is divided into 76 pieces of 216 bytes each. Each piece is changed to [248, 216, 33] RS codes, and is collected by 8 sectors, and these sectors are arranged in an LDC area 1001 (38 bytes×496 bytes) of (A) shown by half-tone dot meshing in FIG. 12. Similarly, the logic sectors are collected every 8 sectors, and the LDC areas of (B)1002, (C)1003 and (D)1004 are filled with these logic sectors (step 1510). Further, a synchronous signal (SYNC code) 1008 is added to the left-hand end (step 1511).

Next, the coding circuit 305 reads data from an area B(1409) of the RAM 1402 in accordance with an arrow 1009 showing a recording-regenerating order in FIG. 12, and continuously reads 31 stages (one stage corresponds to 1 byte in the longitudinal direction) as a “physical sector” of 4 k bytes (step 1512), and performs run length limit coding (step 1513).

The run length limit coded sequence is then written to the optical disk 301 via an LD driver 1405 and the optical pickup 302 (step 1514). Thereafter, the written data are read and are compared with the data of the RAM so as to judge whether the data are normally written to the optical disk (step 1515).

When the data of 1 ECC block are normally recorded to the optical disk 301, the processing is terminated. However, when it is unsuccessful in the record for a certain reason during the record of the data, the medium is deteriorated when the same data are written to the same place. Accordingly, when the disk corresponds to the random seed scramble, the scramble is again performed by changing the seed, and the data are rewritten. Namely, the data are rewritten from the step 1507. In this case, data stored to the area A 1408 of the RAM 1402 are scrambled in the scrambler 2602. The scrambled data are again stored to the RAM 1402, and the error correcting code is again added to these scrambled data by the error correction coding circuit 307. The data adding the error correcting code thereto are converted to a physical sector, and are changed to a run length limit code, and are then again written to the optical disk 301.

It is possible to omit the step 1515 and the rewriting step using the rescramble in a case such as an AV system in which speed is more important than reliability. As shown by 1201 of FIG. 12, seed 1 byte of the random seed scramble is written into the BIS area by performing the writing processing as in this embodiment mode. It is possible to prevent the same data as an adjacent track from being written by using a different bit at any time between adjacent tracks in one portion of the seed of the random seed scramble as in this embodiment mode even when no scramble using an Maximum length sequence additional calculation with ID, etc. as the seed is performed. Therefore, correlation with respect to the adjacent track can be reduced so that noises from a data area with respect to a servo, etc. can be reduced. In this second embodiment mode, b7 and b8 of the sector ID are used. However, any sector number may be used if it is guaranteed to take a different value between the adjacent tracks. If the track number, etc. exist within the ID, the track number, etc. may be also used. One portion of the ID may be also used in one portion of the seed as a value giving track information as in the seed of the Maximum length sequence used in the scramble of the present DVD-RAM.

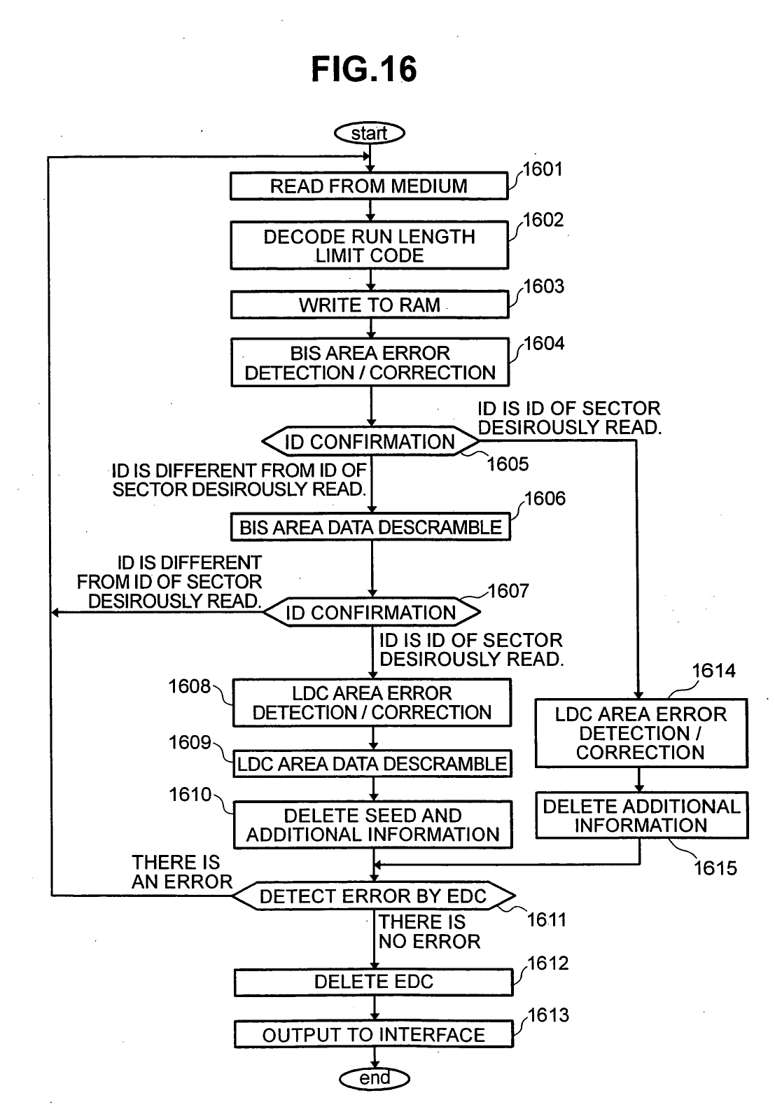

The processing procedure at a regenerating time will next be explained with reference to FIG. 16. At the regenerating time, data are read by the optical pickup 302, and a binary operation is performed and a synchronous clock is generated in the read channel 304 (step 1601). In the decoding circuit 306, the decoding operation is performed from a run length limit code (step 1602), and regenerating data are temporarily stored to the area B 1409 of the RAM 1402 in accordance with the arrow 1009 shown in FIG. 12 (step 1603). The physical sector corresponding to 4 k bytes is collectively read by 16 sectors and is temporarily stored to the area B 1409 of the RAM 1402. The error detection/correction circuit 308 first performs error correction processing of the seed 1114 stored to the BIS area shown in FIG. 12 and the additional information 719 byte 1115 such as ID, etc. (step 1604). Next, it is confirmed whether the ID written to the BIS area and performed with respect to the error correction processing is the ID of an ECC block intended to be regenerated (step 1605). If the ID is the ID of the ECC block or the sector desirously read, the error correction processing of an LDC area is performed (step 1614). The additional information 719 byte 1115 such as ID, etc. is deleted by the ID deleting circuit 1407 (step 1615), and it is jumped to a step 1611. In contrast to this, when no ID written to the BIS area and performed with respect to the error correction processing is the ID of the ECC block intended to be regenerated, the data of the BIS area terminated with respect to the error correction processing are transferred to the descramble circuit 2602 and are descrambled, and are temporarily stored to the area A1408 of the RAM 1402 (step 1606).

As shown in FIG. 21, this descramble circuit 2602 includes the random seed descramble circuit 703. All 1-bit shift registers 801 to 808 within the secondary descramble circuit 704 are cleared to “0” before the data of the BIS area are inputted. After the descramble of the BIS area is terminated, the values of the 1-bit shift registers 801 to 808 within the secondary descramble circuit 704 are held until the descramble of the LDC area is started. Next, it is confirmed whether the ID included in the descrambled BIS data is the ID of a sector desirously read (step 1607). When the read ID is different from the ID of the desired sector, it is again returned to the step 1601, and data are read from the medium. In contrast to this, when the read ID is the ID of the desired sector, the error correction processing of the user data stored to the LDC area is performed in the error detection/correction circuit 308 (step 1608). After the error correction processing is terminated, the data of the LDC area are transferred from the area B 1409 of the RAM 1402 to the descramble circuit 2602 and are descrambled, and are temporarily stored to the area A1408 of the RAM 1402 (step 1609). The descramble processing can be continuously performed since the values of the 1-bit shift registers 801 to 808 within the descramble circuit 310 are not changed as they are. After the descramble is terminated, the seed 1114 for the scramble and the additional information 1115 such as ID, etc. are deleted from the data stored to the area A1408 of the RAM 1402 by the ID deleting circuit 1407 (step 1610).

Thereafter, it is confirmed that there is no error in the user data 1101 to 1106 by using EDCs 1107 to 1112 (step 1611), and the EDCs 1107 to 1112 are deleted (step 1612), and the user data are outputted to the interface 311 (step 1613). Thus, since the scramble is released by using the construction of the second embodiment mode after the error correction processing is terminated, no deterioration of error correction ability due to error propagation of the random seed scramble is generated. In the second embodiment mode, the seed of 1 byte is added to 1 ECC block 64 K bytes, but the random seed scramble can be also performed every logic sector by adding the seed of logic sector 2 K bytes each. When the scramble is performed of logic sector each, a method for processing the random seed scramble by using the same seed in each logic sector in the 1 ECC block is considered.

Further, error propagation is generated in the random seed scramble. Accordingly, when it is considered to remedy data as much as possible in the case of error correction disability, it is desirable to perform the scramble processing on the user side from the error correction coding. As shown in this embodiment mode, it is desirable to descramble-process the additional information such as ID, etc. corresponding to the user data before the user data. Thus, the ID can be early confirmed so that are-reading operation can be rapidly performed when the ID is incorrect. When the ID is confirmed before the data descramble as shown in this embodiment mode, and the desirable ID is obtained here, data are regenerated without descrambling these data. In contrast to this, when no desirable ID is obtained, the ID is confirmed after the descramble is performed. After the desirable ID is thus obtained, the data are also descrambled and regenerated. Thus, the data can be regenerated without any care about a disk recorded by using the random seed scramble and a disk recorded without using the random seed scramble. If this system is used, the data can be regenerated without any care in a case in which the scrambled ECC block and the unscrambled ECC block are mixed within one disk instead of a disk unit. In accordance with the present invention, this disk and a device for regenerating this disk can be provided.

Further, in this embodiment mode, the judgment is made by only the EDC check result of one logic sector. However, it may be also judged that no data are scrambled when all the EDC check results of plural logic sectors or 1 ECC block are OK. In this case, it is possible to reduce the probability of a judgment mistake due to the error detection of the EDC.

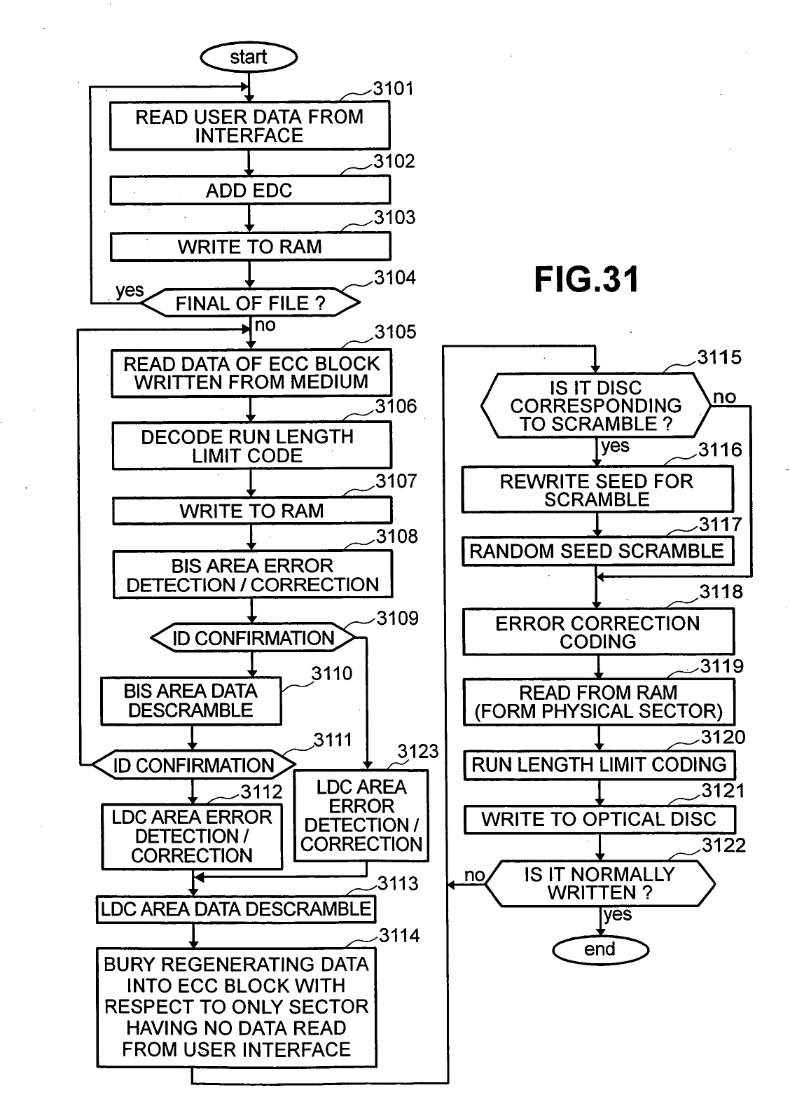

The processing procedure in rewriting only the sector of one portion within the ECC block 64 K bytes will next be explained with reference to FIG. 31. First, user data 1101 of 2048 bytes (corresponding to 1 logic sector) to be rewritten are inputted from the interface 311 (step 3101). The ID adding circuit 1401 adds an error detection code (EDC) 1107 of 4 bytes to the user data 1101 inputted from the interface 311 (step 3102), and writes these user data to the area A1408 of the RAM 1402 (step 3103). It is then confirmed whether a file is terminated (step 3104). If no file is terminated, it is returned to the step 3101, and the data are read until the end of the file. In the case of the termination of the file, written data of the ECC block are read from the optical disk 301 (step 3105). In the decoding circuit 306, the decoding operation is performed from a run length limit code (step 3106), and regenerating data are temporarily stored to the area B1409 of the RAM 1402 in accordance with the arrow 1009 shown in FIG. 12 (step 3107). The physical sector corresponding to 4 k bytes is collectively read by 16 sectors, and is temporarily stored to the area B1409 of the RAM 1402. The error detection/correction circuit 308 first performs the error detection processing of the seed 1114 stored to the BIS area shown in FIG. 12, and the additional information 791 byte 1115 such as ID, etc. (step 3108). It is then conformed whether the ID terminated with respect to the error correction processing is the ID of the ECC block desirously written (step 3109). When the IDs are conformed to each other, the error correction processing of the LDC area is performed (step 3123), and it proceeds to a step 3114. In contrast to this, when no IDs are conformed to each other, the data of the BIS area terminated with respect to the error correction processing are transferred to the descramble circuit 2602 and are descrambled, and are temporarily stored to the area A1408 of the RAM 1402 (step 3110). Before the data of the BIS area are inputted, all the 1-bit shift registers 801 to 808 within the secondary descramble circuit 704 are cleared to “0”.

After the descramble of the BIS area is terminated, the values of the 1-bit shift registers 801 to 808 within the secondary descramble circuit 704 are held until the descramble of the LDC area is started. Next, it is conformed whether the ID included in the descrambled BIS data is the ID of a sector desirously written (step 3111). When the read ID is different from the ID of the desired sector, it is again returned to the step 3105, and data are read from the medium. In contrast to this, when the read ID is the ID of the desired sector, the error correction processing of the user data stored to the LDC area is performed in the error detection/correction circuit 308 (step 3112). After the error correction processing is terminated, the data of the LDC area are transferred from the area B1409 of the RAM 1402 to the descramble circuit 310 and are descrambled (step 3113), and are temporarily stored to the area A1408 of the RAM 1402 with respect to only the sector unwritten in the step 3103 (step.3114).

Thus, the data of written 1 ECC block are completed. Next, in the scramble circuit 2601, it is first checked whether the inserted disk is a disk corresponding to the scramble (step 3115). If no inserted disk is the scramble corresponding disk, it proceeds to a step 3118. In contrast to this, when the inserted disk is the scramble corresponding disk, the random seed scramble is performed. A seed 1114 of 1 byte for the random seed scramble given by the seed generator 2603 is then added (step 3116), and the added data are scrambled (step 3117). As shown by an arrow 1116 of FIG. 11, the scramble is sequentially performed in the order of the seed 1114, the additional information 1115 and the user data 1101 from the left upper portion, and the scrambled data are transferred to the error correction coding circuit 307.

In the error correction coding circuit 307, the data scrambled with respect to the seed 1114 of 1 byte for the random seed scramble stored to the area A1408 within the RAM 1402 and the additional information 1115 of 719 bytes are changed to [62, 30, 33] RS codes of 30 bytes each, and are divided into 24 pieces. In the error correction coding circuit 307, these data of 30 bytes each are changed to [62, 30, 33] RS codes, and are respectively stored to three BIS areas 1005, 1006, 1007 within the area B1409 of the RAM 1402 shown in FIG. 12 by of 8 code words each. Next, the logic sector added with the EDC thereto is collected into groups of 8 sectors each, and is divided into 76 pieces of 216 bytes each. Each piece is changed to [248, 216, 33] RS codes, and is collected by 8 sectors, and is arranged in the LDC area 1001 (38 bytes×496 bytes) of (A) shown by half-tone dot meshing in FIG. 12. Similarly, the LDC areas of (B)1002, (C)1003 and (D)1004 are collectively filled with the pieces of 8 sectors each (step 3118).

Next, the coding circuit 305 reads data from the area B of the RAM 1402 in accordance with the arrow 1009 shown in FIG. 12 and showing a recording-regenerating order, and continuously reads the data at 31 stages (one stage corresponds to 1 byte in the longitudinal direction) as a “physical sector” of 4 k bytes (step 3119), and changes these data to a run length limit code (step 3120). The data of 4 k bytes changed to the run length limit code are written to the optical disk 301 via the LD driver 1405 and the optical pickup 302 (step 3121). The remaining data changed to the error correcting code are similarly processed every “physical sector” of the 4 k bite unit and are written onto the optical disk. Thereafter, the written data are read and are compared with the data of the RAM as to whether the data are normally written to the optical disk (step 3122). When the data of 1 ECC block are normally recorded onto the optical disk 301, the processing is terminated. However, when it is unsuccessful in the record for a certain reason during the record of the data, deterioration of the medium is caused when the same data are written to the same place. Accordingly, when the disk corresponds to the random seed scramble, the scramble is again performed by changing the seed, and data are rewritten.

Namely, the data are rewritten from the step 3115. In this case, the data stored to the area A of the RAM 1402 are scrambled in the scramble 2602. The error correcting code is again added to the scrambled data in the error correction coding circuit 307. The data adding the error correcting code thereto are converted to a physical sector, and are changed to a run length limit code, and are then again written to the optical disk 301. It is possible to omit the step 3122 and the rewriting step using the rescramble in a case such as an AV system in which speed is more important than reliability.

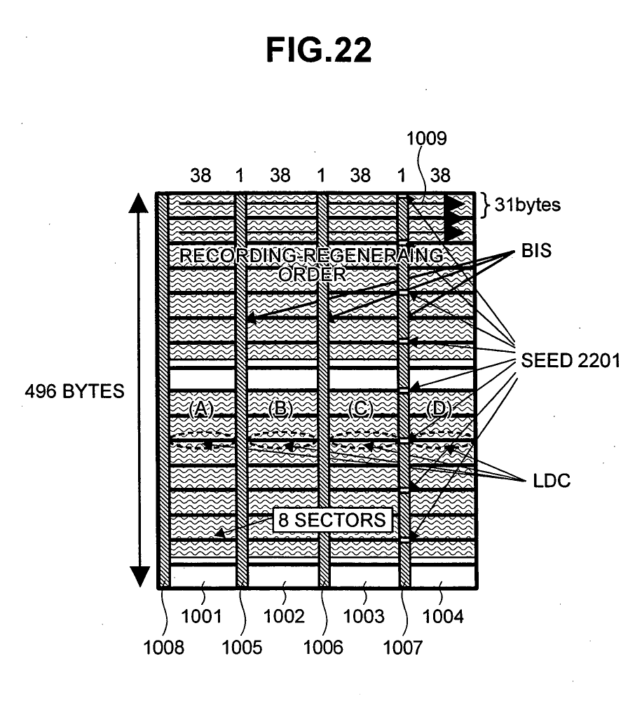

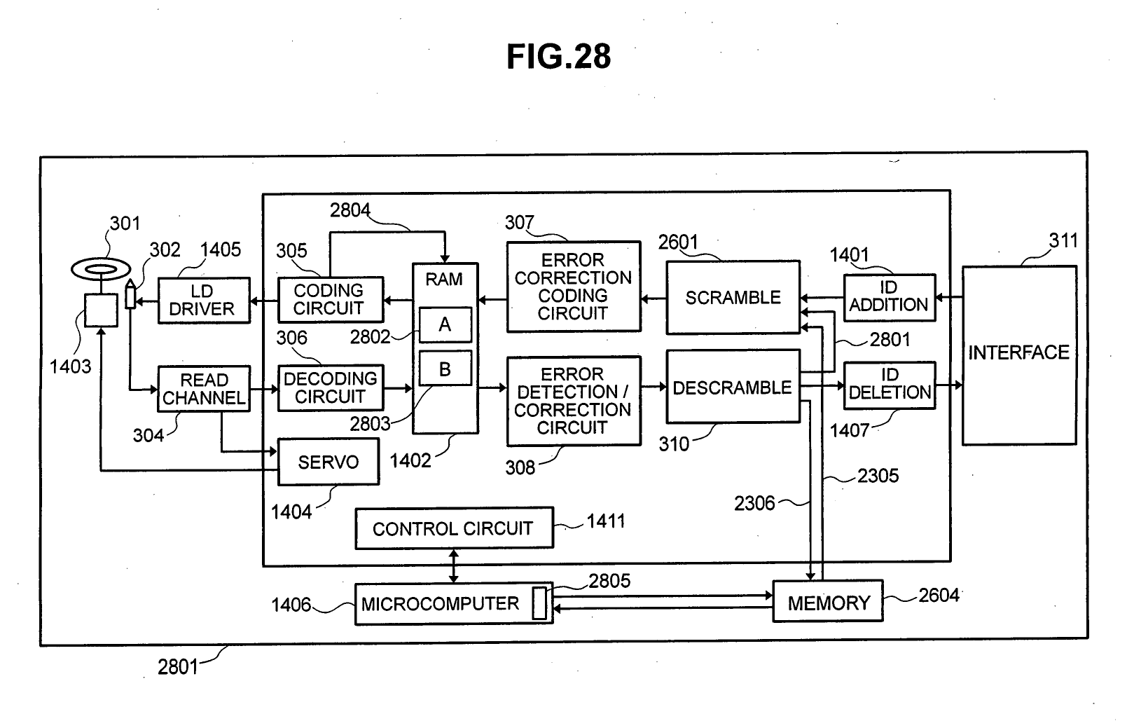

A third embodiment mode will next be explained with reference to FIGS. 28 and 30. FIG. 30 shows an optical disk medium 301 used in this third embodiment mode. Reference numeral 3001 designates an innermost circumferential track of the optical disk 301, and a rewriting number of each ECC block is recorded to tracks 3001 to 3002. Data are written to the optical disk 301 of this third embodiment mode in accordance with the format shown in FIG. 22, and are also written to the innermost circumferential tracks 3001 to 3002 in accordance with the format shown in FIG. 22. In this embodiment mode, the reliability of a rewriting number recording area is raised by arranging there writing number recording area in the innermost circumference. In the format shown in FIG. 22, the data of 32 logic sectors (32*2048 bytes) can be stored as shown in FIG. 11. These 32*2048 bytes are divided into sizes of 17 bits each, and each size is set to the rewriting number recording area. This rewriting number recording area of these 17 bits corresponds to the ECC block for recording data in the entire disk one by one, and can be preferably counted until the rewriting of about 130,000 times. Number 1 is written as the rewriting number at a factory forwarding time of the optical disk. The data of 30480 ECC blocks can be managed in one ECC block. The rewriting number recording area of 12 ECC blocks is required to manage the optical disk of 22.5 G bytes. The tracks (until track 3002) of the 12 ECC blocks from the innermost circumferential track 3001 are prepared as the rewriting number recording area.

FIG. 28 is a schematic block diagram of a DVD device in this third embodiment mode. Reference numerals 311 and 1406 respectively designate an interface for performing input-output control of data with respect to an upper device, and a microcomputer for generalizing a system. The microcomputer 1406 is connected to a control circuit 1411 within a system, and the control circuit 1411 controls the operations of an error correction coding circuit 307, a scrambler 2601, etc. through an unillustrated control line. In the microcomputer 1406, there is an information bit 2805 showing whether the optical disk inserted at present corresponds to the random seed scramble with the rewriting number as one portion of the seed. Reference numeral 1401 designates an ID adder for adding additional information such as ID, etc. required to make a record to user data given by the interface 311. Reference numeral 1402 designates a memory (RAM) for temporarily storing data. Reference numeral 2601 designates a scrambler for randomizing data. This scrambler is explained in the first embodiment mode, and includes an Maximum length sequence generator of a fixing seed and a random seed scrambler. Reference numeral 307 designates an error correction coding circuit for adding an error correcting code to the scrambled user data. Reference numeral 305 is a coding circuit for converting the user data adding the error correcting code thereto to a run length limit code suitable for the record to the optical disk 301. Reference numerals 302 and 1403 respectively designate a pickup for recording/regenerating data of the optical disk 301, and a spindle motor for rotating the disk. Reference numeral 1404 designates a servo for controlling the operation of the optical pickup 302, etc. Reference numeral 304 designates a read channel for performing waveform equalization processing of an analog regenerating signal read from the optical disk 301, a binary operation and synchronous clock generation. Reference numeral 306 designates a decoder for decoding the read run length limit code. Reference numeral 308 designates an error detection-correction circuit for detecting an error on the basis of the error correcting code added by the error correction coding circuit 307, and correcting the error. Reference numeral 310 designates a descramble circuit for releasing the-randomization performed by the scrambler 309 and returning the user data to the original user data and also shown in the first embodiment mode. The descramble circuit 310 includes the Maximum length sequence generator of a fixing seed and a random seed descrambler. Reference numeral 1407 designates an ID deleting device for deleting the additional information such as ID, etc. added by the ID adder 1401 and required to make a record, and setting only the user data.

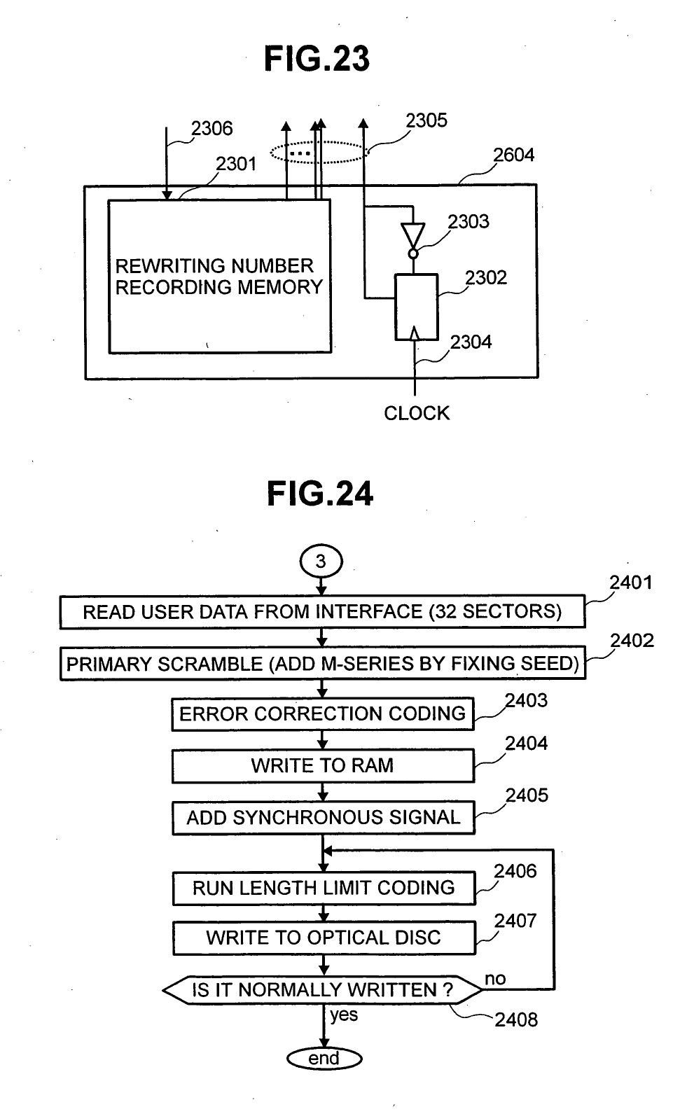

As shown in FIG. 23, a memory 2604 is constructed by a memory 2301 for recording a rewriting number read from tracks 3001 to 3002 of the optical disk 301, a 1-bit register 2302 and an inverter 2303. When a seed for the random seed scramble is required at a writing time of data, CLOCK 2304 is inputted and the value of the 1-bit register 2302 is inverted. 8 bits provided by adding lower 7 bits of the rewriting number of a written ECC block recorded to the rewriting number recording memory 2301 and the value of the 1-bit register 2302 are outputted to the scramble circuit 2601 as the seed of the random seed scramble.

Next, in this third embodiment mode, the scramble is again performed by using a second seed to obtain a series of preferable run length limit codes. When the seed for the rescramble is required, the CLOCK 2304 is again inputted, and the value of the 1-bit register 2302 is inverted. 8 bits provided by adding lower 7 bits of the rewriting number of the written ECC block recorded to the rewriting number recording memory 2301 and the value of the 1-bit register 2302 are outputted to the scramble circuit 2601 as the seed of the random seed scramble. The first seed and the second seed first given are inverted with respect to only a lower 1 bit. This seed generator is one example, and the seed of four or more combinations may be also able to be selected in one writing by setting the shift register 2302 to two bits or more.

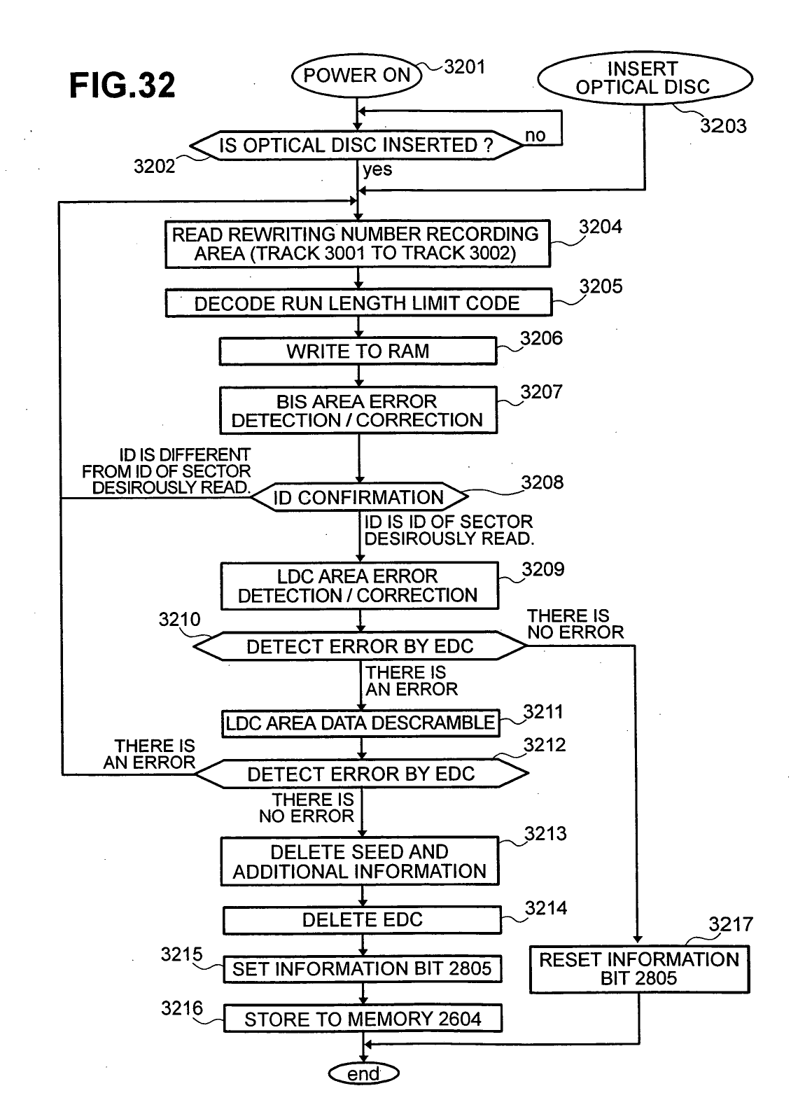

The operation of the optical disk device shown in FIG. 28 will next be explained. This operation at a power turning-on time or an insertion time of the optical disk will first be explained on the basis of FIG. 32. First, when the power of the optical disk device is turned on (step 3201), the optical disk device 2801 confirms whether the optical disk 301 is inserted into this device (step 3202). If no optical disk 301 is inserted, the step 3202 is repeated and the optical disk device waits for the insertion of the optical disk 301. When the optical disk is inserted (step 3203), rewriting number information of the ECC block of the entire disk written to a rewriting number recording area (tracks 3001 to 3002) is read (step 3204). First, the run length limit code is decoded (step 3205), and is stored to the RAM 1402 (step 3206). An error correction of the BIS area is then made (step 3207), and ID written to the BIS area is confirmed (step 3208). In this third embodiment mode, since no BIS area is scrambled, no descramble processing is performed.

If the ID is that of the rewriting number recording area, the error correction of the LDC area is made (step 3209), and an error is detected by the EDC (step 3210). When no error is detected by the EDC, no inserted optical disk corresponds to the random seed scramble with the rewriting number as one portion of the seed so that an information bit 2805 is reset (step 3217) and it is terminated. In contrast to this, when the error is detected by the EDC, the data are descrambled (step 3211), and the error detection is again performed by the EDC (step 3212). When the error is detected by the EDC, the processing is again performed from the step 3204. In contrast to this, when no error is detected by the EDC, the added seed, ID information, etc. are deleted (step 3213), and the EDC is deleted (step.3214). Further, the information bit 2805 is set (step 3215), and the data of the rewriting number are stored to the memory-2604 (step 3216). The operation of the optical disk device at the power turning-on time or the disk insertion time is then terminated, and the optical disk device waits for the instruction of commands from the host interface.

The operation of the optical disk device at a recording time will next be explained with reference to the format shown in FIG. 22 and the processing procedures at the recording time shown in FIGS. 33, 34 and 24.

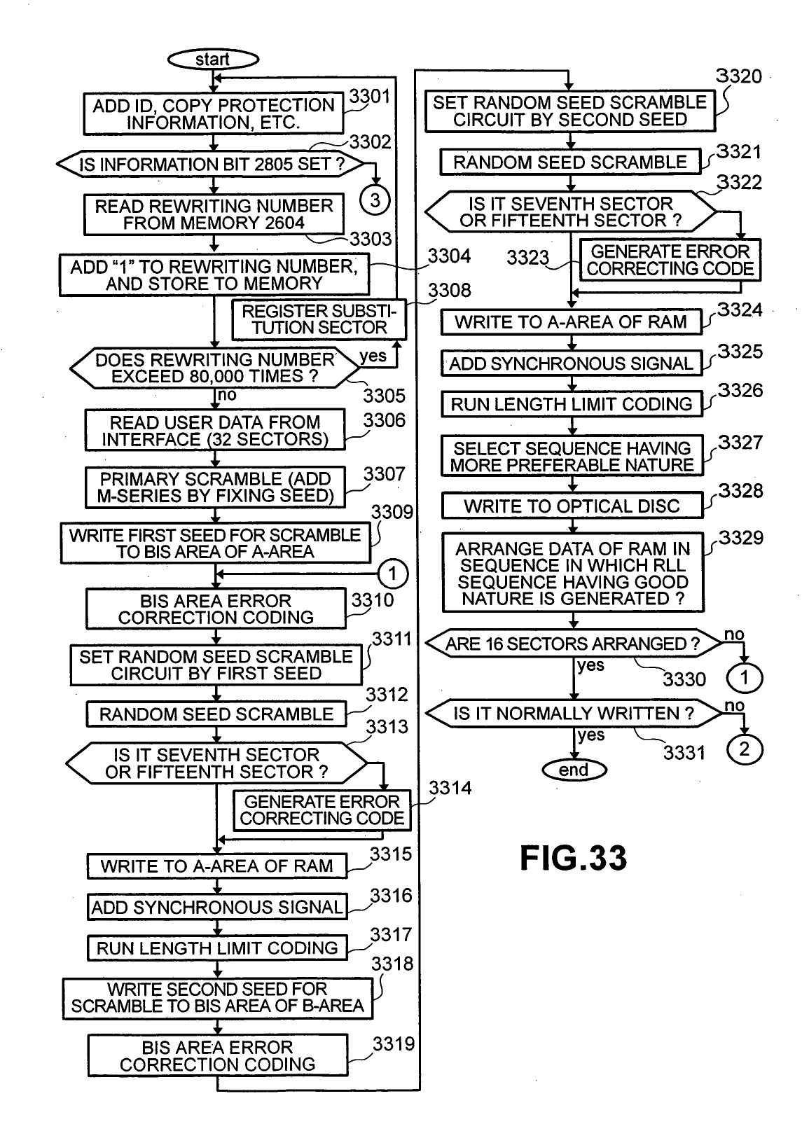

First, as shown in FIG. 33, when information about a written sector is given from the interface 311, the ID adding circuit 1401 generates additional information such as identification address information of data of ID, etc., copy protection information, reserve information, etc., and inputs the additional information to the error correction coding circuit 307. The ID adding circuit 1401 further stores the additional information to a storing place in the BIS area of areas A2802 and B2803 of the RAM 1402 (step 3301). As shown in FIG. 22, each of the areas A2802 and B2803 is divided so as to store data, and the additional information is stored to the BIS area shown by each of 1005, 1006 and 1007. A seed storing area 2201 for storing the seed of the random seed scramble is arranged in the BIS area, and is made such that the seed of 1 byte can be stored to two physical blocks. Next, if no optical disk intended to be written at present corresponds to the random seed scramble with reference to the information bit 2805 (step 3302), it proceeds to a step 2401 of FIG. 24. After the user data of 32 sectors are then read from the interface 311, a primary scramble using a fixing seed is performed (step 2402), and error correction coding is performed (step 2403). Thereafter, a writing operation to the RAM 1402 is performed (step 2404), and a synchronous signal is added (step 2405), and run length limit coding is then performed (step 2406). The run length limit code is then written to the optical disk 301 via the LD driver 1405 and the optical pickup 302 (step 2407).

Thereafter, the written data are read and compared with the data of the RAM as to whether the data are normally written to the optical disk (step 2408). When the data of 1 ECC block are normally recorded onto the optical disk 301, the processing is terminated. However, when it is unsuccessful in the record for a certain reason during the record of the data, the processing is again performed from the step 2406. Namely, the processing is again performed from the conversion of the data of the RAM 1402 to the run length limit code.

When the information bit 2805 is set and the optical disk 301 written at present corresponds to the random seed scramble, the rewriting number corresponding to the written ECC block is first read from the memory 2604 (step 3303), and “1” is added to the rewriting number and the added number is stored to the memory 2604 (step 3304). At this time, when the rewriting number exceeds a constant value, e.g., 80,000 times, replacement processing with a different physical sector is performed by supposing that reliability is reduced by deterioration of the medium. Therefore, replacing sector processing (step 3308) is performed, and it is again returned to-the step 3301, and the ID, etc. are re-added and the record processing is again performed. When the rewriting number is a constant value or less, the user data of 32 logic sectors are read from the interface 311 (step 3306), and are first sent to the scramble circuit 2601, and the primary scramble is performed by adding an Maximum length sequence by the fixing seed using one portion of the ID, etc. (step 3307). The processing after the step 3309 is performed of two physical blocks each. One physical block shows 31 stages (one stage corresponds to 1 byte in the longitudinal direction) in FIG. 22.

The processing case of first two physical blocks will first be explained. A first seed constructed by lower 7 bits of the rewriting number added by “1” and the output of the 1-bit register 2302 is stored to a seed (uppermost seed) with the physical block processed at present as one of seeds 2201 shown in FIG. 22 within an area A2802 of the RAM 1402 (step 3309). Next, the data of the BIS area within the first two physical blocks processed at present are changed to [62, 30, 33] RS codes by the error correction coding circuit 307 (step 3310). Next, the shift register of the random seed scramble circuit is set by the first seed (step 3311). The user data of the first two physical blocks are then random-seed-scrambled. At this-time, the random seed scramble is performed in the order of the arrow 1009 of the recording-regenerating order shown in FIG. 22 (step 3312). When the physical block being processed is seventh and eighth sectors or fifteenth and sixteenth sectors (step 3313), the user data are intermediately interrupted so that the user data are changed to [248, 216, 33] RS codes (step 3314) and are written to the area A2802 of the RAM 1402 (step 3315). A synchronous signal is then added (step 3316), and the run length limit coding is performed (step 3317).

Next, a second seed inverted in only a lower 1 bit with respect to the first seed is stored to the seed (uppermost seed) within the physical block processed at present as one of seeds 2201 shown in FIG. 22 within an area B2803 of the RAM 1402 (step 3318). The data of the BIS area within the first two physical blocks processed at present are changed to [62, 30, 33] RS codes by the error correction coding circuit 307 (step 3319). Next, a shift register of the random seed scramble circuit is set by the second seed (step 3320). The user data of the first two physical blocks are then random-seed-scrambled. At this time, the random seed scramble is performed in the order of the arrow 1009 of the recording-regenerating order shown in FIG. 22 (step 3321). When the physical block being processed is seventh and eighth sectors or fifteenth and sixteenth sectors (step 3322), the user data are intermediately interrupted so that the user data are changed to [248, 216, 33] RS codes (step 3323) and are written to the area B2803 of the RAM 1402 (step 3324). A synchronous signal is then added (step 3325), and the run length limit coding is performed (step 3326). A preferable sequence in nature among the sequences of the two run length limit codes made in the steps 3317 and 3326 is selected (step 3327), and is written to the optical disk 301 via the LD driver 1405 and the optical pickup 302 (step 3328).

Here, various methods such as the following three methods, etc. are considered as a selecting method of the preferable sequence in nature. (1) A sequence for providing small sizes of a maximum mark and a maximum space is selected. (2) A sequence for providing a low value of a low frequency component of the code is selected. (3) A sequence for providing small generation frequencies of a minimum mark and a minimum space is selected.

When the selected sequence is next generated from the second seed, the seed and the random-seed-scrambled sequence are next transferred from the area B2803 of the RAM 1402 to the area A2802. In contrast to this, when the selected sequence is generated from the first seed, the seed and the random-seed-scrambled sequence are transferred from the area A2802 of the RAM 1402 to the area B2803 (step 3329). This operation is repeated until the processing of 1 ECC block is terminated (step 3330). After the processing of the 1 ECC block is terminated, the written data are read and compared with the data of the RAM as to whether the data are normally written to the optical disk (step 3331). When the data of the 1 ECC block are normally recorded onto the optical disk 301, the processing is terminated.

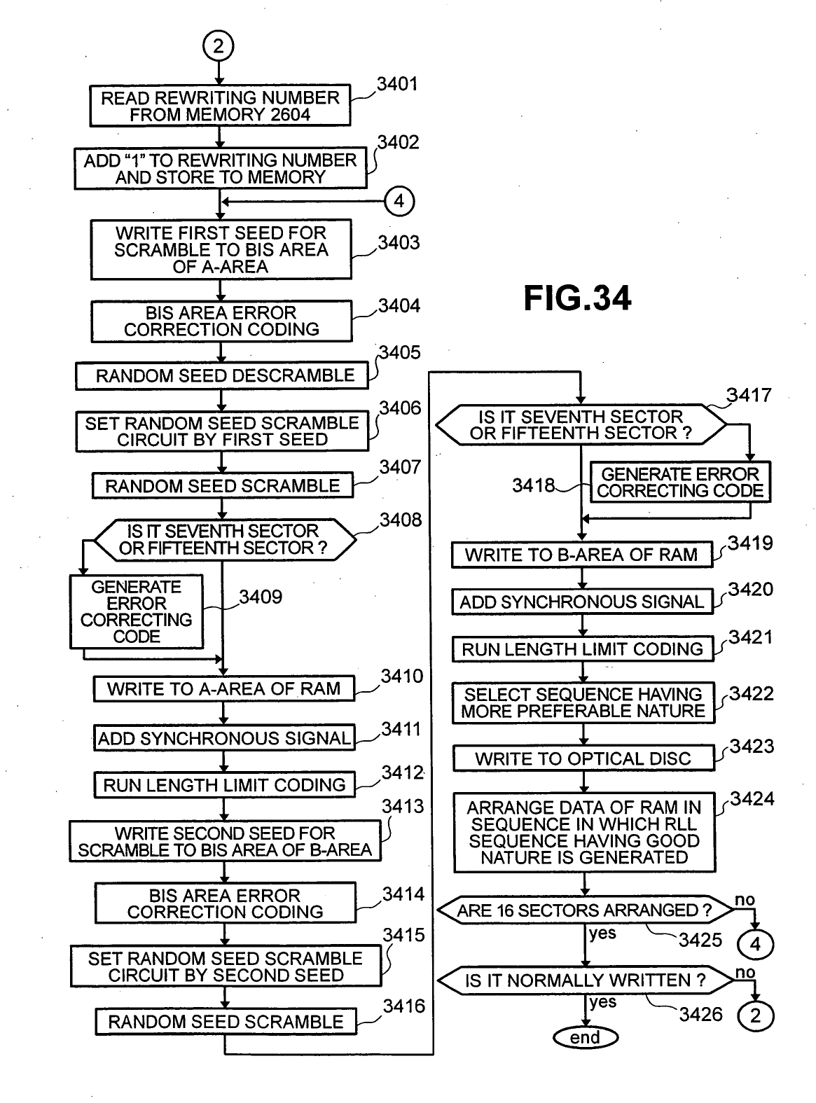

However, when it is unsuccessful in the record for a certain reason during the record of the data, deterioration of the medium is caused when the same data are written to the same place. Accordingly, in this case, the scramble is again performed by changing the seed, and the data are rewritten. Namely, the processing shown in FIG. 34 is performed. First, the rewriting number of the corresponding ECC block stored to the memory 2604 is read (step 3401), and “1” is added to the rewriting number, and the added number is stored to the memory 2604 (step 3402). The first seed constructed by lower 7 bits of the rewriting number and the output of the 1-bit register 2302 is stored to a seed (uppermost seed) within the physical block processed at present as one of seeds 2201 shown in FIG. 22 within the area A2802 of the RAM 1402 (step 3403). At this time, since the rewriting number is added by one, the seed becomes a seed different from that at the first time at any time. Next, the data of the BIS area within the first two physical blocks processed at present are changed to [62, 30, 33] RS codes by the error correction coding circuit 307 (step 3404). Next, the random-seed-scrambled data of the first two physical blocks stored into the area A2802 of the RAM 1402 are descrambled (step 3405).

Next, the shift register of the random seed scramble circuit, is set by the first seed (step 3406). Next, the descrambled user data are random-seed-scrambled. At this time, the random seed scramble is performed in the order of the arrow 1009 of the recording-regenerating order shown in FIG. 22 (step 3407). When the physical block being processed is seventh and eighth sectors or fifteenth and sixteenth sectors (step 3408), the user data are intermediately interrupted so that the user data are changed to [248, 216, 33] RS codes (step 3409) and are written to the area A2802 of the RAM 1402 (step 34.10). Further, a synchronous signal is added (step 3411), and the run length limit coding is performed (step 3412). Next, a second seed inverted in only a lower 1 bit with respect to the first seed is stored to a seed (uppermost seed) within the physical block processed at present as one of seeds 2201 shown in FIG. 22 within the area B2803 of the RAM 1402 (step 3413).

Next, the data of the BIS area within the first two physical blocks processed at present are changed to [62, 30, 33] RS codes by the error correction coding circuit 307 (step 3414). Next, the shift register of the random seed scramble circuit is set by the second seed (step 3415). The user data obtained in the step 3405 is then random-seed-scrambled. At this time, the random seed scramble is performed in the order of the arrow of the recording-regenerating order shown in FIG. 22 (step 3416). When the physical block being processed is seventh and eighth sectors or fifteenth and sixteenth sectors (step 3417), the user data are intermediately interrupted so that the user data are changed to [248, 216, 33] RS codes (step 3418) and a rewritten to the area B2803 of the RAM 1402 (step 3419). Further, a synchronous signal is added (step 3420), and the run length limit coding is performed (step 3421). A preferable sequence in nature among the sequences of the two run length limit codes made in the steps 3412 and 3421 is selected (step 3422), and is written to the optical disk 301 via the LD driver 1405 and the optical pickup 302 (step 3423).

Next, when the selected sequence is generated from the second seed, the seed and the random-seed-scrambled sequence are transferred from the area B2803 of the RAM 1402 to the area A2802. In contrast to this, when the selected sequence is generated from the first seed, the seed and the random-seed-scrambled sequence are transferred from the area A2802 of the RAM.1402 to the area B2803 (step 3424). This operation is repeated until the processing is terminated by 1 ECC block (step 3425). When the processing is terminated by the 1 ECC block, the written data are read and compared with the data of the RAM as to whether the data are normally written to the optical disk (step 3426). When the data of the 1 ECC block are normally recorded onto the optical disk 301, the processing is terminated.

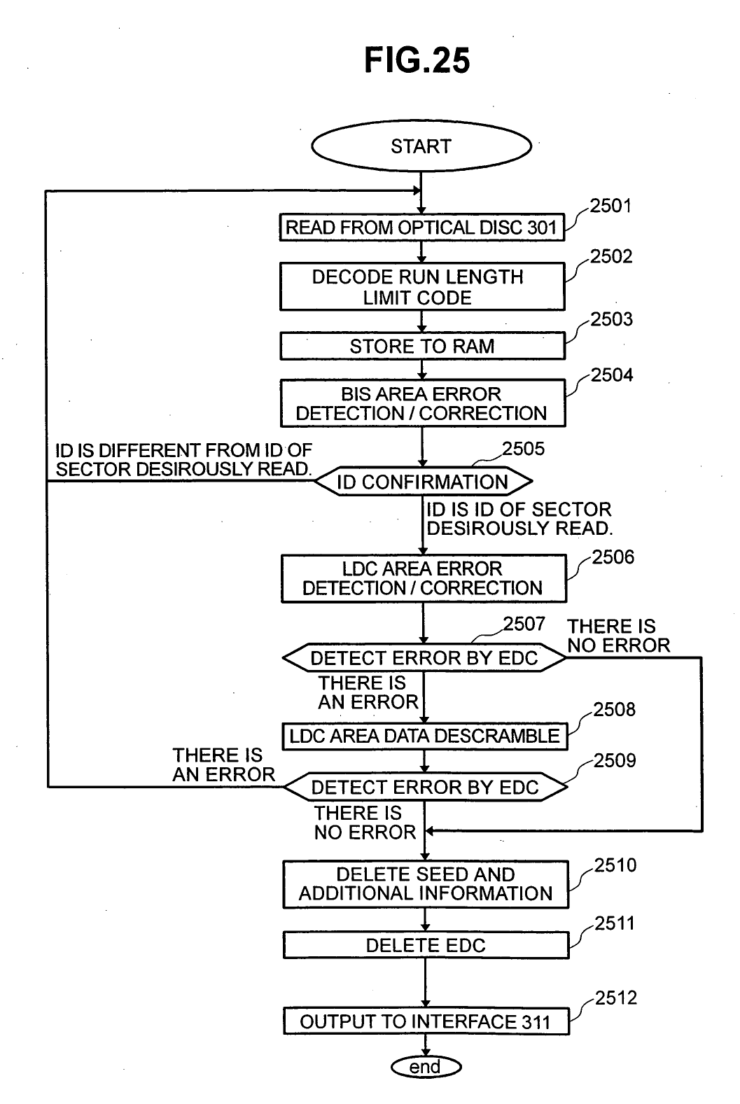

The operation of the optical disk device at a regenerating time will next be explained with reference to the processing procedure of FIG. 25. First, the optical disk device 2801 reads data from the optical disk (step 2501), and the run length limit code is first decoded (step 2502) and is stored to the RAM 1402 (step 2503). An error correction of the BIS area is then made (step 2504)., and ID written to the BIS area is confirmed (step 2505). In this third embodiment mode, no descramble processing is performed since no BIS area is scrambled. If the ID is the ID of the ECC block in a reading request, the error correction of the LDC area is made (step 2506), and the error is detected by the EDC (step 2507). When no error is detected by the EDC, it proceeds to a step 2510. In contrast to this, when the error is detected by the EDC, the data are descrambled (step 2508), and the error detection is again performed by the EDC (step 2509). When the error is detected by the EDC, the processing is again performed from the step 2501. In contrast to this, when no error is detected by the EDC, added seed, ID information, etc. are deleted (step 2510), and the EDC is deleted (step 2511), and the user data decoded from the interface 311 are outputted (step 2512). When a random-seed-scrambled area and an area not random-seed-scrambled are mixed and exist in one disk, the reading operation can be simply performed by such control without particularly arranging a special bit, etc. in a format showing this mixture.

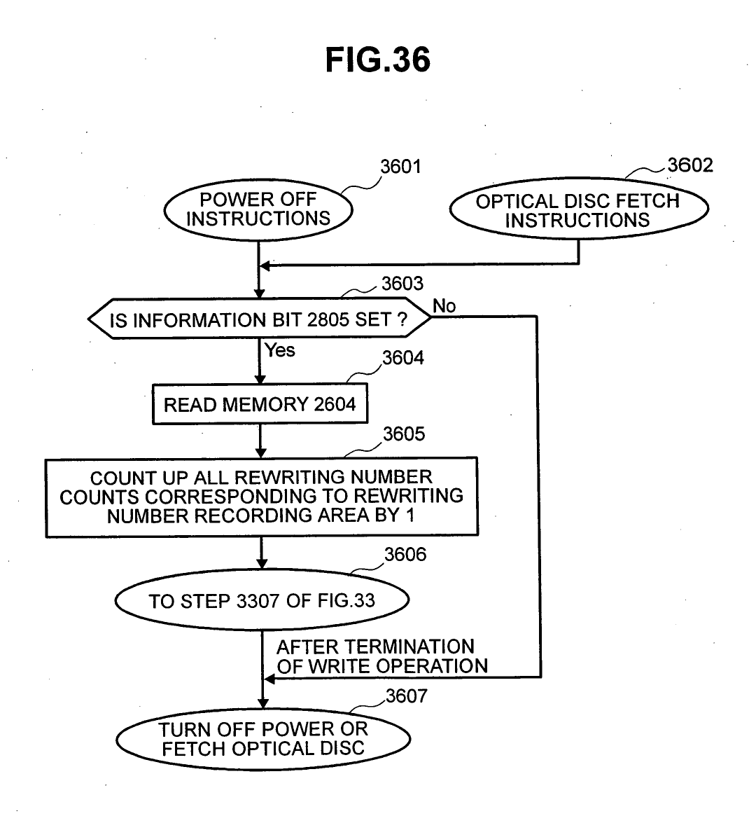

Next, the operation of the optical disk device at the power turning-off time and the optical disk fetching time will be explained with reference to the processing procedure shown in FIG. 36. At the generating time of power turning-off instructions or optical disk fetching instructions, the optical disk device 2801 first refers to an information bit 2805 (step 3603). When the information bit 2805 is cleared, it proceeds to a step 3606. In contrast to this, when the information bit 2805 is set, data of the memory 2604 are read (step 3604), and all rewriting number counts corresponding to the rewriting number recording area are counted up by one (step 3605). Thereafter, the rewriting number stored to the memory 2604 is written from a track 3001 of the disk 301 to a track 3002 in accordance with a writing sequence after the step 3307 of the writing sequence of FIG. 33 (step 3606). Thereafter, the optical disk is taken out and the power is turned off (step 3606).

As shown in this third embodiment mode, after plural RLL sequences are generated, one sequence having preferable characteristics is selected. Thus, a technique for making the disk from the sequence of good nature is particularly effective in a ROM disk making device. A construction similar to that in this third embodiment mode can be used in the ROM disk making device.

Further, in accordance with the third embodiment mode, a run length code sequence of better nature can be obtained by selecting this sequence from plural sequences.

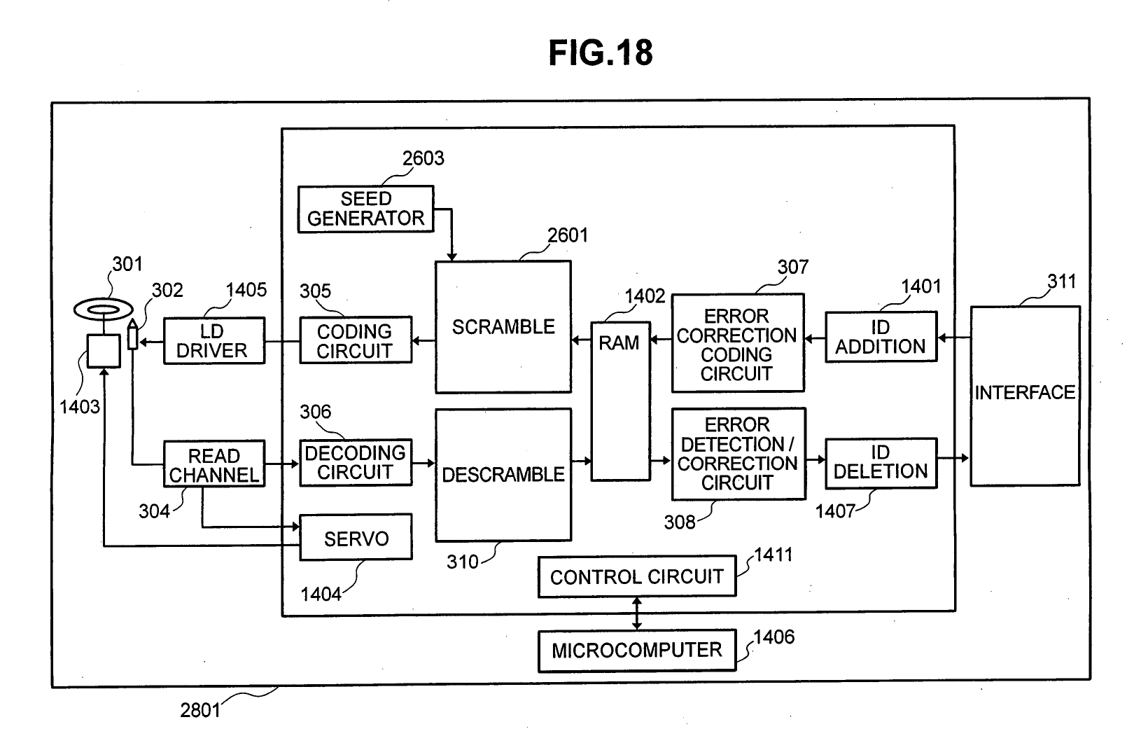

Next, a fourth embodiment mode will be explained with reference to FIGS. 18 and 13. FIG. 18 is a schematic block diagram of an optical disk device 2801 shown in this fourth embodiment mode. Reference numeral 311 designates an interface for performing input-output control of data with respect to an upper device. Reference numeral 1406 designates a microcomputer for generalizing a system. The microcomputer 1406 is connected to a control circuit 1411 within the system. The control circuit 1411 controls the operations of a seed generator 2603, an error correction coding circuit 307, a scrambler 2601, etc. through an unillustrated control line. Reference numeral 1401 designates an ID adder for adding additional information such as ID, etc. required to make a record to user data given by the interface 311. Reference numeral 307 designates an error correction coding circuit for adding an error correcting code to the user data. Reference numeral 1402 designates a memory (RAM) for temporarily storing data. Reference numeral 2601 designates a scrambler for randomizing data. This scrambler is explained in the first embodiment mode, and includes an Maximum length sequence generator of a fixing seed and a random seed scrambler. Reference numeral 305 designates a coding circuit for converting the scrambled user data to a run length limit code suitable for the record to the optical disk 301. Reference numeral 302 designates a pickup for recording/regenerating data of the optical disk 301. Reference numeral 1403 designates a spindle motor for rotating the disk.

Reference numeral 1404 designates a servo for controlling the operation of the optical pickup 302,etc. Reference numeral 304 designates a read channel for performing waveform equalization processing of an analog regenerating signal read from the optical disk 301, a binary operation and synchronous clock generation. Reference numeral 306 designates a decoder for decoding a read run length limit code. Reference numeral 310 designates a descramble circuit for releasing the randomization performed by the scrambler 309 and returning user data to the original user data and also shown in the first embodiment mode. The descramble circuit 310 includes an Maximum length sequence generator of a fixing seed and a random seed descrambler. Reference numeral 308 designates an error detection-correction circuit for detecting an error on the basis of an error correcting code added by the error correction coding circuit 307, and correcting the error. Reference numeral 1407 designates an ID deleting circuit for deleting additional information such as ID, etc. required to make a record and added by the ID adder 1401, and setting only the user data. Reference numeral 2603 designates a seed generator for generating and giving a new seed to the scrambler 309 every writing processing.

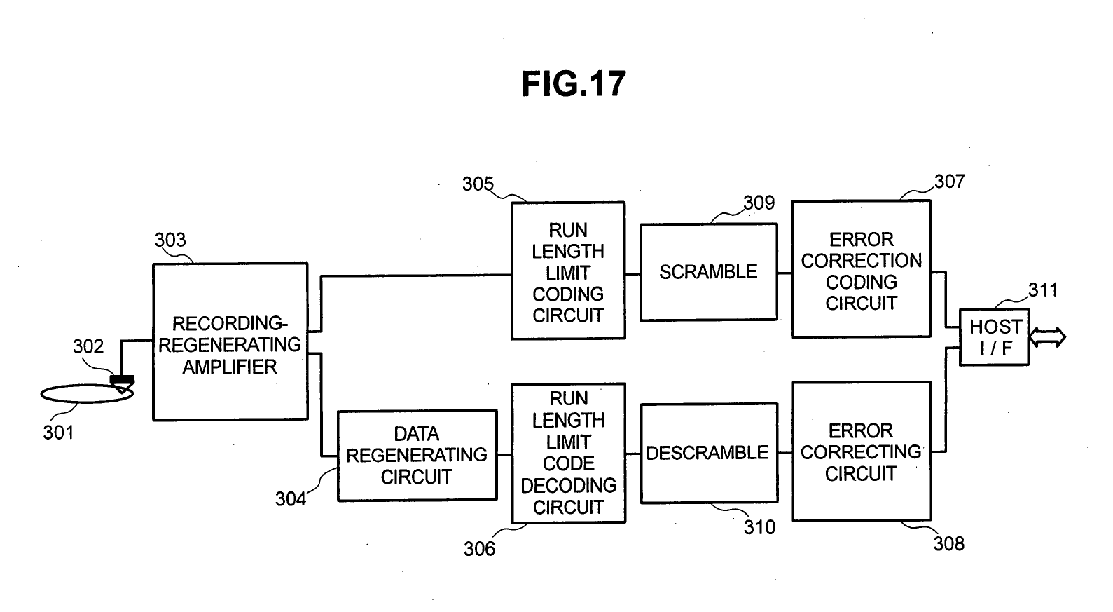

The operation of the optical disk device shown in FIG. 18 will next be explained with reference to FIG. 17. First, at a recording time, additional information such as ID, etc. required to make a record is added to user data inputted from the host interface 311 by the ID adder 1401. Thereafter, the added user data are changed to an error correcting code by the error correction coding circuit 307, and are stored to the RAM 1402 in accordance with the format shown in FIG. 12. Thereafter, the stored data are read in the unit of a physical sector, and are scrambled by a fixing seed. Thereafter, the seed given from the seed generator 2603 is added to the head of the data read from the RAM, and the random seed scramble is performed. Run length limit coding is then performed by the run length limit coding circuit 305, and the run length limit code is written to the optical disk 301. Thereafter, it is confirmed by reading the data whether the data are normally written to the optical disk. When no data are normally written to the optical disk, the data stored to the RAM 1402 are again scrambled by using the fixing seed, and the random seed scramble is performed by changing the seed. The run length limit coding is then performed by the run length limit coding circuit 305, and the run length limit code is written to the optical disk 301. When the run length limit code is written to the optical disk, the run length limit code is written in accordance with the format shown in FIG. 13. Namely, seed 1 byte 3708 after the scramble is written to generate a sector after Header 3702 and Mirror 3703 formed on the optical disk, Gap 3704 for absorbing the shift of writing start timing, Guard 3705, VFO area 3706 for generating a regenerating clock, and PS 3707 for taking byte synchronization.

Thereafter, the user data are written in accordance with the format of FIG. 12. With respect to the storing place of the seed, the seed may be buried into an unused area among BIS areas 1005, 1006, 1007 shown in FIG. 12. Next, the operation of the optical disk device at the regenerating time will be explained. At the regenerating time, data read from the optical disk are first decoded by the run length limit code decoding circuit 306, and the seed is taken out of the head position 3708 of the data or the BIS areas 1005, 1006, 1007. The random seed descramble and the descramble of the fixing seed scramble are then performed by the descramble circuit 310, and the descrambled data are stored to the RAM 1402 (step 3206). Error correction processing is then performed by the error correcting circuit 308, and added ID information, etc. are deleted and the remaining data are outputted to the host interface.

As shown in this embodiment mode, error correction coding processing can be omitted in rewriting processing by performing the random seed scramble on the medium side from the error correcting circuit. Accordingly, the rewriting processing can be executed at high speed.

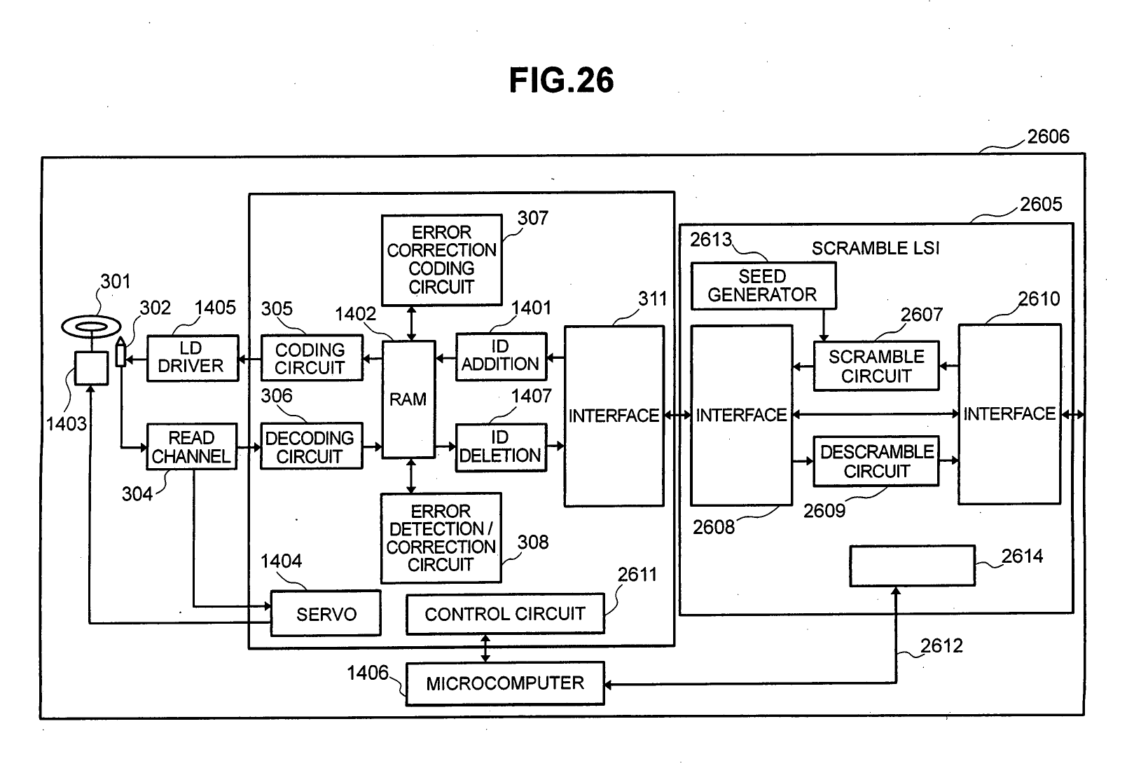

Next, a fifth embodiment mode will be explained with reference to FIG. 26. In the fifth, sixth and seventh embodiment modes, a method for applying the random seed scramble to the optical disk device controlled by the existing optical disk control LSI building-in the error correction coding circuit, etc. will be described. First, in the fifth embodiment mode, a scramble LSI 2605 for performing the random seed scramble processing is arranged on the host interface side from the optical disk control LSI 2611. The scramble LSI 2605 includes an interface 2610 for performing data input-output control with respect to the host computer, a scramble circuit 2607, a descramble circuit 2609, and an interface circuit 2608 for outputting a signal similar to that of the interface circuit of the host computer, and performing data input-output control with respect to the interface circuit 311 of the optical disk control LSI 2611. A seed generator 2613, the scramble circuit 2607 and the descramble circuit 2609 are the same as those explained in the second embodiment mode. A microcomputer 1406 is connected to a control circuit 2614 within the scramble LSI 2605, and this control circuit 2614 controls the operations of the seed generator 2613, the scramble circuit 2607, etc. through an unillustrated control line.

The operation of the optical disk device at the recording time will next be explained. When information such as the size of data, the ID of a recording place, etc. with respect to a written sector is first given from the interface 311, information given to the optical disk control LSI 2611 is transmitted as it is through the interface 2608. Next, when the user data of a first one logic sector (2048 bytes) is received from the interface 2610, the seed generator 2613 generates a new seed, and transmits this new seed to the scramble circuit 2607. The scramble circuit 2607 adds the seed to the head of the user data of one logic sector and performs the scramble. First 1 byte of the sequence after the scramble is read by the microcomputer 1406, and the subsequent sequence of 2048 bytes after the scramble is transferred to the optical disk control LSI 2611 through the interface 2608. Next, when the user data of a second 1 logic sector (2048 bytes) are received and this logic sector is data to be written to the same ECC block as the above first logic sector, no seed generator 2613 generates a new seed.

When this logic sector is data to be written to the ECC block different from the above first logic sector, the seed generator 2613 generates a new seed. Thus, the user data of 1 ECC block are read. The optical disk control LSI 2611 generates additional information 720 byte such as identification address information of data of ID, etc., copy protection information, reserve information, etc. from the above sector information by the ID adder 1401, and writes the generated additional information to the RAM 1402 in the format shown in FIG. 12. The additional information is written to three BIS areas 1005, 1006, 1007 shown in FIG. 12. The microcomputer 1406 writes first 1 byte of the sequence previously scrambled and read to a reserve area written by a fixing value within the above additional information 720 byte within the BIS areas 1005, 1006, 1007 of the RAM 1402. The additional information 720 byte including the 1 byte written by the microcomputer 1406 is divided into 24 pieces of 30 bytes each. The error correction coding circuit 307 changes these data of 30 bytes each to [62, 30, 33] RS codes, and stores the respective RS codes to the three BIS areas 1005, 1006, 1007 of the RAM 1402 shown in FIG. 12 of 8 code words each.

Next, the user data 1101 of 2048 bytes (corresponding to 1 logic sector) are read from the interface 311. The ID adder 1401 adds an error detection code (EDC) of 4 bytes to the user data inputted from the interface 311, and stores the added data to the RAM 1402. Next, these data are transferred to the error correction coding circuit 307, and are changed to [248, 216, 33] RS (Reed Solomon) codes of 216 bytes each, and are stored to four LDC areas 1001, 1002, 1003, 1004 of the RAM 1402 shown in FIG. 12. After the user data of 1 ECC block are read and the error correction coding is performed, a synchronous signal (SYNC code) 1008 is further added to the left-hand end of the error correction code. Next, the coding circuit 305 reads data from the RAM 1402 in accordance with the arrow 1009 shown in FIG. 12 and showing the recording-regenerating order, and continuously reads data at 31 stages (one stage corresponds to 1 byte in the longitudinal direction) as a “physical sector” of 4 k bytes, and changes these data to a run length limit code. The run-length-limit-coded data of 4 k bytes are written to the optical disk 301 via the LD driver 1405 and the optical pickup 302.

Next, the processing procedure at the regenerating time will be explained. At the regenerating time, data are read from the optical pickup 302, and a binary operation is performed and a synchronous clock is generated in the read channel 304. In the decoding circuit 306, the decoding operation is performed from the run length limit code, and regenerated data are temporarily stored to the RAM 1402 in accordance with the arrow 1009 shown in FIG. 12. The error detection/correction circuit 308 first performs error correction processing of additional information 720 byte such as ID, etc. including first 1 byte of a sequence scrambled and stored to the BIS area shown in FIG. 12. Next, it is confirmed whether the ID written to the BIS area performed with respect to the error correction processing is the ID of an ECC block intended to be regenerated. Here, if the ID is the ID of the ECC block or a sector desirously read, the microcomputer 1406 first reads the first 1 byte of the scrambled sequence stored to the BIS area, and returns the data of the RAM storing this 1 byte thereto to a fixing value of the reserve area. Then, the error correction processing of the LDC area is performed, and the additional information 720 byte such as ID, etc. is deleted by the ID deleting circuit 1407, and an error is checked by using the EDC. Thereafter, the user data 2048 byte are transferred to the descramble circuit 2609 via the interfaces 311, 2608. The microcomputer 1406 adds the first 1 byte of the scrambled sequence read from the BIS area to the head of the user data 2048 byte, and performs the descramble. The descrambled sequence is transferred from the interface 2610 to the host computer.

Thus, in accordance with the construction of the fifth embodiment mode, the scramble is released after the error correction processing is terminated. Accordingly, no deterioration of error correction ability due to error propagation of the random seed scramble is generated. Further, in the fifth embodiment mode, the random seed scramble processing is performed by using the same seed in each logic sector in the 1 ECC block. However, a method for continuously scrambling the 1 ECC block 64 K bytes is also considered. Further, a method for performing the random seed scramble processing by using a different seed every logic sector is considered. In this case, it is necessary to secure an area of 32 bytes in the BIS area as an area for storing the head byte after the scramble.

Further, the error propagation is generated in the random seed scramble. Accordingly, when it is considered to remedy data as much as possible in the case of error correction disability, it is desirable to perform the scramble processing on the user side from the error correction coding.

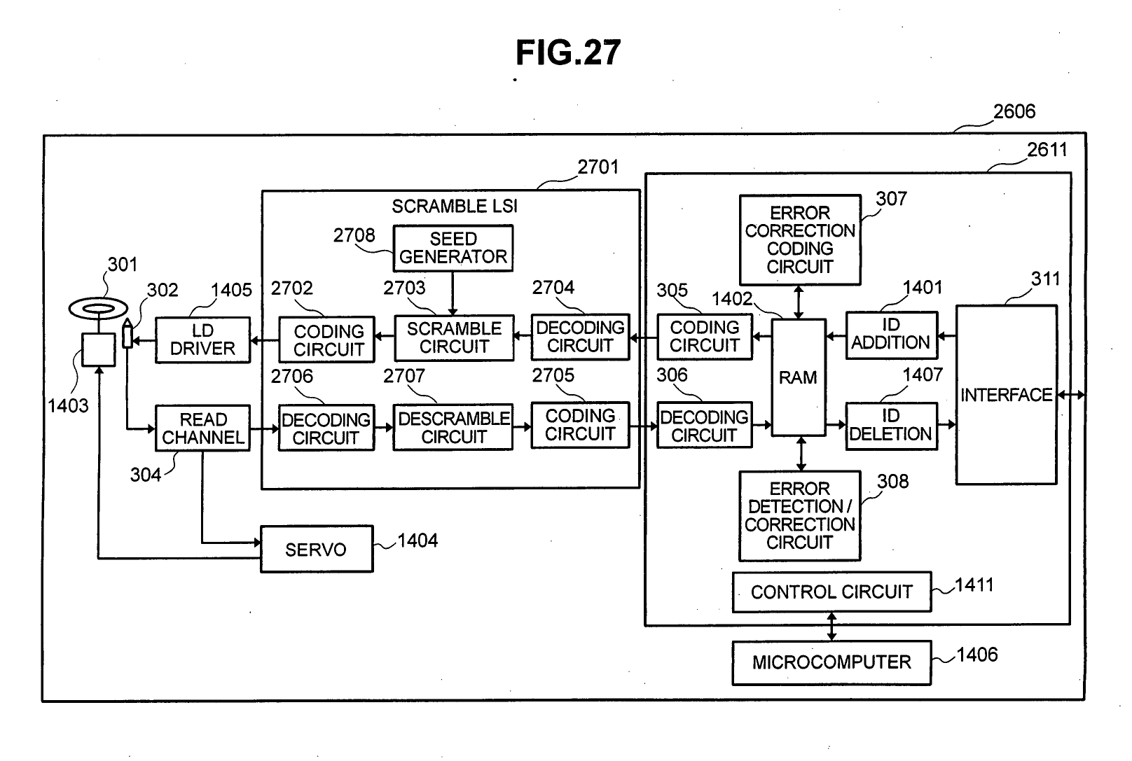

Next, a sixth embodiment mode will be explained with reference to FIG. 27. In the sixth embodiment mode, a scramble LSI 2701 for performing the random seed scramble processing is arranged closer to the optical disk medium side than the optical disk control LSI 2611. The scramble LSI 2701 includes decoding circuits 2704, 2706 of a run length limit code, coding circuits 2702, 2705, a scramble circuit 2703, a descramble circuit 2707, and a seed generator 2708. The scramble circuit 2703 and the descramble circuit 2707 are the same as those explained in the third embodiment mode. The seed generator is the same as that explained in the second embodiment mode.

The operation of the optical disk device at the recording time will next be explained. When information about a written sector is first given from the interface 311, the optical disk control LSI 2611 generates additional information 720 byte such as identification address information of data of ID, etc., copy protection information, reserve information, etc. from information about the above sector by the ID adding circuit 1401, and writes this additional information to the RAM 1402 in the format shown in FIG. 12. The additional information is written to three BIS areas 1005, 1006, 1007 shown in FIG. 12. The additional information 720 byte generated in the ID adding circuit 1401 is changed to [62, 30, 33] RS codes of 30 bytes each, and is divided into 24 pieces. The error correction coding circuit 307 changes these data of 30 bytes each to [62, 30, 33] RS codes, and stores the respective RS codes to the three BIS areas 1005, 1006, 1007 of the RAM 1402 shown in FIG. 12 of 8 code words each.

Next, the user data 1101 of 2048 bytes (corresponding to 1 logic sector) are read from the interface 311. The ID adder 1401 adds an error detection code (EDC) of 4 bytes to the user data inputted from the interface 311, and stores the added data to the RAM 1402. Next, these data are transferred to the error correction coding circuit 307, and are changed to [248, 216, 33] RS codes of 216 bytes each, and are stored to four LDC areas 1001, 1002, 1003, 1004 of the RAM 1402 shown in FIG. 12. After the user data of 1 ECC block are read and the error correction coding is performed, a synchronous signal (SYNC code) 1008 is further added to the left-hand end of the error correcting code.

Next, the coding circuit 305 reads data from the RAM 1402 in accordance with the arrow 1009 shown in FIG. 12 and showing the recording-regenerating order, and continuously reads data at 31 stages (one stage corresponds to 1 byte in the longitudinal direction) as a “physical sector” of 4 k bytes, and changes these data to a run length limit code. The run-length-limit-coded data of 4 k bytes are transferred to the scramble LSI 2701. The scramble LSI 2701 returns the run-length-limit-coded data of 4 k bytes to user data by the decoding circuit 2704. The seed of 1 byte generated by the seed generator 2708 is buried to a reserve area of the BIS area, and is used as a preset value of the random seed scrambler. The decoded user data are scrambled-processed by the scrambler 2703, and are then again changed to a run length limit code by the coding circuit 2702. The run length limit code is written to the optical disk 301 via the LD driver 1405 and the optical pickup 302.

Next, the processing procedure at the regenerating time will be explained. At the regenerating time, data are read from the optical pickup 302, and a binary operation is performed and a synchronous clock is generated in the read channel 304. In the decoding circuit 2706, the decoding operation is performed from the run length limit code, and the seed buried to the BIS area is taken out. The taken-out seed is used as a preset value of the random seed descrambler within the descramble circuit 2707. The descrambled sequence is again changed to a run length limit code by the coding circuit 2705, and is sent to the optical disk control LSI 2611. The optical disk control LSI 2611 again decodes the run length limit code, and temporarily stores regenerated data to the RAM 1402 in accordance with the arrow 1009 shown in FIG. 12. The error detection/correction circuit 308 first performs the error correction processing of additional information 720 byte such as ID, etc. stored to the BIS area shown in FIG. 12. Next, it is confirmed whether the ID written to the BIS area and performed with respect to the error correction processing is the ID of an ECC block intended to be regenerated.

Here, if the ID is the ID of the ECC block or a sector desirously read, the error correction processing of the LDC area is performed, and the additional information 719 byte such as ID, etc. is deleted by the ID deleting circuit 1407, and an error of the user data 2048 byte is checked by using the EDC. Thereafter, the user data 2048 byte are transferred to the host computer via the interface 311. Thus, in accordance with the construction of the sixth embodiment mode, the random seed scramble can be applied by adding the scramble LSI 2701 to the existing optical disk control LSI 2611.

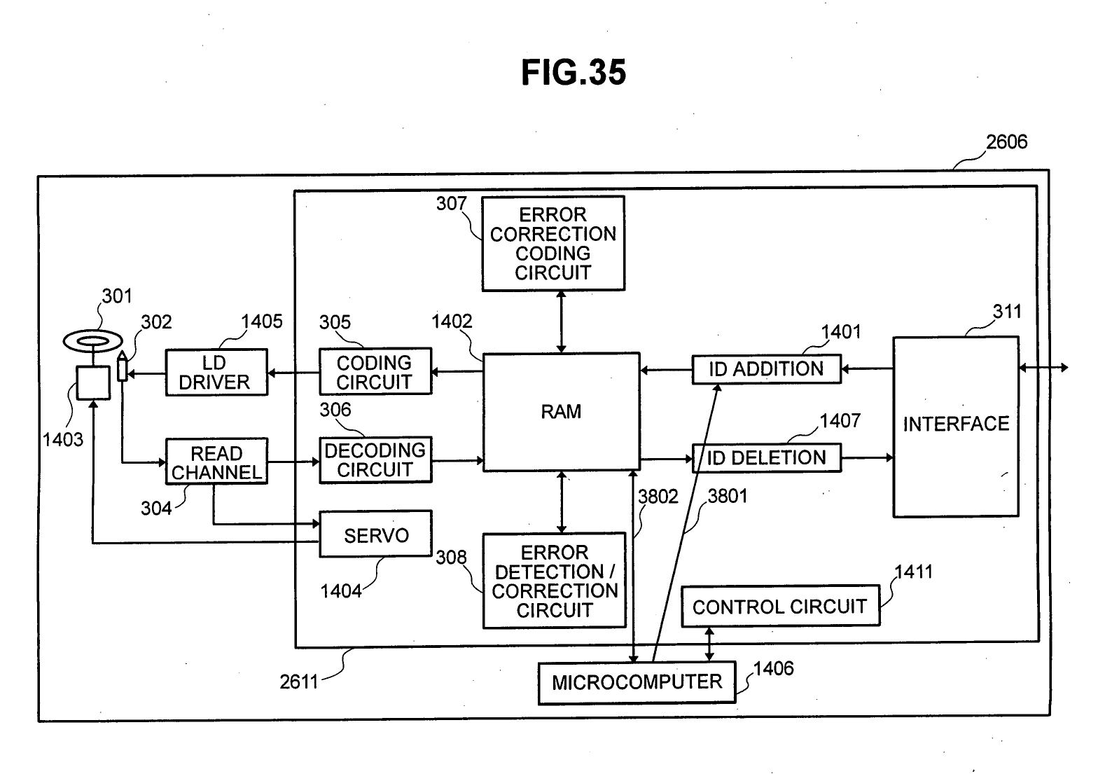

Next, a seventh embodiment mode will be explained with reference to FIG. 35. In the seventh embodiment mode, the random seed scramble processing is performed in software by the microcomputer 1406.

The operation of the optical disk device at the recording time will next be explained. When information about a written sector is first given from the interface 311, the optical disk control LSI 2611 generates additional information 720 byte such as identification address information of data of ID, etc., copy protection information, reserve information, etc. from the information about the above sector by the ID adding circuit 1401. The microcomputer 1406 determines a seed by making a calculation shown by the following formula 8.
SD(k)=(SDi k−1)+n)mod256 [Formula 8]
Here, k shows k-th seed generation, and n is a suitable prime number with respect to 256. The seed of 1 byte generated by the microcomputer 1406 is written to the reserve area within 720 bytes generated by the ID adding circuit 1401 through a control line 3801. The 720 bytes are divided into 24 pieces of 30 bytes each. The error correction coding circuit 307 changes these data of 30 bytes each to [62, 30, 33] RS codes, and stores the respective RS codes to three BIS areas 1005, 1006, 1007 of the RAM 1402 shown in FIG. 12 of 8 code words each.

Next, the user data 1101 of 2048 bytes (corresponds to 1 logic sector) are read from the interface 311. The ID adder 1401 adds an error correction code (EDC) of 4 bytes to the user data inputted from the interface 311, and stores these data to the RAM 1402. Next, the microcomputer 1406 performs the scramble by making a calculation shown by the following formula 2 with respect to the data stored to the RAM through a control line 3802.
cᵢ=bᵢ+cᵢ₋₄+cᵢ₋₅+cᵢ₋₆+cᵢ₋₈ [Formula 2]
In this calculation, bᵢ shows read i-th user data. The data are read from the head of the user data of the RAM 1402 every 1 bit, and the calculation is made by substituting these data for this bᵢ. Reference numeral cᵢ designates an i-th calculated result, and is a value after the scramble. The microcomputer 1406 writes the value of cᵢ to the RAM. The seed of 1 byte generated by the microcomputer is used as an initial value of c₀ from c-7 in calculating the formula 2.

After the scramble using the microcomputer 1406 is terminated, the scrambled data are transferred to the error correction coding circuit 307, and are changed to [248, 216, 33] RS (Reed Solomon) codes of 216 bytes each, and are stored to four LDC areas 1001, 1002, 1003, 1004 of the RAM 1402 shown in FIG. 12. After the user data of 1 ECC block are read and the error correction coding is performed, a synchronous signal (SYNC code) 1008 is further added to the left-hand end of the error correcting code. Next, the coding circuit 305 reads data from the area B1409 of the RAM 1402 in accordance with the arrow 1009 shown in FIG. 12 and showing the recording-regenerating order, and continuously reads data at 31 stages (one stage corresponds to 1 byte in the longitudinal direction) as a “physical sector” of 4 k bytes, and changes these data to a run length limit code. The run-length-limit-coded data of 4 k bytes are written to the optical disk 301 via the LD driver 1405 and the optical-pickup 302.

The processing procedure at the regenerating time will next be explained. At regenerating time, data are read from the optical pickup 302, and a binary operation is performed and a synchronous clock is generated in the read channel 304. The decoding circuit 306 performs the decoding operation from the run length limit code. Regenerated data are temporarily stored to the RAM 1402 in accordance with the arrow 1009 shown in FIG. 12. The error detection/correction circuit 308 performs the error correction processing of additional information 720 byte such as ID, etc. stored to the BIS area shown in FIG. 12. Next, it is confirmed whether the ID written to the BIS area and performed with respect to the error correction processing is the ID of an ECC block intended to be regenerated.

Here, if the ID is the ID of the ECC block or a sector desirously read, the error correction processing of the LDC area is performed. Next, the-microcomputer 1406 reads the seed written to the BIS area, and makes the calculation of the following formula 3 with respect to the user data stored onto the RAM.
bᵢ=cᵢ+cᵢ₋₄+cᵢ₋₅+cᵢ₋₆+cᵢ₋₈ [Formula 3]
The seed of 1 byte is used as an initial value of c₀ from c−7 in calculating the formula 3. Reference numeral bᵢ designates an i-th bit value after the scramble, and cᵢ is an i-th bit value from the head of a read sequence.

After the scramble is terminated, the additional information 720 byte such as ID, etc. is deleted by the ID deleting circuit 1407. Thereafter, an error of the user data 2048 byte is checked by using the EDC. Thereafter, the user data 2048 byte are transferred to the host computer via the interface 311. Thus, in accordance with the construction of the seventh embodiment mode, the random seed scramble can be applied by the processing of only software without changing the existing optical disk control LSI 2611. Therefore, in a system mounting the existing optical disk control LSI thereto, the random seed scramble can be applied by making a small change.

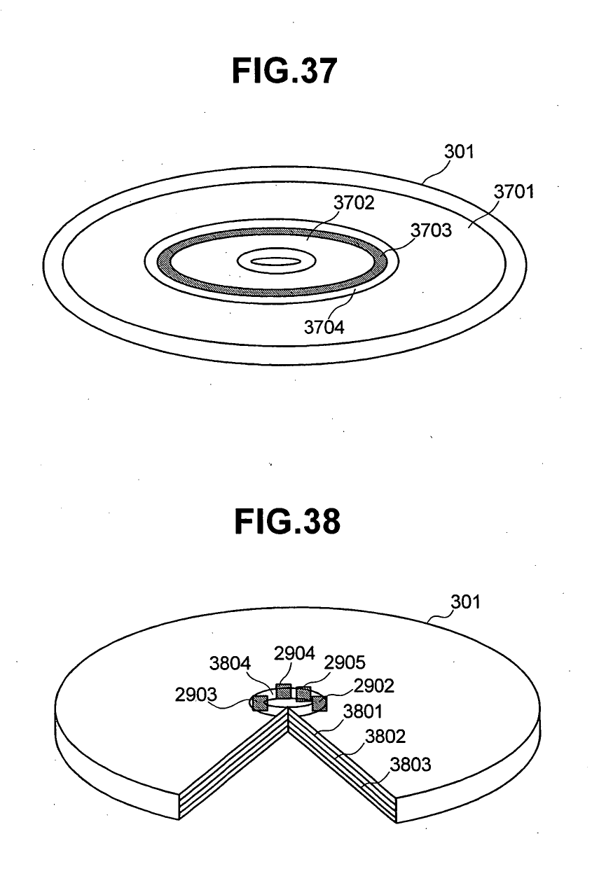

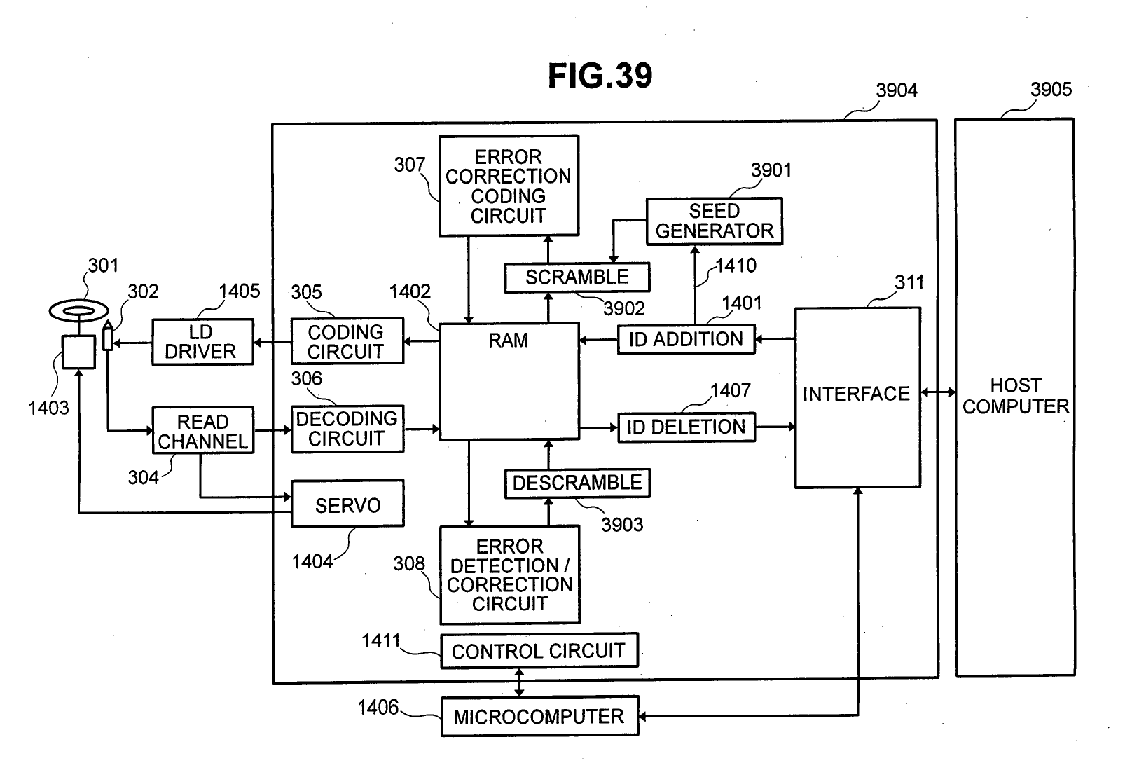

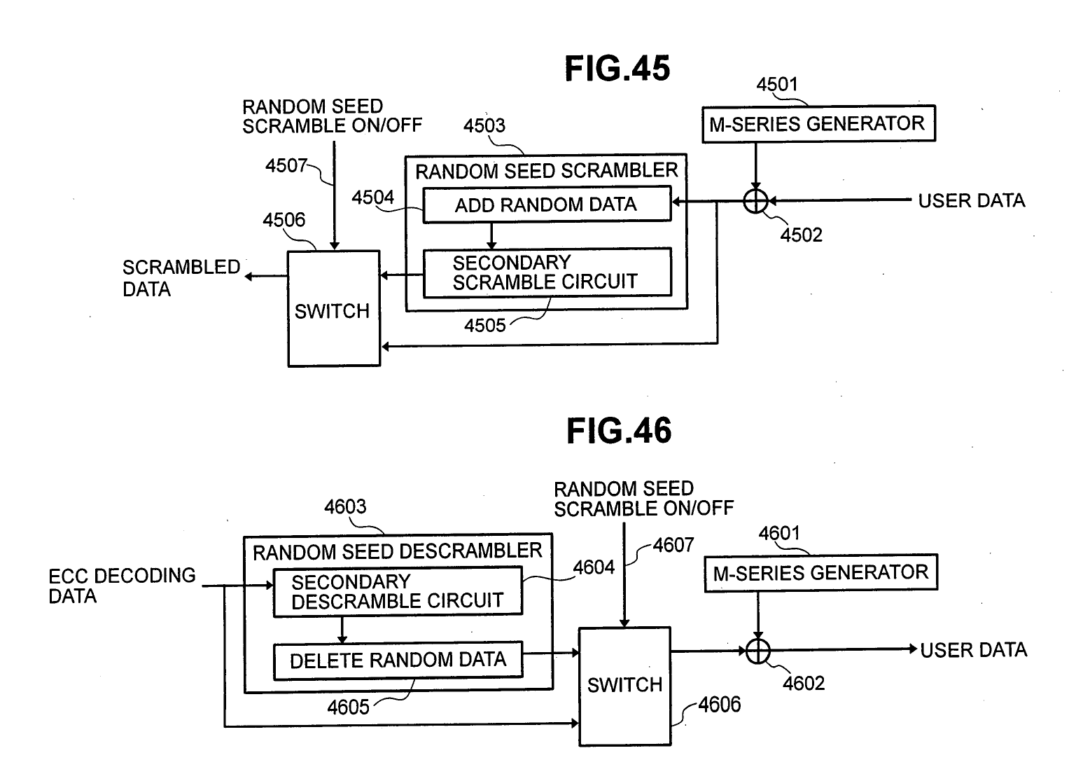

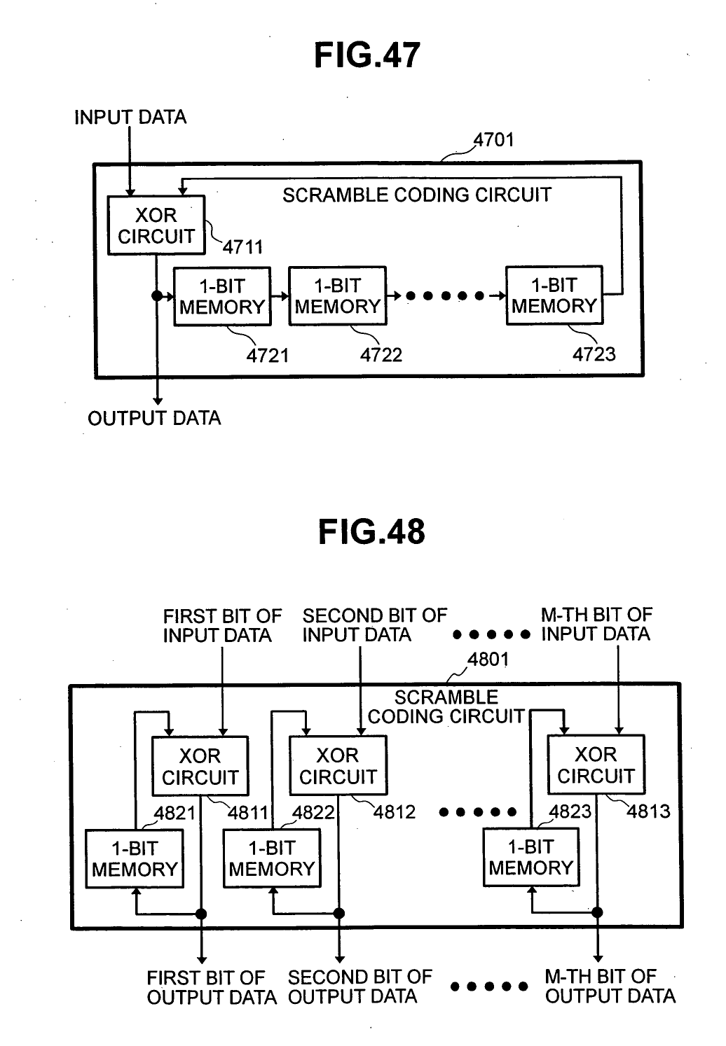

Next, an eighth embodiment mode will be explained. In general, when the optical disk is used as a recording medium for a computer, it is said that it is necessary to resist a large number of rewriting times in comparison with a case using this disk as an optical disk for audio. This is because the computer manages the disk while the computer frequently rewrites a FAT (File Allocation Table) written into the disk. It is said that the rewriting is generated 10 times or more in a writing area of the FAT in comparison with an area for writing general data thereinto. An optical disk drive 3904 in this embodiment mode is set to an optical disk drive having an object command corresponding interface in which the file management is performed within the optical disk drive 3904. Writing and reading operations are set to be performed from a host computer 3905 by a file name instead of a concrete physical address. FIG. 37 shows an optical disk medium 301 used in this embodiment mode. This optical disk medium 301 is divided into an area 3702 for writing data by performing the random seed scramble, and areas 3701 and 3703 for writing data without performing the random seed scramble. The FAT is respectively written to the areas 3702 and 3703 in a scrambling form of the FAT and an unscrambling form of the FAT. FIG. 39 is a schematic block diagram of a DVD device in this eighth embodiment mode. An interface 311 performs input-output control of data with respect to an upper device, and converts a file name and a physical address. Reference numeral 1406 designates a microcomputer for generalizing a system. The microcomputer 1406 is connected to the interface 311, and controls the operation of the interface 311. The microcomputer 1406 is also connected to a control circuit 1411 within the system. This control circuit 1411 controls the operations of a seed generator 2603, an error correction coding circuit 307, a scrambler 2601, etc. through an unillustrated control line. Reference numeral 1401 designates an ID adder for adding additional information such as ID, etc. required to make a record to user data given by the interface 311. Reference numeral 1402 designates a memory (RAM) for temporarily storing data. Reference numeral 3902 designates a scrambler for randomizing data. This scrambler is a scrambler shown in FIG. 45, and includes an Maximum length sequence generator of a fixing seed and a random seed scrambler. This scrambler is almost the same as that explained in the first embodiment mode, but differs from the scrambler in the first embodiment mode in that a switch 4506 able to select whether the random seed scramble is performed or not is arranged. The operation of the switch 4506 is controlled by a signal line 4507 showing random seed scramble ON/OFF and controlled by the microcomputer. Reference numeral 3901 designates a seed generator for giving a different seed every writing to the random seed scrambler within the scrambler 3902. Reference numeral 307 designates an error correction coding circuit for adding an error correcting code to the scrambled user data. Reference numeral 305 designates a coding circuit for converting the user data adding the error correcting code thereto to a run length limit code suitable for the record to the optical disk 301. Reference numeral 302 designates a pickup for recording/regenerating data of the optical disk 301. Reference numeral 1403 designates a spindle motor for rotating the disk. Reference numeral 1404 designates a servo for controlling the operation of the optical pickup 302, etc. Reference numeral 304 designates a read channel for performing waveform equalization processing of an analog regenerating signal read from the optical disk 301, a binary operation and synchronous clock generation. Reference numeral 306 designates a decoder for decoding the read run length limit code. Reference numeral 308 designates an error detection-correction circuit for detecting an error on the basis of the error correcting code added by the error correction coding circuit 307, and correcting the error. Reference numeral 3903 designates a descramble circuit for releasing the randomization performed by the scrambler 3902, and returning user data to the original user data. This descrambler is the descrambler shown in FIG. 46, and includes an Maximum length sequence generator 4601 of a fixing seed and a random seed descrambler 4603. This scrambler is almost the same as that explained in the first embodiment mode, and differs from the descrambler in the first embodiment mode in that a switch 4606 able to select whether the random seed descramble is performed or not is arranged. The operation of the switch 4606 is controlled by a signal line 4607 showing random seed scramble ON/OFF and controlled by the microcomputer. Reference numeral 1407 designates an ID deleting device for deleting addition information such as ID, etc. required to make a record and added by the ID adder 1401, and setting only the user data.

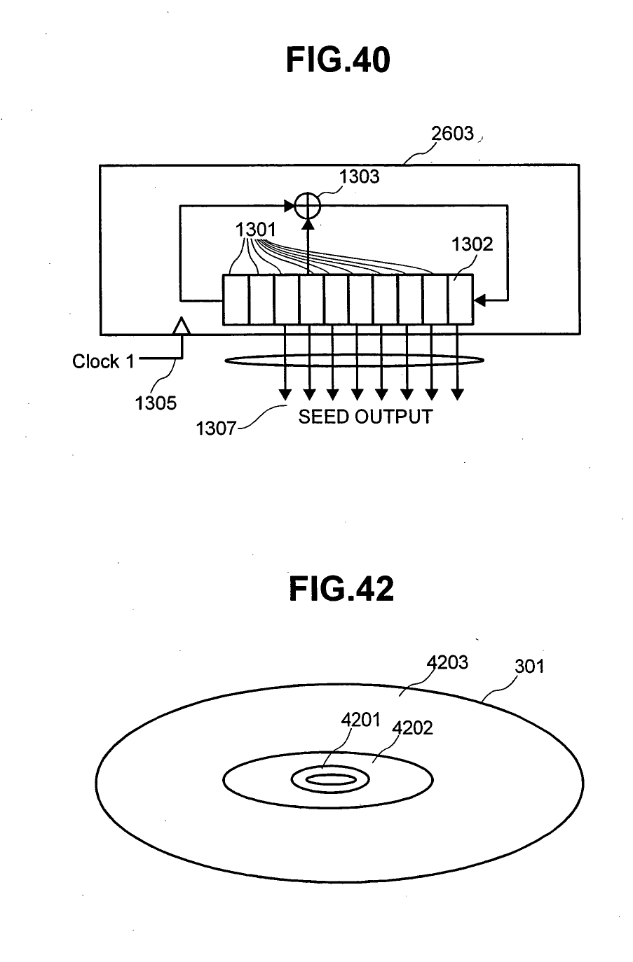

FIG. 40 is a view showing the seed generator 3901 of this eighth embodiment mode. Each of reference numerals 1301, 1302 designates a 1-bit shift register. Reference numeral 1303 designates an exclusive logical sum circuit. A suitable value except for zero is inputted to each 1-bit shift register 1301 in an initial state. When a seed is required at a data writing time, a clock (1305) is inputted, and the values of the 1-bit shift registers 1301, 1302 are leftward shifted. An output value of the exclusive logical sum circuit 1303 is inputted to the 1-bit shift register 1302. Thereafter, 8 bits of the seed value inputted to the 1-bit shift registers 1301, 1302 are outputted to the scramble circuit 3902 as the seed through a seed output line 1307.

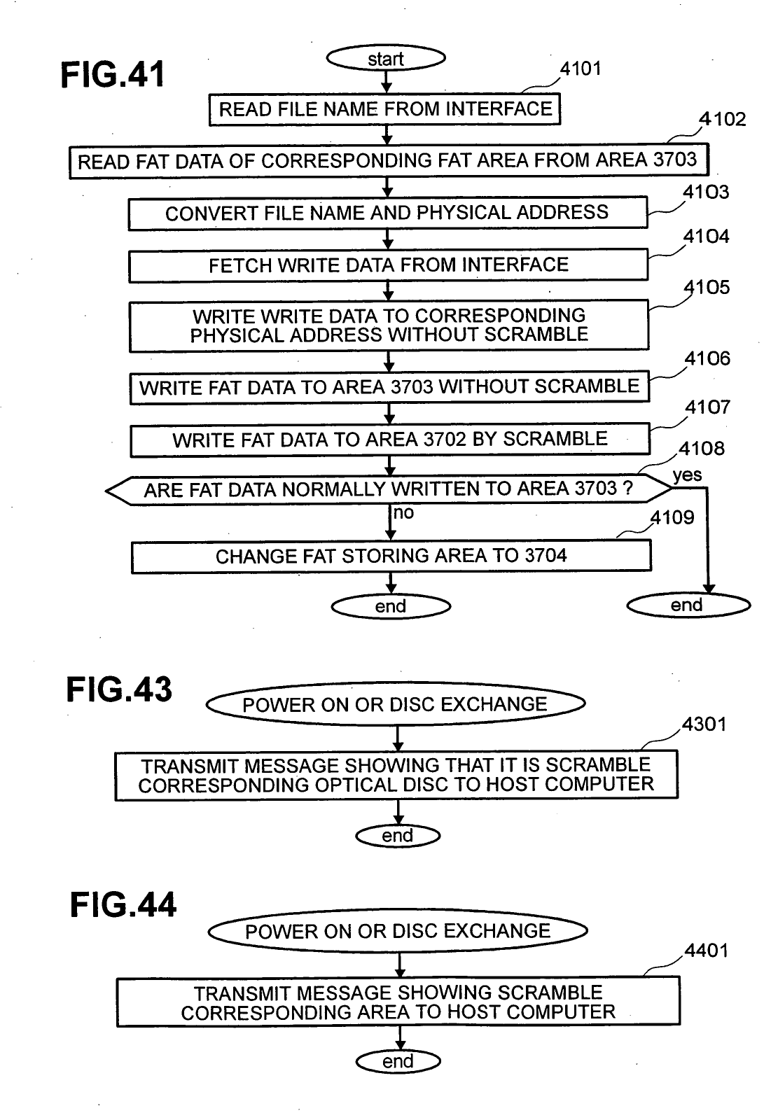

The operation of the DVD device shown in FIG. 39 will next be explained. First, this operation at a recording time will be explained with reference to the optical disk shown in FIG. 37 and the processing procedure at the recording time shown in FIG. 41.

First, when a written file name and the size of the file are inputted from the interface 311 (step 4101), the microcomputer 1406 reads a FAT stored to the area 3703 (step 4102), and calculates a written physical address from the size of the written file (step 4103). Next, written data are fetched from the interface 311 (step 4104), and are written to a place within the area 3701 shown by the physical address calculated in the step 4103 without the random seed scramble (step 4105). Next, the FAT is updated, and is written to the area 3703 without the random seed scramble (step 4106). Next, the same FAT is random-seed-scrambled and is written to the area 3702 (step 4107). Next, the FAT written to the area 3703 is read and it is checked whether the FAT is written without any error (step 4107). Since the writing operation is performed in the area 3703 without performing the scramble, medium deterioration in the area 3703 is faster than that in the area 3702 so that an error is early generated. When the error lies within an error correcting ability range in the step 4107, the writing processing is terminated. In contrast to this, when the number of errors is greater than the error correcting ability range in the step 4107, the FAT stored to the area 3702 is read, descrambled and stored to an area 3704. Hereafter, the area 3704 is used as a FAT area (step 4109). The writing processing is next terminated.

As shown in this eighth embodiment mode, the FAT data often written can be protected by scrambling and storing the FAT. Further, data can be read by the existing optical disk device not corresponding to the scramble by writing the data onto the optical disk medium in a data area in which no rewriting is often caused, and a form in which one of the FATs is not scrambled.

A ninth embodiment mode will next be explained by using FIGS. 39, 42 and 44. FIG. 39 shows a block diagram of a DVD device in the ninth embodiment mode. The DVD device 3904 in this ninth embodiment mode is a DVD device in which this DVD device is not the optical disk of object command correspondence and a file is managed by the host computer, and data are written to an address such as a logic block address or a physical block address, etc. assigned by the host computer by writing commands.

In the DVD device 3904 of this embodiment mode, one portion 4202 of the optical disk medium for performing the writing operation as shown in FIG. 42 is treated as an area written by performing the scramble, and one portion 4203 of the optical disk medium for performing the writing operation is treated as an area written without performing the scramble. Further, information as to what tracks the area written by performing the scramble is, and information as to what tracks the area written without performing the scramble is, are stored to the track 4201. Similar to the scramble mode information 2902, 2903, 2904, 2905 shown in the embodiment mode 2, this information can raise reliability by using the writing operation in plural places, strong ECC, etc. The DVD device 3904 of this embodiment mode transmits a message showing the scramble corresponding area as shown in FIG. 44 (the information as to what tracks the area written by performing the scramble is, or the information as to what tracks the area written without performing the scramble is) to the host computer at the power turning-on time or the disk medium exchanging time (step 4301). The host computer writes FAT data particularly often rewritten or data particularly having a large rewriting number in the nature of application to the writing area by performing the scramble. The host computer calculates a logic sector number or a physical sector number corresponding to the scramble by using the message showing the scramble corresponding area obtained in the step 4301, and allocates the data particularly often rewritten as in the FAT data, etc. to the sector of the writing area by performing this scramble, and issues writing commands and performs the writing operation. As shown in this ninth embodiment mode, the FAT data frequently written can be protected by scrambling and storing the FAT and an area particularly frequently written.

A tenth embodiment mode will next be explained by using FIGS. 39 and 43. FIG. 39 shows a block diagram of the DVD device in the tenth embodiment mode. Similar to the DVD device in the ninth embodiment mode, the DVD device 3904 in this tenth embodiment mode is a DVD device in which this DVD device is not the optical disk of object command correspondence and a file is managed by the host computer, and data are written to an address such as a logic block address or a physical block address, etc. assigned by the host computer by writing commands.

In the DVD device 3904 of this embodiment mode, similar to the second embodiment mode, scramble mode information 2902, 2903, 2904, 2905 showing whether the optical disk medium corresponds to the scramble is recorded to the optical disk medium of this embodiment mode. At the power turning-on time or the disk medium exchanging time, as shown in FIG. 43, the DVD device 3904 reads the scramble mode information 2902, 2903, 2904, 2905 from the optical disk medium, and transmits a message showing that it is the scramble corresponding optical disk to the host computer (step 4301).

When the optical disk written at present is the scramble corresponding optical disk, and data particularly often rewritten as in the FAT data, etc. and data known to be particularly often rewritten in application are written, the host computer gives commands to the DVD device so as to random-seed-scramble and write the data. Concretely, the host computer assigns whether the random seed scramble is performed or not by 1 bit determined within a command byte outputted from the host computer to the DVD device. If the above determined 1 bit within the command byte shows that the scramble is performed, the DVD device 3904 controls a signal line 4507 showing random seed scramble ON/OFF to ON, and writes data to a scrambled and assigned address. In contrast to this, if the above determined 1 bit within the command byte shows that no scramble is performed, the-DVD device 3904 controls the signal line 4507 showing the random seed scramble ON/OFF to OFF, and writes data to an address assigned without performing the random seed scramble. As shown in this tenth embodiment mode, the FAT data frequently written can be protected by scrambling and storing the FAT and the area particularly frequently written. In a method for assigning whether the host computer performs the random seed scramble or not with respect to the DVD device, there are a method for transmitting a signal to the others as a message byte, a method for writing a specific value to 1 bit of a specific register determined in advance and arranged in an interface section within the DVD device by the host computer, etc. in addition to the method using 1 bit within the above command byte. When there is no vacant bit within the command byte, these methods are effective. It is considered that the above method for transmitting a signal to the others as 1 bit within the message byte is particularly effective in the interface such as SCSI, etc., and the method for writing a specific value to 1 bit of a specific register determined in advance is effective in an ATA interface.

An eleventh embodiment mode will next be explained with reference to FIG. 38. The DVD device of this embodiment mode is also shown in FIG. 39. FIG. 38 is a view showing an optical disk medium 301 of this eleventh embodiment mode. In this view, one portion of the optical disk medium 301 is cut and sectionally shown. The optical disk 301 has n-recording layers, and layers 3801, 3802 are sequentially formed from the surface and reference numeral 3803 designates a layer farthest from the surface. It is not necessary to generally transmit light more deeply from the layer 3803 farthest from the surface. Accordingly, a metal can be used as a reflection layer for reflecting light. However, it is necessary to transmit light more deeply from the layers 3801, 3802 near the surface in comparison with the farthest layer. Accordingly, no metal can be used as the reflection layer, and a flowage phenomenon is easily caused and medium deterioration due to overwrite is easily caused in characters. Accordingly, in this embodiment mode, the random seed scramble for preventing the medium deterioration is performed in the first recording layer 3801, the second recording layer 3802, . . . , the (n-1)-th recording layer from the surface, and data are recorded onto the medium. The record is made without performing the random seed scramble in the n-th recording layer 3803 deepest from the surface. Similar to the second embodiment, scramble mode information 2902, 2903, 2904, 2905 showing whether each layer corresponds to the random seed scramble, are recorded to an innermost circumferential track 3804 of each layer. The optical disk drive reads the scramble mode information of each layer written in the innermost circumference at the power turning-on time, the exchanging time of the optical disk medium or the moving time of an accessed layer, and holds its value within the microcomputer. The optical disk drive controls whether this value is written by performing the random seed scramble at the writing time, or is written without performing the random seed scramble. Thus, in the DVD device not corresponding to the random seed scramble, the optical disk can be treated as an optical disk of one layer constructed by only the n-th layer 3803. In the DVD device corresponding to the random seed scramble, the optical disk can be treated as an optical disk having the n-th recording layer and able to guarantee the rewriting numbers of all the layers constantly or more. Thus, this optical disk can be treated as an optical disk having a recording capacity n-times that of the optical disk of only one layer. For example, basic data such as an image, a voice, etc. are recorded to the recording layer 3803, and interpolation data, etc. are recorded to the recording layers 3801, 3802 in such an optical disk. Thus, in the DVD device not corresponding to the random seed scramble, the optical disk medium can be used as an optical disk medium able to regenerate only data not so good in image quality, sound quality, etc. In contrast to this, in the DVD device corresponding to the random seed scramble, the optical disk medium can be used as an optical disk medium able to regenerate high image quality and high sound quality.

The present invention will next be explained from a new viewpoint. A scramble coding method, a scramble decoding method, a recording method and a regenerating method of the present invention will be respectively sequentially explained in detail with their basic embodiment modes as a twelfth embodiment mode while a circuit and a device for embodying these methods are explained. In this specification, the scramble is said as one kind of data conversion.

First, the scramble coding method in the twelfth embodiment mode will be explained. Here, the bit number (expressed by a binary number) of a seed (a value used in the scramble) is set to L-bits, and the bit number of object data is set to K-bits (L≧1, K≧1). This method is constructed by the following steps 1 to 2.

Step 1 (seed selecting step): The seed is selected.

Step 2 (scramble step): Inputted data are scrambled by using the selected seed, and its result is outputted as data after the scramble. A method for selecting the seed of the L-bits in the step 1 will be explained in detail.

In one method for selecting the seed of the L-bits, a random value is selected as the seed.

For example, a counter (timer) of the L-bits able to show numbers 0 to (2ˆL−1) is arranged (irrespective of the interior or the exterior of the scramble coding method). The counting value of this counter is continuously increased one by one irrespective of the operations in the steps 1 and 2 while a cyclic operation is performed so as to be continued to the minimum value 0 after the maximum value (2ˆL−1). In the scramble coding method, in the step 1, the value of this counter at that time is referred and is selected as the seed.

Otherwise, for example, the number of arithmetic operations of an external processor (CPU, MPU, microcomputer) itself of the scramble coding method is stored into this processor. A counter (register) of the L-bits or more able to show numbers of 0 to (2ˆL−1) or more is arranged. The counting value of this counter is increased one by one at every arithmetic operation of the processor while a cyclic operation is performed so as to be continued to the minimum value 0 after the maximum value. In the scramble coding method, in the step 1, the counting value of this counter at that time is referred and a surplus value provided in surplus with (2ˆL) as a divisor with respect to this counting value is selected as the seed.

Namely, in the scramble coding method, in the step 1, the value of the counter operated irrespective of (easily) the operation of the scramble coding method is referred. Thus, the random value can be selected as the seed. With respect to the random value of the L-bits (the range of 0 to (2ˆL−1)), the probability of setting two values of the random value to the same is (1/(2ˆL)). Accordingly, even when the data of inputted K-bits are the same, data outputted by the scramble in the step 2 are the same in probability (1/2ˆL)), and are different in probability (1−(1/(2ˆL))). In another method for selecting the seed of the L-bits, a value different from the value used at present is selected as the seed.

Here, when data are already recorded in the past in a certain place of the recording medium, it is supposed in the scramble coding method in this record of the past that the value (0≦A≧(2ˆL−1)) of A is selected as the seed in the step 1, and the scramble is performed by using this value in the step 2. In this case, in the scramble coding method or the external processor and a memory, etc., the value of A is stored as the value of the seed selected in the record of this place. When data should be recorded to the same place as this record of the past at present, the value of A is used with respect to the data recorded at present with reference to the value of A stored in the step 1 in the scramble coding method. Therefore, a value different from this value of A is selected as the seed. For example, (A+1) is selected as the seed when (A+1)<(2ˆL), and 0 is selected as the seed when (A+1)=(2ˆL). In this case, in the scramble coding method or the external processor and the memory, etc., (A+1) (or 0) is newly stored instead of the stored A as the value of the seed selected in the record of this place.

When data should be recorded to a certain place of the memory medium and no value of A as the selected seed with respect to the data recorded to this object place at present is stored in the scramble coding method or the external processor and the memory, etc., the value of A is regenerated and referred by executing the regenerating method and the scramble decoding method described later. Thus, for example, with respect to a different from the value of A, (A+1) is selected as the seed when (A+1)<(2ˆL) and 0 is selected as the seed when (A+1)=(2ˆL) as mentioned above.

Namely, in the scramble coding method, a value different from the value used with respect to the data recorded at present is selected in the step 1. Thus, the value reliably different from the value used at present can be selected as the seed in comparison with the above random selecting case.

Next, the scrambling method in the step 2 will be explained in detail. In the step 2, a polynomial called a scramble polynomial is used. This polynomial is an M-th order polynomial (M≧1) to be set in advance in the execution of the present invention, and having each coefficient of 0 or 1. Here, an i-th coefficient of this scramble polynomial is set to f[i] with respect to 0≦i≦M−1. This scramble polynomial is the M-th order polynomial, and an M-th order coefficient is 1. Namely, when the scramble polynomial is set to F(x), F(x)=xˆM+f[M−1]·xˆ(M−1)+ . . . +f[1]·x+f[0] is formed.

Here, it is supposed that the value of the seed of the L-bits selected in the step 1 is A, and its bits are a[L−1], a[L−2], . . . , a[0]. It is also supposed that the data of inputted K-bits of a scramble object are D, and its bits are d[K−1], d[K−2], . . . , d[0]. Further, a[i]ε{0,1} is formed with respect to 0≦i≦(L−1), and d[i]ε{0,1} is formed with respect to 0≦i≦(K−1).

With respect to a [L−1], a[L−2], . . . , a[0], d[K−1], d[K−2], . . . , d[0] provided by continuously connecting A of the L-bits and D of the K-bits, a polynomial provided by interpreting as these values as a polynomial expression is called a scrambled polynomial. Concretely, with respect to 1≦i≦(L+K), an i-th bit of the (L+K) bits provided by continuously connecting A and B is set to an (L+K+M−i)-th order coefficient of the scrambled polynomial. Namely, when the scrambled polynomial is set to G(x), G(x)=a[L−1]·xˆ(L−1+K+M)+a[L−2]·xˆ(L−2+K+M)+ . . . +a[0]·xˆ(K+M)+d[K−1]·xˆ(K−1+M)+d[K−2]·xˆ(K−2+M)+ . . . +d[0]·xˆM is formed. G(x) is a polynomial of the (L+K+M−1)-th order or less, and it can be understood that all coefficients of the (M−1)-th order or less of this polynomial are 0.

In the scramble coding method, when a polynomial divisional calculation (G(x)≈F(x)) is made with F(x) as a divisional polynomial (divisor) with respect to the divided polynomial (dividend) G(x) in the step 2, each coefficient of a quotient polynomial as the result of this calculation is outputted as data after the scramble. In this polynomial divisional calculation, the arithmetic operation of each coefficient is performed in a surplus system with 2 as a divisor. Namely, a multiplying calculation is made as a logical sum ‘·’ (0·0=0·1=1·0=0, 1·1=1), and an adding calculation is made as an exclusive logical sum ‘+’ (0(+)0=1(+)1=0, 0(+)1=1(+)0=1). In this system, a subtracting calculation is equal to the adding calculation. G(x) is a polynomial of the (L+K+M−1)-th order or less. F(x) is an M-th polynomial. Therefore, it can be understood that the quotient polynomial (quotient) of the result of this polynomial divisional calculation is a polynomial of the (L+K−1)-th order or less. This quotient polynomial is set to H(x) and an i-th coefficient of this quotient polynomial is set to h[i] with respect to 0≦i≦(L+K−1). In the scramble coding method, coefficients h[L+K−1], h[L+K−2], . . . , h[0] of (L+K) bits of the quotient polynomial of the result of the polynomial divisional calculation are outputted as data after the scramble.

The above polynomial divisional calculation is not the original calculation of the present invention, but is considered as a general calculation, but will be explained in detail by using a simple example. The explanation is made in the case of an order M=2 of the scramble polynomial, the scramble polynomial F(x)=xˆ2+x+1(f[2]=1, f[1]=1, f[0]=1), a bit number L=3 of the seed, bits 0, 1, 0 (a[2]=0, a[1]=1, a[0]=0) of the seed selected in the step 1, a bit number K=2 of inputted data of a scramble object, and bits 0, 1 (d[1]=0, d[0]=1) of the inputted data of the scramble object. In this case, the order of the scrambled polynomial is sixth order or less, and the scrambled polynomial is G(x)=xˆ5+xˆ2.

The polynomial divisional calculation is made with F(x) as a divisional polynomial with respect to the divided polynomial G(x). If the polynomial divisional calculation is made by the second order F(x) with respect to G(x) of the sixth order or less, the quotient polynomial of this result is a fourth order or less. However, in this case, G(x) is a fifth order so that the quotient polynomial becomes a third order. Namely, the fourth order coefficient of the quotient polynomial becomes 0 (h[4]=0). Further, the third order coefficient of the quotient polynomial becomes 1 ([h[3]=1]). Since the third order coefficient of the quotient polynomial is 1, an intermediate surplus polynomial so far is set to R(x). Thus, R(x)=G(x)+xˆ3·F(x)=(xˆ5+xˆ2)+(xˆ5+xˆ4+xˆ3)=xˆ4+xˆ3+xˆ2 is formed. It is understood from R(x) that the second order coefficient of the quotient polynomial is 1 (h[2]=1). Since the second order coefficient of the quotient polynomial is 1, the intermediate surplus polynomial so far is set to R′(x). Thus, R′(x)=R(x)+xˆ2·F(x)=(xˆ4+xˆ3+xˆ2)+(xˆ4+xˆ3+xˆ2)=0 is formed. It is understood from R′(x) that both the first and zeroth order coefficients of the quotient polynomial are 0 (h[1]=0, h[0]). Thus, a quotient polynomial H(x)=xˆ3+xˆ2 is obtained. In the case of this example, the coefficients h[4], h[3], h[2], h[1], h[0] of five bits of the quotient polynomial, i.e., 0, 1, 1, 0, 0 are outputted as data after the scramble in the scramble coding method.

Namely, when the seed and the inputted data are continuously connected and are interpreted as a polynomial expression in the step 2 in the scramble coding method and the polynomial divisional calculation is made with respect to this polynomial with a predetermined scramble polynomial as a divisional polynomial, each coefficient of the quotient polynomial of the result of this calculation is outputted as data after the scramble. These contents will be described later in detail. Thus, even when an error exists in the data of a descramble object in the descramble (which is a reverse operation to the scramble, and is scramble decoding), the descramble is performed such that this error is diffused by only M-bits at most.

The M-th order scramble polynomial. F(x) having each coefficient of 0 or 1 to be set in advance in the execution of the present invention is not limited to the above example. For example, the scramble polynomial may be also set to a polynomial such as F(x)=xˆM+1 in which only the M-th order coefficient of the maximum order and the zeroth order coefficient of the minimum order are 1 and the other order coefficients are 0.

As mentioned above, the scrambled polynomial G(x) is a polynomial of the (L+K+M−1)-th order or less, and the coefficients of the (M−1)-th order or less of this polynomial are 0. When the polynomial divisional calculation is made with the scramble polynomial F(x)=xˆM+1 as a divisional polynomial with respect to the divided polynomial G(x), the coefficient of the (L+K−1)-th order of the quotient polynomial H(x) of the result of this calculation is obtained as the coefficient of the (L+K+M−1) -th order of G(x). When the intermediate surplus polynomial so fat is set to R(x), R(x) is obtained by adding the (L+K+M−1) -th order coefficient (in the surplus system with 2 as a divisor) to the (L+K−1)-th order coefficient of G(x) and setting the (L+K+M−1)-th order coefficient to 0. Thus, the (L+K−2)-th order coefficient of H(x) is obtained as the (L+K+M−2)-th order coefficient of R(x). When the intermediate surplus polynomial so far is set to R′(x) R′(x) is obtained by adding the (L+K+M−2)-th order coefficient (in the surplus system with 2 as a divisor) to the (L+K−2)-th order coefficient of R(x) and setting the (L+K+M−2)-th order coefficient to 0. Thus, the (L+K−3)-th order coefficient of H(x) is obtained as the (L+K+M−3)-th order coefficient of R′(x). When the intermediate surplus polynomial so far is set to R″(x), R′(x) is obtained by adding the (L+K+M−3)-th order coefficient (in the surplus system with 2 as a divisor) to the (L+K−3)-th order coefficient of R′(x) and setting the (L+K+M−3)-th order coefficient to 0. Thus, the (L+K−4)-th order coefficient of H(x) is obtained as the (L+K+M−4)-th order coefficient of R″(x). Finally, the initial polynomial (initial value) of the intermediate surplus polynomial is set to G(x), and the i-th coefficient of the quotient polynomial H(x) is sequentially obtained as the (i+M)-th order of the intermediate surplus polynomial from i=L+K−1 to i=0. Further, the (i+M)-th order coefficient is set to 0 while the (i+M)-th order coefficient is added to the i-th order coefficient of this intermediate polynomial (in the surplus system with 2 as a divisor). Thus, this polynomial is set as a new surplus polynomial, and H(x) is obtained by repeating these operations with respect to i.

In the above repetition, with respect to the i-th order coefficient of the intermediate surplus polynomial, the (i+M)-th order coefficient is added to the original value (in the surplus system with 2 as a divisor). This original value is the i-th order coefficient of G(x). When the repetition of the (i+M)-th order coefficient of the intermediate surplus polynomial is retrospected, the (i+M)-th order coefficient of the intermediate surplus polynomial is obtained by adding the (i+2−M)-th order coefficient to the original value (in the surplus system with 2 as a divisor) in the case of (i+M)≧(L+K−1) (namely i≦(L+K−M−1)), and is the original value itself in the case of (i+M)>(L+K−1) (namely, i>(L+K−M−1)). This original value is the (i+M)-th order coefficient of G(x). Namely, when the i-th order coefficient of the intermediate surplus polynomial is set to the i-th order coefficient of H(x), the i-th order coefficient of the intermediate surplus polynomial is a value obtained by accumulatively calculating (adding in total) all the i-th order, (i+M)-th order, (i+T·M)-th order coefficients of G(x) (in the surplus system with 2 as a divisor). Here, T shows a maximum integer when (i+T·M)≦(L+K−M−1) is formed.

Namely, when the scramble polynomial is set in advance to a polynomial such as F(x)=xˆM+1 in which only the M-th order of the maximum order and the zeroth order of the minimum order are set to 1 and the other order coefficients are 0, a result accumulatively calculated by the exclusive logical sum is outputted every bits separated by M-bits with respect to a case in which the seed and the inputted data of a scramble object are continuously connected in the step 2 in the scramble coding method. Concretely, with respect to 1≦i≦(L+K), bits provided by accumulatively calculating the (i−T·M)-th, the (i−(T−1)·M)-th, . . . , the (i−M)-th, and the i-th bits of the (L+K) bits provided by continuously connecting the seed and the inputted data of the scramble object (in the surplus system with 2 as a divisor) are set to the i-th bit of the output, and (L+K) bits provided by repeating this operation with respect to i are outputted. These contents will be described later in detail. Thus, it can be understood that the optical disk device can be cheaply constructed in view of the calculating amount and the circuit scale in execution in comparison with a case using other polynomials as the scramble polynomial.

The scramble coding method in the twelfth embodiment mode has been thus explained. It is natural to be able to change the bit number L of the seed, the bit number K of data of the scramble object, the order M of the used scramble polynomial, etc. irrespective of the above example.

Next, the scramble coding circuit for embodying the above scramble coding method will be explained. In the following description, when it is not particularly said, the scramble polynomial uses a polynomial such as F(x)=xˆM+1 in which only the M-th order coefficient of a maximum order and the zeroth order coefficient of a minimum order are set to 1, and the other order coefficients are 0. When the seed and the inputted data are continuously connected and are interpreted as a polynomial expression and the polynomial divisional calculation is made with respect to this polynomial with this scramble polynomial as a divisional polynomial, the explanation is made with respect to the scramble coding circuit for outputting each coefficient of a quotient polynomial of the result of this calculation as data after the scramble. Namely, when it is not particularly said in the following description, the explanation is made with respect to the scramble coding circuit for outputting the result accumulatively calculated every bits separated by M-bits with respect to the continuous connection of the seed and the inputted data.

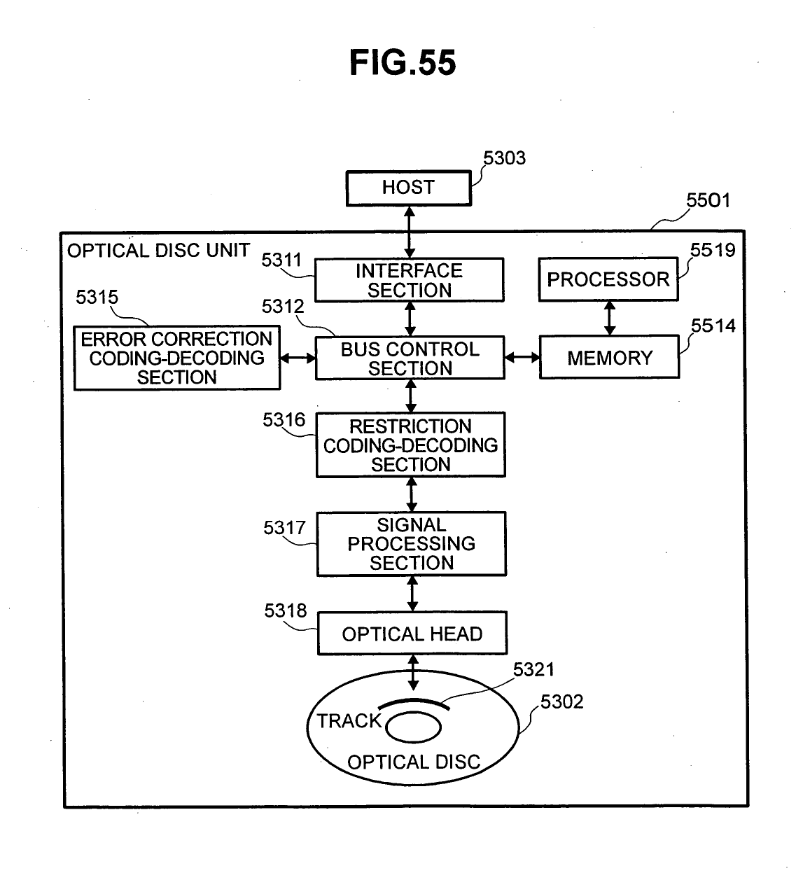

FIG. 55 is a block diagram showing the construction of the scramble coding circuit for performing a sequential outputting operation every 1 bit with respect to a sequential input every 1 bit. In FIG. 55, the scramble coding circuit 4701 is constructed by one XOR circuit 4177 and M 1-bit memories. In FIG. 55, for convenience, only three 1-bit memories 4721, 4722, 4723 among the M 1-bit memories are shown and the others are not shown.

The operation of this scramble coding circuit 4701 will be explained.

First, the seed of L-bits is selected. In this method, the seed may be selected similarly to the procedure described in the above scramble coding method. Namely, a counter for playing the role of a timer or a register is arranged and is referred. Further, a random value may be selected as the counting value of the counter, or a value different from the used value may be also selected as the counting value. The selection of the seed has been explained in detail in the above description. Therefore, no part for playing the role of this seed selection is shown in FIG. 55.

In the scramble, the M 1-bit memories (4721, 4722, 4723, and others) are respectively reset in advance and hold value 0. (L+K) bits a[L−1], a[L−2], . . . , a[0], d[K−1], d[K−2], d[0] provided by continuously connecting a seed A of L-bits and data D of a scramble object of K-bits are sequentially inputted as input data to the scramble coding circuit 4701 every 1 bit. With respect to each sequential input, the XOR circuit 4711 performs an exclusive logical sum (adding calculation of the surplus system with 2 as a divisor) with respect to the value of the input data and the held value of the 1-bit memory, 4723, and outputs the value of this result. In this case, the contents of the other (M−1) 1-bit memories (4722, 4723, and others) except for the 1-bit memory 4721 are respectively updated (shifted) to the held values of the 1-bit memories at the previous stage. The contents of the 1-bit memory 4721 are also updated to the value of the result of the XOR circuit 4711. Further, the scramble coding circuit 4701 outputs the value of the result of the XOR circuit 4711 as 1-bit among data after the scramble. (L+K) bits h[L+K−1], h[L+k−2], . . . , h[0] sequentially outputted with respect to the sequential input of (L+K) bits a[L−1], a [L−2], . . . , a[0], d[K−1], d[K−2], . . . , d[0] are the data after the scramble.

These contents will be explained in detail by using a simple example. The explanation is made in the case of an order M=3 (scramble polynomial F(x)=xˆ3+1) of the polynomial of the scramble, a bit number (L+K)=7 provided by continuously connecting the seed and the data of the scramble object, and input data 1, 0, 1, 1, 1, 0, 0 of 7 bits of this continuous connection. In this case, the scramble coding circuit 4701 includes three 1-bit memories (4721, 4722, 4723).

The three 1-bit memories (4721, 4722, 4723) sequentially hold 0, 0, 0 in advance. When the value 1 of a first bit of the input data is inputted to the scramble coding circuit 4701, the XOR circuit 4711 outputs a value 1+0=1 obtained by performing the exclusive logical sum with respect to this value 1 and the held value 0 of the 1-bit memory 4723. The 1-bit memory 4721 updates its contents to the output value 1 of the XOR circuit 4711, and the other 1-bit memories (4722, 4723) respectively update their contents to the held values of the 1-bit memories at the previous stage. Thus, the three 1-bit memories (4721, 4722, 4723) sequentially hold 1, 0, 0. The scramble coding circuit 4701 outputs the output value 1 of the XOR circuit 4711 as a first bit of data after the scramble. Next, when the value 0 of a second bit of the input data is inputted to the scramble coding circuit 4701, the XOR circuit 4711 outputs value 0, and the three 1-bit memories (4721, 4722, 4723) sequentially hold 0, 1, 0. Further, the scramble coding circuit 4701 outputs value 0 as a second bit of the data after the scramble. Next, when the value 1 of a third bit of the input data is inputted to the scramble coding circuit 4701, the XOR circuit 4711 outputs value 1, and the three 1-bit memories (4721, 4722, 4723) sequentially hold 1, 0, 1. Further, the scramble coding circuit 4701 outputs value 1 as a third bit of the data after the scramble. Similarly, in the sequential input of fourth to seventh bits of the input data to the scramble coding circuit 4701, the scramble coding circuit 4701 respectively outputs 0, 1, 1, 0 as fourth to seventh bits of the data after the scramble. Finally, in this case, the scramble coding circuit 4701 outputs 1, 0, 1, 0, 1, 1, 0 as the data after the scramble.

Namely, this scramble coding circuit 4701 respectively outputs the first to third bits of the input data as the first to third bits of the data after the scramble. Further, the scramble coding circuit 4701 respectively outputs values provided by performing the exclusive logical sum of the values of the first to third bits and the values of the fourth to sixth bits of the input data, as the fourth to sixth bits of the data after the scramble. Further, the scramble coding circuit 4701 outputs a value accumulatively calculated by performing the exclusive logical sum of the values of the first bit, the fourth bit and the seventh bit of the input data, as the seventh bit of the data after the scramble. Thus, this scramble coding circuit 4701 outputs the result accumulatively calculated by the exclusive logical sum every bits separated by M-bits.

As shown in FIG. 55, the construction for performing a feedback (cyclical) shift operation from the construction of plural 1-bit memories (and required XOR circuits) is not the original construction of the present invention, but is generally called a linear feedback shift register. FIG. 55 shows a case using a polynomial such as F (x)=xˆM+1 as the scramble polynomial in which only the coefficients of the M-th order of a maximum order and the zeroth order of a minimum order are 1 and the coefficients of the other orders are 0. When a polynomial having value 1 in the coefficients of the M-th order of the maximum order and the zeroth order of the minimum order and some of the coefficients of the other orders is used as the scramble polynomial, the construction is different from that shown in FIG. 55 and the number of XOR circuits is concretely increased. Accordingly, in the case using a polynomial such as F(x)=xˆM+1 as the scramble polynomial in which only the coefficients of the M-th order of the maximum order and the zeroth order of the minimum order are 1 and the coefficients of the other orders are 0, it can be understood that the optical disk device can be cheaply constructed in view of the calculating amount and the circuit scale in execution.

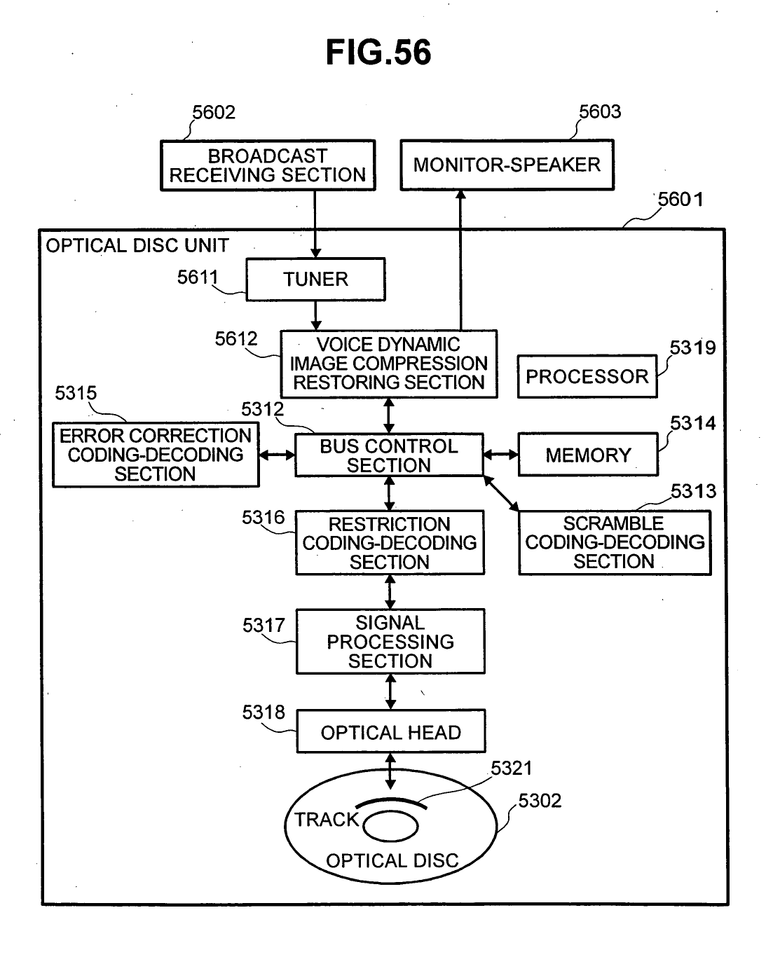

The scramble coding circuit is not limited to the construction for performing the sequential outputting operation every 1 bit with respect to the sequential input every 1 bit as in FIG. 55, but can use the construction of a sequential input-output type every plural bits irrespective of the value of M. FIG. 56 is a block diagram showing the construction of a scramble coding circuit for performing the output operation every M-bits with respect to the sequential input every M-bits. In FIG. 56, the scramble coding circuit 4801 is constructed by M-XOR circuits and M 1-bit memories. In FIG. 56, for convenience, only three XOR circuits 4811, 4812, 4813 among the M-XOR circuits and only three 1-bit memories 4821, 4822, 4823 among the M 1-bit memories are shown, and the other XOR circuits and the other 1-bit memories are not shown.

In the scramble using this scramble coding circuit 4801, the M 1-bit memories (4821, 4822, 4823, and others) are respectively reset in advance, and hold value 0. (L+K) bits provided by continuously connecting a seed A of L-bits and data D of a scramble object of K-bits are sequentially inputted to the scramble coding circuit 4801 as input data every M-bits. The (L+K) bits sequentially outputted every M-bits with respect to this sequential input are data after the scramble. Similar to the scramble coding circuit 4701 of FIG. 55, it can be understood that this scramble coding circuit 4801 outputs the result accumulatively calculated by the exclusive logical sum every bits separated by M-bits as the data after the scramble.

FIG. 55 shows the scramble coding circuit of a 1-bit input-output type. In contrast to this, it can be understood that FIG. 56 shows the scramble coding circuit of an M-bit input-output type for performing processing in a bit parallel arrangement. The construction for performing processing in the bit parallel arrangement as shown in FIG. 56 can be also naturally used even when a polynomial having value 1 in the coefficients of the M-th order of the maximum order and the zeroth order of the minimum order and some of the coefficients of the other orders is used as the scramble polynomial. Further, the number of input and output bits of a (2·M) bit input-output type and a (4·M) bit input-output type, etc. can be naturally arbitrarily constructed.

The scramble coding circuit in the twelfth embodiment mode has been explained as mentioned above. The scramble decoding method corresponding to the above scramble coding method in the twelfth embodiment mode will next be explained. Here, the data of an object are data of (L+K) bits after the scramble outputted by the above scramble coding method. The original data before the scramble are obtained in the scramble decoding method by performing the descramble of these data (which is a reverse operation to the scramble and is scramble decoding). This scramble decoding method is constructed by the following steps 1 to 2.

Step 1 (descramble step): Inputted data are descrambled.

Step 2 (seed separating step): A seed is separated from the descrambled data, and its result is outputted as the original data before the scramble.

The descrambling method in the step 1 will be explained.

In the above scramble coding method, with respect to a scrambled polynomial G(x)=a[L−1]·xˆ(L−1+K+M)+a[L−2]·xˆ(L−2+K+M)+ . . . +a[0]·xˆ(K+M)+d[K−1]·xˆ(K−1+M)+d[K−2]·xˆ(K−2+M)+ . . . +d[0]·xˆM having an (L+K+M−1)-th order or less and value 0 in the coefficient of an (M−1)-th order or less, a polynomial divisional calculation (G(x)+F(x)) is made with an M-th order scramble polynomial F(x)=xˆM+f[M−1]·xˆ(M−1)+ . . . +f[1]·x+f[1] as a divisional polynomial. At this time, each coefficient of a quotient polynomial of the (L+K−1)-th order or less H(x)=h[L+K−1]·xˆ(L+K−1)+h[L+K−2]·xˆ(L+K−2)+ . . . +h[1]·x+h[0] as a result of this polynomial divisional calculation is outputted as data after the scramble. Here, when a surplus polynomial ( ) of the result of this polynomial divisional calculation is set to R(x), the order of R(x) is the (M−1)-th order or less since the divisional polynomial F(x) is the M-th order. At this time, since the quotient polynomial of the polynomial divisional calculation G(x)+F(x) is H(x) and the surplus polynomial is R(x), it can be understood that G(x)+R(x)=F(x)·H(x) is formed. (Here, this formula is not described as G(x)−R(x)=F(x)·H(x) because the arithmetic calculation of the polynomial is made in the surplus system with 2 as a divisor and the subtracting calculation is equal to the adding calculation.) Accordingly, G(x) is calculated by making the polynomial multiplying calculation F(x)·H(x). Concretely, G(x) is calculated by interpreting all the coefficients (corresponding to R(x)) of the (M−1)-th order or less of the product polynomial of the result of the polynomial multiplying calculation F(x)·H(x) as 0. Thus, the respective coefficients of the (L+K+M−1)-th to M-th orders of G(x), i.e., the (L+K) bits become the seed before the scramble and the data of a scramble object. This polynomial multiplying calculation is not the original multiplying calculation of the present invention, but is a general multiplying calculation.

In the scramble decoding method, when the data of the (L+K) bits of an inputted descramble object are interpreted as a polynomial expression in the step 1, and the polynomial multiplying calculation is made with respect to this polynomial H(x) with a predetermined scramble polynomial F(x) as a multiplying polynomial (multiplier), each coefficient (an upper portion except for lower M-bits) of the product polynomial of this result is set to descrambled data. Concretely, with respect to 1≦i≦(L+K), an i-th bit (means the (L+K+M−i)-th order coefficient in G(x)) of the descrambled data is set to a value provided by accumulatively calculating (adding in total) all f[j]·h[L+K+M−i−j] with respect to max{0,(M+1−i))}≦j≦M (in the surplus system with 2 as a divisor). Here, max{x,y} shows a larger value of x and y. Namely, this description means the value of 0 if (M+1−i)≦0, and the value of (M+1−i) if (M+1−i)>0.Further, with respect to this, since the scramble polynomial F(x) should be set in advance, the i-th bit of the descrambled data may be also set to a value provided by accumulatively calculating all h[L+K+M−i−j] with respect to j in f[j]=1.

Here, it is supposed that the data of the (L+K) bits of the descramble object, i.e., H(x) is incorrect, and the explanation will be made as to how the descrambled data are provided in this case. Here, since the data are treated as a binary value, for example, an error in e-th order coefficient h[e] of H(x) means that this value is inverted to 1 if 0 and 0 if 1. As mentioned above, the i-th bit of the descrambled data is a value provided by accumulatively calculating all h[L+K+M−i−j] with respect to j in f[j]=1. Accordingly, even when h[e] is incorrect, it can be understood that this error has an influence on only (L+K−e)-th to (L+K+M−e)-th bits of the descrambled data at most. Namely, even when an error in the data of the descramble object exists, it can be understood that this error is diffused by M-bits at most by the descramble by the benefit of the step 1 of the above scramble coding method and the scramble decoding method.

Further, the explanation will be made with respect to a case using a polynomial such as F(x)=x−M+1 as the scramble polynomial in which only the coefficients of the M-th order of a maximum order and the zeroth order of a minimum order are 1 and the coefficients of the other orders are 0. In this case, with respect to 1≦i≦(L+K), the i-th bit of the descrambled data is the value of (h[L+K+M−i]+h[L+K−i]) in the case of i≦(M+1), and the value of h[L+K−i] itself in the case of i<(M+1).

Namely, in the case using a polynomial such as F(x) =xˆM+1 as the scramble polynomial in which only the coefficients of the M-th order of the maximum order and the zeroth order of the minimum order are 1 and the coefficients of the other orders are 0, a value provided by calculating the exclusive-logical sum every bits separated by M-bits is outputted with respect to the inputted data of a descramble object in the step 1 in the scramble decoding method. The detailed explanation will be described later. However, similar to the case of the scramble coding method, it can be understood that the optical disk device can be thus cheaply constructed in view of the calculating amount and the circuit scale in execution in comparison with cases using other polynomials as the scramble polynomial.

As explained above, the descramble corresponding to the above scramble coding method is performed in the step 1 in the scramble decoding method. Thus, in the scramble decoding method, when no error exists in the data of the descramble object, the seed and the data of a scramble object before the scramble in the above scramble coding method are obtained.

A method for separating the seed in the step 2 will be explained.

In the scramble decoding method, (L+K) bits are obtained by the step 1. The L-bits of first to L-th bits in these (L+K) bits are a portion of the seed before the scramble, and the K-bits of (L+1)-th to (L+K)-th bits are a portion of the data of the scramble object before the scramble. Accordingly, in the step 2 in the scramble decoding method, the K-bits of the (L+1)-th to (L+K)-th bits among the (L+K) bits obtained by the step 1 are outputted as the original data before the scramble. The portion of the seed of the remaining L-bits of the first to L-th bits before the scramble may be disused if a random value is selected as the seed in the above scramble coding method. If there is a possibility that this value is referred later as in the selection of a value different from the used value as the seed, this value may be transmitted to a part (the scramble coding method itself or an external processor, etc.) having a possibility requiring this value, a memory, etc. and may be also stored to this part.

As mentioned above, the scramble decoding method in the twelfth embodiment mode has been explained. The scramble decoding circuit for embodying the above scramble decoding method will next be explained. When inputted data are interpreted as a polynomial expression by using a polynomial such as F(x)=xˆM+1 as the scramble polynomial in which only the coefficients of the M-th order of a maximum order and the zeroth order of a minimum order are 1 and the coefficients of the other orders are 0, and a polynomial multiplying calculation is made with respect to this polynomial with this scramble polynomial as a multiplication polynomial, the explanation is made with respect to the scramble decoding circuit with each coefficient of the product polynomial of this multiplying result as descrambled data when it is not particularly said in the following description. Namely, when it is not particularly said in the following description, the explanation is made with respect to the scramble decoding circuit in which a value provided by calculating an exclusive logical sum every bits separated by M-bits with respect to the inputted data is set to the descrambled data.

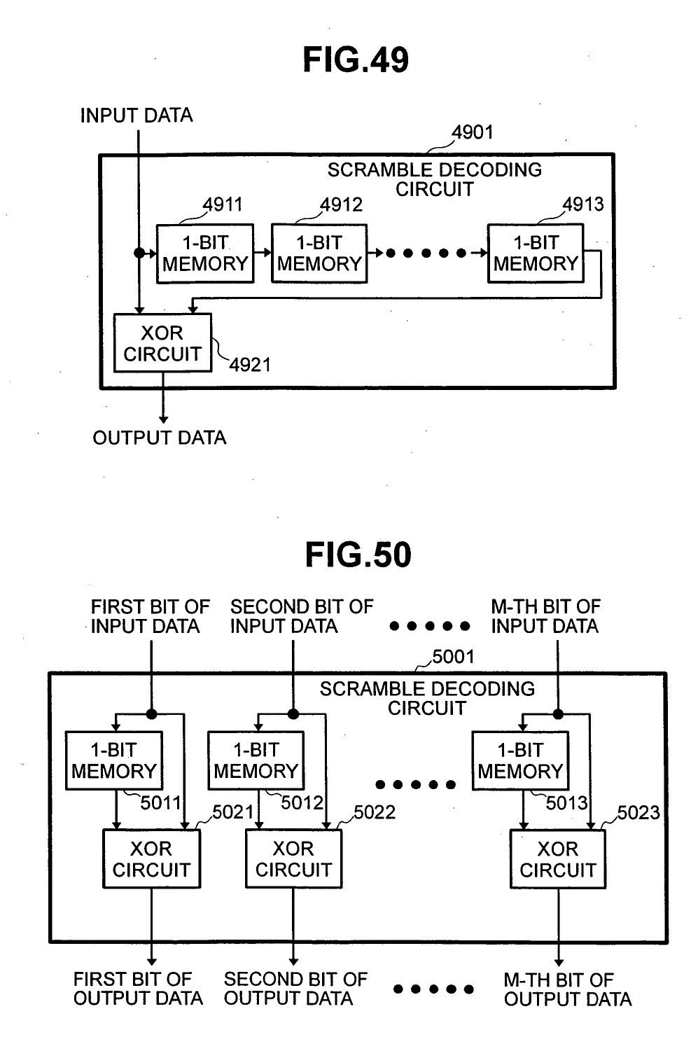

FIG. 49 is a block diagram showing the construction of the scramble decoding circuit for performing a sequential outputting operation every 1 bit with respect to a sequential input every 1 bit. In FIG. 49, the scramble decoding circuit 4901 is constructed by M 1-bit memories and one XOR circuit 4921. In FIG. 49, for convenience, only three 1-bit memories 4911, 4912, 4913 among the M 1-bit memories are shown and the others are not shown.

The operation of this scramble decoding circuit 4901 will be explained.

In the descramble, the M 1-bit memories (4911, 4912, 4913, and others) are respectively reset in advance, and hold value 0. (L+K) bits h[L+K−1], h[L+K−2], . . . , h[0] of a descramble object are sequentially inputted to the scramble decoding circuit every 1 bit. With respect to each sequential input, the XOR circuit 4921 calculates the exclusive logical sum (adding calculation of the surplus system with 2 as a divisor) of the value of input data and the held value of the 1-bit memory 4913, and outputs the value of this result. In this case, the contents of the other (M−1) 1-bit memories (4912, 4913, and others) except for the 1-bit memory 4911 are respectively updated (shifted) to the held values of the 1-bit memories at their previous stage. Further, the contents of the 1-bit memory 4911 are updated to the value of the result of the XOR circuit 4921. Further, the scramble decoding circuit 4901 outputs the value of the result of the XOR circuit 4921 as 1 bit among the descrambled data. With respect to the sequential input of the (L+K) bits h[L+K−1] h[L+K−2], . . . , h[0], sequentially outputted (L+K) bits g[L+K+M−1], g[L+K+M−2], . . . , g[M] are the descrambled data. Thus, this scramble decoding circuit 4901 outputs the value provided by calculating the exclusive logical sum every bits separated by M-bits as the descrambled data.

The construction having no feedback (cyclic) structure and performing a shift operation by constructing plural 1-bit memories (and required XOR circuits) as shown in FIG. 49 is not the original construction of the present invention, but is generally called a multiplier of the polynomial. FIG. 49 shows a case using a polynomial such as F(x)=xˆM+1 as the scramble polynomial in which only the coefficients of the M-th order of a maximum order and the zeroth order of a minimum order are 1 and the coefficients of the other orders are 0. When a polynomial having value 1 in the coefficients of the M-th order of the maximum order and the zeroth order of the minimum order and some of the coefficients of the other orders is used as the scramble polynomial, the construction is different from that shown in FIG. 49 and the number of XOR circuits is concretely increased. In the case using a polynomial such as F(x)=xˆM+1 as the scramble polynomial in which only the coefficients of the M-th order of the maximum order and the zeroth order of the minimum order are 1 and the coefficients of the other orders are 0, it can be understood that the optical disk device can be cheaply constructed in view of the calculating amount and the circuit scale in execution. Further, there is no feedback (cyclic) structure in FIG. 49. Therefore, as mentioned above, even when an error exists in the inputted data, it can be understood that this error is diffused by M-bits at most by the descramble.

The scramble decoding circuit is not limited to the construction for performing the sequential outputting operation every 1 bit with respect to the sequential input every 1-bit as in FIG. 49, but can also use the construction of a sequential input-output type every plural bits irrespective of the value of M. FIG. 50 is a block diagram showing the construction of a scramble decoding circuit for performing the outputting operation every M-bits with respect to the sequential input every M-bits. In FIG. 50, the scramble decoding circuit 401 is constructed by M 1-bit memories and M-XOR circuits. In FIG. 50, for convenience, only three 1-bit memories 5011, 5012, 5013 among the M 1-bit memories and only three XOR-circuits 5021, 5022, 5023 among the M-XOR circuits are shown, and the other 1-bit memories and the other XOR circuits are not shown.

In the descramble using this scramble decoding circuit 5001, the M 1-bit memories (5011, 5012, 5013, and others) are respectively reset in advance, and hold value 0. (L+K) bits of a descramble object are sequentially inputted to the scramble decoding circuit 5001 every M-bits. (L+K) bits sequentially outputted every M-bits with respect to this sequential input are descrambled data. Similar to the scramble decoding circuit 4901 of FIG. 49, it can be understood that this scramble decoding circuit 5001 outputs a value provided by calculating the exclusive logical sum every bits separated by M-bits as the descrambled data. FIG. 49 shows the scramble decoding circuit of a 1-bit input-output type. In contrast to this, it can be understood that FIG. 50 shows the scramble decoding circuit of an M-bit input-output type for performing processing in a bit parallel arrangement. The construction for performing the processing in the bit parallel arrangement as shown in FIG. 50 can be also naturally used even when a polynomial having value 1 in the coefficients of the. M-th order of the maximum order and the zeroth order of the minimum order and some of the coefficients of the other orders is used as the scramble polynomial. Further, the number of input and output bits of a (2·M) bit input-output type and a (4·M) bit input-output type, etc. can be naturally arbitrarily constructed.

The descrambled data of the (L+K) bits are obtained by the scramble decoding circuit explained above. The L-bits of first to L-th bits of the (L+K) bits are a portion of the seed before the scramble, and the K-bits of (L+1)-th to (L+K)-th bits are a portion of the data of a scramble object before the scramble. The scramble decoding circuit particularly outputs the K-bits of the (L+1)-th to (L+K)-th bits as the original data before the scramble among these (L+K) bits. The portion of the seed of the remaining L-bits of the first to L-th bits before the scramble may be treated similarly to the procedure described in the above scramble coding method. The separation of the seed has been explained in detail in the above description. Therefore, no part playing its role is shown in FIGS. 49 and 50.

The scramble decoding circuit in the twelfth embodiment mode has been explained as mentioned above. The recording method applying the above scramble coding method thereto in the twelfth embodiment mode will next be explained. In a memory device, there are a magnetic disk device called a HDD (Hard Disk Drive), an optical disk device using an optical disk called a CD (Compact Disc) and a DVD (Digital Versatile Disc) a magnetic tape device, etc. Further, there are also semiconductor memories called a FLASH memory, a DRAM (Dynamic Random Access Memory) and a SRAM (Static Random Access Memory), etc. The recording method explained below is not limited to any one of these memory devices in applicability. Therefore, the explanation is made without any particular limit. This recording method is constructed by the following steps 1 to 2.

Step 1 (scramble step): The scramble is performed by the above scramble coding method or its circuit with respect to data to be recorded.

Step 2 (recording step): The scrambled data are recorded to a recording medium. For example, the memory device is used in the secondary storage of data treated in a host (computer) and a use for storing (recording) the data of a voice and a dynamic image. In the former case, the memory device (or its front end portion and this description is omitted hereinafter) receives data of a predetermined size (U-bits) to be recorded to the recording medium from the host. In the latter case, the memory device receives the data of the predetermined size from a part for compressing information by controlling the data of the voice and the dynamic image (there is a case in which apart for making an error correction, etc. explained hereinafter is called a front end portion, but this information compressing part is called a backend portion). The unit of these data is called a sector. The memory device also receives a logic address (information showing the order of the sector) of these data together with these data.

The memory device receiving the logic address recognizes a physical address (information showing the position of the memory medium) to which these data should be recorded from the logic address. The logic address and the physical address may be set to the same value. Otherwise, the logic address and the physical address are converted by a predetermined rule and may be set to different values so as to get suitable access to the recording medium (record and regeneration). Otherwise, the logic address and the physical address may be also converted so as to avoid a breakdown area of the memory area.

Thus, in the step 1, the memory device scrambles the data to be recorded by the above scramble coding method or its circuit. In the step 1, the size (k-bits) of the data of the scramble object in the above scramble coding method may be defined in advance in the execution of the present invention such that this size is equal to the size of the sector (namely, K=U). Further, the size (L-bits) of the seed in the above scramble coding method may be also defined in advance in the execution of the present invention. Thus, in the step 1, the data of the K-bits to be recorded are converted to data of the (L+K) bits to be recorded.

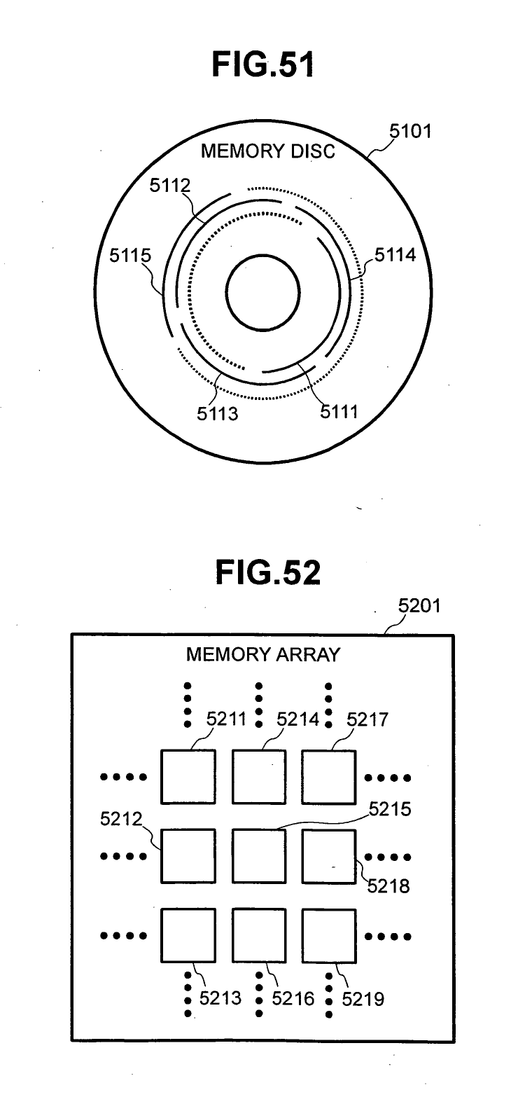

Next, in the step 2, the memory device records these scrambled data of the (L+K) bits to the position of the memory medium shown by the physical address. For example, a case in which this physical address is a value of 19 will be explained. FIG. 51 is a view showing the memory medium of a disk type used in the memory device. In FIG. 51, it is supposed that the values of physical addresses 17, 18, 19, 20, 21, etc. are respectively allocated in advance to memory are as (tracks) 5111, 5112, 5113, 5114, 5115, etc. of the memory disk 5101. The memory device using this memory disk 5101 records the scrambled data of the (L+K) bits to be recorded to the value of 19 in the physical address to the memory area 5113. FIG. 52 is a view showing the memory medium of an array type used in the memory device. In FIG. 52, it is supposed that the values of physical addresses 11, 12, 13, 18, 19, 20, 25, 26, 27,etc. are respectively allocated in advance to memory areas (memory element arrays) 5211, 5212, 5213, 5214, 5215, 5216, 5217, 5218, 5219, etc. of the memory array 5201. The memory device using this memory array 5201 records the scrambled data of the (L+K) bits to be recorded as the value of 19 in the physical address to the memory area 5215.

As explained above, the memory device for recording data to the memory medium can obtain the main effects of the present invention explained in the above scramble coding method and the scramble decoding method. When the above scramble coding method is not applied, the data of the (L+K) bits are recorded by applying the recording place of the data of L-bits. Therefore, it can be understood that the necessary memory area is slightly increased so that a slight change in format efficiency is caused.

In the above explanation, in the step 1, the size (K-bits) of the data of the scramble object is set to be equal to the size (U-bits) of the sector, but is not limited to this case. If the size of the data of the scramble object is defined in advance in the execution of the present invention, this size may be set in any way. For example, with respect to the data of plural (N) sectors, one of seeds of the L-bits is selected, and (N·U) bits provided by continuously connecting these data of the plural sectors are scrambled by using this seed of the L-bits (namely, K=N·U). Thus, the (L+N·U) bits as a result are recorded to the memory medium.

Otherwise, with respect to the data of the plural (N) sectors, one of the seeds of the L-bits is selected, and data U-bits of these plural sectors are respectively scrambled by using this seed of the L-bits (namely, K=U). Namely, the data of each sector are scrambled by using the same seed. Thus, N-results of the (L+U) bits are respectively obtained, but the L-bits of the respective first to L-th bits of the other (N−1) results except for one of these N-results are disused. Thus, the (L+U) bits as one of these results and the (N−1) U-bits are recorded to the memory medium. The L-bits of the respective first to L-th bits of the (N−1) results are disused because the scramble is performed by using the same seed so that all the first to L-th bits of the data after the scramble are the same with respect to the N-results. Namely, these L-bits may be disused since it is redundant.

As mentioned above, a required memory area can be reduced and format efficiency can be improved by treating plural (N) sectors with respect to one seed of the L-bits in comparison with a case in which one sector is treated with respect to one seed.

Further, in the above explanation, in, the step 1, the seed of the L-bits is selected and this seed and the data of K-bits as the scramble object are scrambled. The (L+K) bits as this result are recorded in the step 2. However, for example, with respect to L′<L, the seed of L′-bits may be selected and an extension seed of the L-bits may be constructed by overlapping and using the bits of the seed of these L′-bits. In this case, this extension seed and the data of the K-bits as the scramble object are scrambled. The seed of these L′-bits and the K-bits of (L+1)-th to (L+K)-th bits of the result of this scramble may be also recorded in the step 2.

As a more concrete example, in the step 1, the seed of 8 bits is selected and such four seeds are continuously connected and constitute the extension seed of 32 bits. The extension seed of 32 bits and the data of the K-bits as the scramble object are accumulatively calculated by the exclusive logical sum every bits separated by 32. bits and are scrambled. In the step 2, the seed of 8 bits and the K-bits of 33rd to (L+32)-th bits of the result of this scramble are recorded. Such execution may be also performed.

There is a memory device using the memory medium of a general disk type or tape type in which data conversion is performed with respect to data to be recorded so as to be used in record and regeneration, and its result is recorded. Namely, there is a memory device in which the technique of a code (hereinafter called a channel restricting code) such as a run length limit code, a direct current component control code, etc. for restricting channel data (data really stored to the memory medium) so as to satisfy a predetermined condition is used, and the data to be recorded are converted to channel data satisfying this condition, and the channel data of this result are recorded. When the present invention is applied in such a memory device, the data to be recorded are first scrambled by the above scramble coding method, and its result is converted to the channel data by the technique of the channel restricting code, and these channel data are recorded to the memory medium.

In the technique of the channel restricting code, there is a technique in which conversion to every Y-bits of the channel data is performed every X-bits of the data to be recorded. In this case, X and the order M of a scramble equation used in the above scramble coding method may be set to be equal to each other. Further, X and the bit number L of the seed used in the above scramble coding method may be also set to be equal to each other. Namely, data bit numbers treated in the connection of the scramble coding and decoding methods of the present invention and the technique of the channel restricting code may be conformed to each other. At a regenerating time, for example, even when an error in few bits of the regenerating channel data is caused, there is a case in which all decoded X-bits become incorrect when the decoding is performed by using the technique of the channel restricting code. When the data bit numbers treated in the connection are conformed to each other even in such a case, it is avoided to diffuse the error over the boundary of the bit numbers treated in the connection except that the error is diffused to slight data as features of the present invention in the descramble performed later.

Even when M and X are not equal to each other, one of M and X is set to a multiple of the other (e.g., M=4, X=8), or M and X are set-so as not to be mutually primes (the greatest common divisor is not 1) (e.g., M=8, X=12), etc. to obtain an effect close to that obtained in the case in which M and X are equal to each other. Thus, it can be understood that it is avoided to greatly diffuse the error over the boundary of the bit numbers treated in the connection although it depends on the equilibrium of the above technique and an error correcting code described later.

In the general memory device, there is a device having a possibility that an error in data is caused in a process from the record using the memory device until the regeneration using the memory device through storage using the memory medium. In such a memory device, the technique of the error correcting code is applied to the data to be recorded. Namely, redundant data are added to the data to be recorded, or the data to be recorded are converted to data having a redundancy degree, and its result is recorded to the memory medium. Thus, even when an error in regenerated data is caused, this error can be restored.

When the present invention is applied in such a memory device, the data to be recorded are first changed to an error correcting code by using the technique of the error correcting code, and its result is scrambled by the above scramble coding method, and these scrambled data are recorded to the memory medium. Thus, when an error in the regenerated data is caused at the regenerating time, this error is diffused to only slight data within these regenerated data in the descramble. Therefore, there is a possibility that these data can be restored to the original data by an error correction made later. In contrast to the present invention, if a method for diffusing the error to all data in the descramble is applied, this method exceeds error correction ability of the error correcting code in this case so that no original data can be restored. The effects of the present invention will be understood from the above description.

Further, another application method of the present invention to the memory device applying the technique of the error correcting code thereto will be explained. First, the data to be recorded are scrambled by the above scramble coding method, and its result is changed to an error correcting code by using the technique of the error correcting code, and its error correcting coded data are recorded to the memory medium. Thus, when an error in regenerated data is caused at the regenerating time, no descramble for diffusing the error is performed before the error correcting code. Therefore, the possibility of exceeding the correction ability of the error correcting code is reduced in comparison with the above case in which the descramble is performed before the error correcting code. Even when the error is caused by exceeding the correction ability of the error correcting code, this error is diffused to only slight data within the regenerated data in the descramble. Therefore, the original data can be restored in the data except for the error portion. In contrast to the present invention, if the method for diffusing the error to all data in the descramble is applied, the error is diffused to the entire data in this case.

In the technique of the error correcting code, there is a technique in which the data to be recorded are respectively treated as 1 symbol every Z-bits of the data to be recorded. For example, Z-bits are treated as 1 symbol in an RS (Reed-Solomon) code of GF (2ˆZ) relatively often applied to a general field among the error correcting code. (Here, GF is an abbreviation of Galois Field and means a finite field.) In such an error correcting code, the error correction is made in a symbol unit. Accordingly, in such a case, Z and the order M of the scramble equation used in the above scramble coding method may be set to be equal to each other. Further, Z and the bit number L of the seed used in the above scramble coding method may be also set to be equal to each other. Namely, the data bit numbers treated in the connection of the scramble coding and decoding methods of the present invention and the technique of the error correcting code may be conformed to each other. For example, even when an error in generated data is caused at the regenerating time, it is avoided to diffuse the error over the boundary of the bit numbers treated in the connection except that the error is diffused to slight data as features of the present invention in the descramble when the data bit numbers treated in the connection are conformed to each other. Even when M and Z are not equal to each other, one of M and Z is set to a multiple of the other (e.g., M=16, X=8), or M and X are set so as not to be mutually primes (the greatest common divisor is not 1), (e.g., M=8, X=12), etc. to obtain an effect close to that obtained in the above conformity case. Thus, it can be understood that it is avoided to greatly diffuse the error over the boundary of the bit numbers treated in the connection.

In the general memory device, when data recorded to adjacent positions of the memory medium have correlation, there is a possibility that this correlation has a bad influence in the recording and regenerating processes. Therefore, there is a device in which the recorded data are scrambled by a predetermined method. To discriminate this scramble from the scramble of the present invention, this scramble is called a second scramble and the scramble of the present invention is called a first scramble. When only the scramble of the present invention is described, the scramble of the present invention is simply called the scramble. The above description will be explained in more detail by using a simple example. When all first data to be recorded are 0 and all second data to be recorded are similarly 0, and these first and second data are stored to adjacent positions of the memory medium, these first and second data have a bad influence on each other in the recording and regenerating processes. As a result, it is difficult to normally regenerate the data in the memory device. In such a memory device, to avoid this problem, the second scramble is performed with respect to these data of sectors by a predetermined method for providing different results even when these data are the same. Namely, for example, the second scramble is performed with the logic address and the physical address of each sector as a seed. Thus, if the values of the respective seeds are different from each other, the respective data are different from each other by the second scramble so that the degree of the bad influence mutually exerted in the recording and regenerating, processes is reduced. Since a variable seed is used in the first scramble, different data are recorded except for the selecting case of the same seed even when the same data should be recorded to the same place of the memory medium. In contrast to this, a proper seed is used with respect to the recording place of the memory medium as mentioned above in the second scramble. Therefore, when the same data should be recorded to the same place of the memory medium, the same data are recorded. Thus, it can be understood that the first scramble and the second scramble are different techniques.

When the present invention is applied in such a memory device, the second scramble is first performed with respect to the data to be recorded, and the first scramble of its result is performed by the scramble coding method of the present invention, and its result is recorded to the memory medium. Thus, in the rescramble (the regenerated data are descrambled and the first scramble is again performed by using the value of a different seed with respect to the original data obtained by this descramble), it is not necessary to perform the rescramble through the second scramble. Namely, it is possible to omit the decoding and coding procedures of the second scramble. Further, another application method of the present invention to the memory device applying the second scramble thereto will be explained. First, the first scramble is performed with respect to the data to be recorded by the scramble coding method of the present invention. The second scramble is performed with respect to the result of the first scramble, and its result is recorded to the memory medium. As mentioned above, one of objects for performing the second scramble is that no data stored to adjacent positions of the memory medium have correlation as little as possible. Therefore, the second scramble is performed by mutually adding a proper pseudo random series (a maximum length series, an Maximum length sequence, a maximum length sequence) (by the exclusive logical sum in the surplus system with 2 as a devisor), etc. with respect to the recording place of the memory medium. Accordingly, no characteristics originally provided in the pseudo random series are thus changed by the first scramble performed by the scramble coding method of the present invention. Conversely, when the procedures of the first and second scrambles are replaced, the first scramble performed by the scramble coding method of the present invention changes the characteristics originally provided in the pseudo random series.

Further, in the general memory device, there is a device in which a logic address or a physical address is added to the data to be recorded so as to inspect whether the data of an object sector are correctly regenerated at the regenerating time. There is also a device in which information for security and the protection of copyright is added to the data to be recorded to limit the regeneration of the data with respect to a limited user, etc. Further, there is a device in which redundant data are added to the data to be recorded, or the data to be recorded are converted to data having a redundancy degree by applying the technique of an error detection code (EDC) and a so-called CRC (Cyclic Redundancy Check) code, etc. to inspect whether the result of the error correction is normal data after the error correction-at the regenerating time. In the memory device using such a technique, the scramble is first performed with respect to the data to be recorded by the scramble coding method of the present invention, and such a technique may be applied to this result. Otherwise, such a technique is first applied and the scramble may be also performed with respect to this result by the scramble coding method of the present invention. Otherwise, such a technique is first applied and the scramble is performed with respect to only a portion of the data to be recorded and included in this application result by the scramble coding method of the present invention, and no scramble coding method of the present invention maybe also applied to the portion of information added by such a technique. If the scramble coding method of the present invention is also applied to the portion added by such a technique, the effects of the present invention can be also given to this portion. Further, if no scramble coding method of the present invention is applied to the portion added by such a technique, for example, this portion can be referred without performing the descramble at the regenerating time. Otherwise, with respect to the technique of the error detection code, the operation of the error detection can be performed before the descramble is performed at the regenerating time.

Further, in the general memory device, there is a device in which the order of the data to be recorded is rearranged by using a predetermined rule and its result is recorded. For example, this is called interleave (interlacing) in the error correcting code. In the error correcting code, this rearrangement is performed to strengthen correction ability with respect to a certain error. In the memory device in which the logic address or the physical address is added to the data to be recorded, there is a structure in which this arrangement is performed so as to store its information at a predetermined interval in the recording medium. The scramble coding method of the present invention can be naturally applied both before and after such an arrangement of the data is performed.

If the present invention is applied, different data can be really recorded to the memory medium even when the same data should be recorded to the same place of the memory medium. Accordingly, the present invention can be applied without limiting the present invention to an increase in the rewritable number of the memory medium as a main object of the present invention mentioned above. For example, when data stored to adjacent positions of the memory medium mutually have a bad influence in the recording and regenerating processes, a seed for reducing this influence is selected in consideration of the data stored to the adjacent positions of the memory medium, and the scramble is performed by using this seed, and its result may be recorded. Further, for example, if direct current component control of channel data, etc. are performed by the technique of a restricting code, the seed (for example, for further reducing the direct current component) for setting the final channel data to be more suitable in nature in the record and the regeneration is selected, and the scramble is performed by using this seed and its result may be also recorded (by converting this result to the channel data).

The recording method in the twelfth embodiment mode has been explained as mentioned above.

The recorder for embodying the above recording method will next be explained. In the following description, when it is not particularly said, the explanation is made by using the optical disk device using the optical disk.

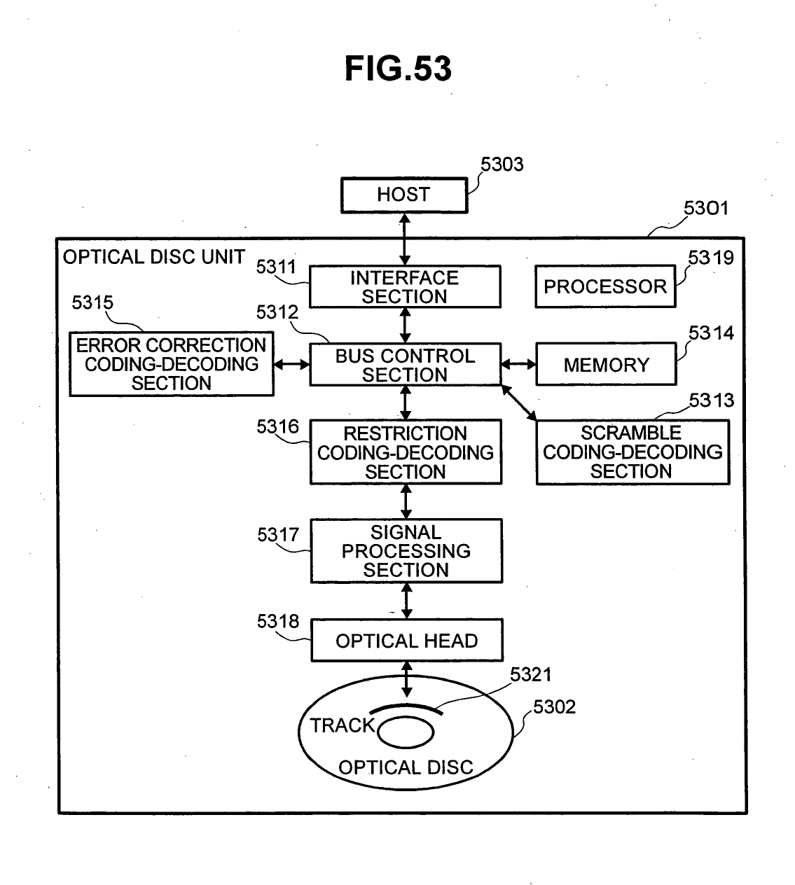

FIG. 53 is a block diagram showing the construction of the optical disk device for storing host data. FIG. 53 includes a regenerating function as well as a recording function to use this figure in the explanation of a regenerator described later. The optical disk device 5301 of FIG. 53 is a memory device using the optical disk 5302 as a memory medium and storing data of the host 5303. The optical disk device 5301 is constructed by an interface section 5311 for performing interface with the host 5303, a bus control section 5312 for mediating data buses so as to transfer data between suitable parts, a scramble coding-decoding section for executing the above scramble coding method and the scramble decoding method, a memory 5314 for storing work data, an error correction coding-decoding section 5315 for performing error correction coding and its decoding (error correction), a restriction coding-decoding section 5316 for performing channel restriction coding and its decoding, a signal processing section 5317 for generating a recording signal and processing a regenerating signal, an optical head 5318 for irradiating a light beam to the optical disk and detecting this light beam, a processor 5319 for controlling the entire internal operation of the optical disk device 5301, an unillustrated spindle motor, etc.

When the interface section 5311 within the optical disk device 5301 receives data to be recorded (and a logic address) from the host 5303, the interface section 5311 stores their data into the memory 5314 through the bus control section 5312 (hereinafter this description is omitted). Next, the memory 5314 sends the stored data to be recorded to the scramble coding-decoding section 5313. The scramble coding-decoding section 5313 first selects a seed and then scrambles this seed and its data and stores its result into the memory 5314. Next, the memory 5314 sends the stored and scrambled data to the error correction coding-decoding section 5315. The error correction coding-decoding section 5315 generates redundant data with respect to these data, and stores its result to the memory 5314. Next, when it is prepared that the optical head 5318 can get access to an object track 5321 (corresponding to its logic address) of the optical disk 5302 rotated by an unillustrated spindle motor, the memory 5314 sends the stored and error-correction coded data to the restriction coding-decoding section 5316. The restriction coding-decoding section 5316 converts these data to channel data, and sends its result to the signal processing section 5317. Next, the signal processing section 5317 sends a recording signal regenerated with respect to these data to the optical head 5318. The optical head 5318 records this recording signal to the object track 5321 (corresponding to its logic address) of the optical disk 5302. Thus, the optical disk device 5301 records the received data to be recorded from the host 5303 to the optical disk 5302.

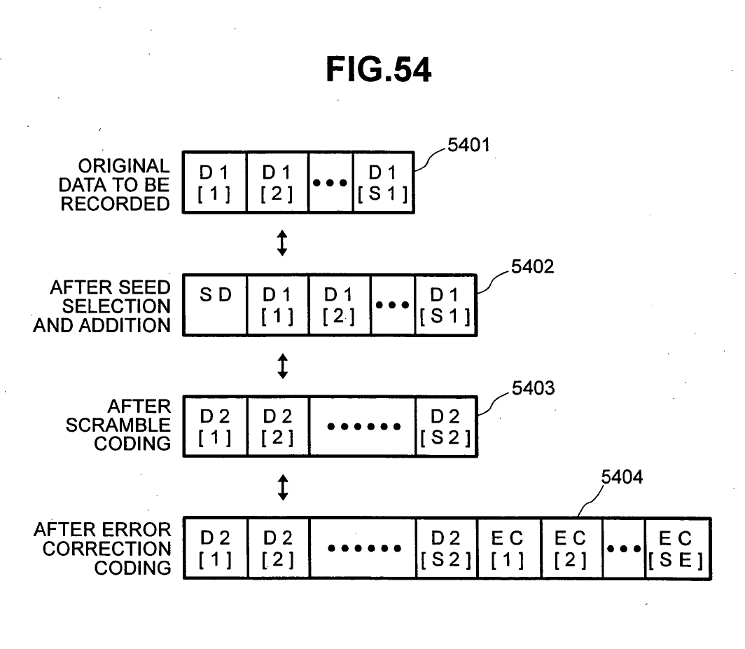

FIG. 54 is a view showing the transition of the data generated in the recording process by the above optical disk device 5301. In FIG. 54, it is supposed that one grating shows data of a predetermined bit number, and its bit number is here set to 8 bits=1 byte. It is also supposed that the size of the selected seed of the scramble coding-decoding section 5313 is 1 byte (L=8), and the scramble coding-decoding section performs the scramble by making an accumulative calculation by the exclusive logical sum every bits separated by 8-bits (M=8, F(x)=xˆ8+1).

In FIG. 54, data 5401 are received data of S1 bytes to be recorded from the host 5303, and its bytes are sequentially set to D1[1], D1[2], . . . , D1[S1]. These S1 bytes maybe naturally set to data of one sector, and may be also naturally set to data of plural sectors. Further, the data 5402 are data of (S1+1) bytes provided by adding (mutually continuously connecting) a seed SD of 1 byte selected by the scramble coding-decoding section 5313 to data 5401, and these bytes are sequentially set to SD, D1[1], D1[2], . . . , D1[S1]. Data 5403 are data of (S1+1) bytes provided by scrambling the data 5402 by the scramble coding-decoding section 5313, and these bytes are sequentially set to D2[1], D2[2], . . . , D2[S2]. Here, S2=S1+1 is set. Inthis case (M=8, F(x)=xˆ8+1), with respect to 1≦i≦2, an i-th byte D2[i] of the data 5403 is set to D2[i]=SD when i=1, and is also set to D2[i]=SD+?(j=1, . . . , i)D1[j] when i≠1. Here, ‘+’ shows the calculation of the exclusive logical sum every bit, and ?(j=1, . . . , i)D1[j] shows that D1[j] is accumulatively calculated in this ‘+’ with respect to j increased one by one from 1 until 1. Data 5404 are data of a result obtained by performing the error correction coding with respect to the data 5403 by the error correction coding-decoding section 5315, and its bytes are sequentially set to D2[1], D2[2], . . . , D2[S2], EC[1], EC[2], . . . , EC[SE]. Namely, the error correction coding-decoding section 5315 generates redundant data EC[1], EC[2], . . . , EC[SE] of SE bytes with respect to the data 5403. Data finally recorded to the optical disk 5302 become channel data obtained by converting the data 5404 by the restriction coding-decoding section 5316. The present invention is not limited to the above explanation of the optical disk device 5301, but can be modified and embodied in the scope not departing from the features of the present invention. For example, in the above description, data are respectively stored to the memory 5314 when the data are received from the host 5303, and the scramble coding-decoding section 5313 performs the scramble, and the error correction coding-decoding section 5315 performs the error correction coding. However, the present invention can be also executed as follows. Namely, the data received from the host 5303 are sent to the scramble coding-decoding section 5313, and the scramble coding-decoding section 5313 first selects a seed, and next scrambles this seed and its data, and sends its result to the error correction coding-decoding section 5315. The error correction coding-decoding section 5315 generates redundant data with respect to these data, and stores its result into the memory 5314.

FIG. 55 is a block diagram showing the construction of an optical disk device different from that in FIG. 53. In comparison with the optical disk device 5301 of FIG. 53, the optical disk device 5501 of FIG. 55 particularly has no scramble coding-decoding section so that the connection of a bus control section is slightly different from that in FIG. 53. Further, the optical disk device 5501 of FIG. 55 differs from that of FIG. 53 in that a processor 5519 gets access to data stored to a memory 5514. Since the optical disk device 5501 has no scramble coding-decoding section, the processor 5519 executes the scramble coding method and the scramble decoding method of the present invention. Namely, the processor 5519 refers to data within the memory 5514 and performs a predetermined arithmetic operation, and then stores its result into the memory 5514. In processors arranged in the general memory device, there is a processor in which the exclusive logical sum calculation every bit with respect to two numbers of a predetermined bit number is set to a basic calculation and can be executed by a small arithmetic step. Namely, in the case of such execution, it can be understood that the present invention can be cheaply executed in view of the calculating amount if the order M of a scramble equation treated in the present invention is-conformed to an arithmetic bit number of the basic calculation of the processor, and the scramble is performed by making an accumulative calculation by the exclusive logical sum every bits separated by a predetermined bit number. In the processor arranged in the general memory device, there are many cases in which the bit number of the basic calculation is 8 bits, 16 bits or 32 bits. Accordingly, the order M of the scramble equation treated in the present invention may be set to 8, 16 or 32. Further, the present invention is not limited to the constructions of FIGS.53 and 55. If the present invention is executed by setting the bit number (width) of a main data bus of the memory device and the access bit numbers (widths) of the memories (5314 and 5514) to 8, 16 or 32, the order M of the scramble equation treated in the present invention may be also conformed to this number.

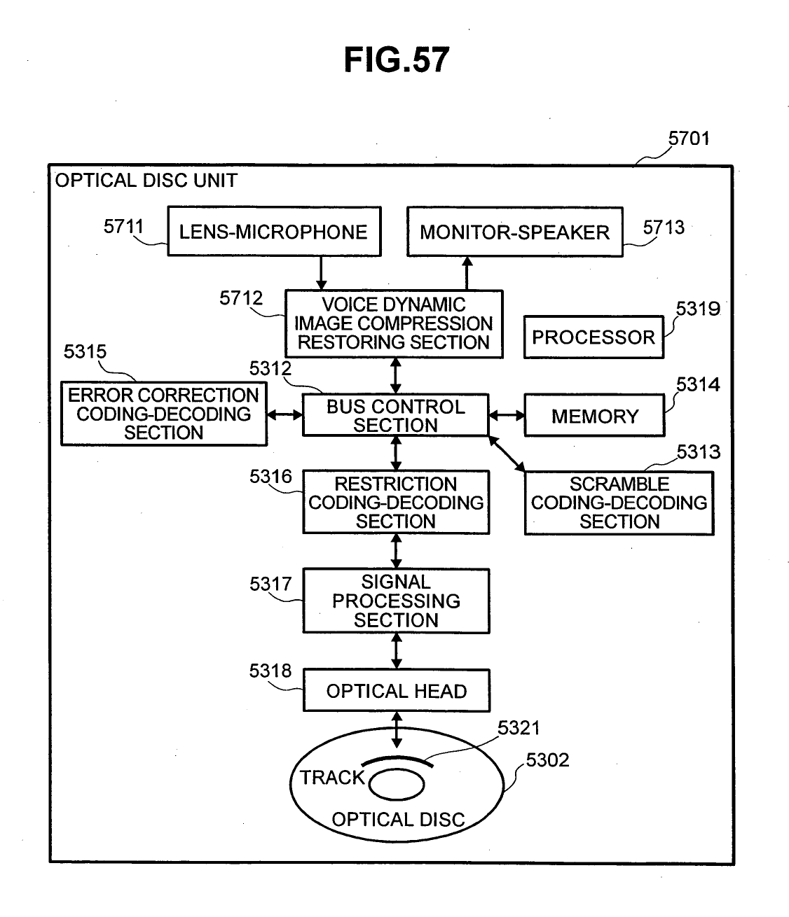

FIG. 56 is a block diagram showing the construction of an optical disk device different from that of each of FIG. 53 and 55. The optical disk device 5601 of FIG. 56 is arranged to store data of a voice and a dynamic image in broadcast. In comparison with the optical disk device 5301 of FIG. 53, this optical disk device 5601 particularly has no interface section. Instead, the optical disk device 5601 has a tuner 5611 for receiving the voice dynamic image data in the broadcast from a broadcast receiving section 5602, and a voice dynamic image compression restoring section 5612 for compressing information of these data and restoring this information at a regenerating time and sending the restored information to a monitor-speaker 5603. FIG. 57 is a block diagram showing the construction of an optical disk device different from that of FIG. 53, 55 or 56. The optical disk device 5701 of FIG. 57 is arranged to store the voice dynamic image data of a camera type. In comparison with the optical disk device 5301 of FIG. 55, this optical disk device 5701 particularly has no tuner. Instead of the tuner, the optical disk device 5701 has a lens -microphone 5711 for obtaining a voice and a dynamic image. Further, the optical disk device 5701 has a built-in monitor-speaker 5713 for displaying the voice dynamic image instead of a construction for outputting data to an external monitor-speaker to display the voice dynamic image. The data may be also outputted to the unillustrated external monitor-speaker. Thus, the present invention can be also embodied such that no host data are stored, but the voice dynamic image data are stored. These uses are merely one use example of the embodiment of the present invention.

The present invention is not limited to the optical disk device explained above, but can be also applied irrespective of the modes of the memory device such as a magnetic disk device, a semiconductor memory, etc. In the above explanation, the rewriting number of the rewritable memory medium is increased as the main object of the present invention. However, the present invention is not limited to such a memory medium, but may be also embodied even when a memory medium able to make only one record (including “write-once” in which the record cannot be made in a recorded place, but can be made in an unrecorded place) and a memory medium for only regeneration are used.

For example, in the kind of DVD, there are DVD-R (Write once) able to make only one record and DVD-ROM (Read Only Memory) for only regeneration in addition to rewritable DVD-RAM (Random Access Memory) and DVD-RW (ReWritable). Thus, in formats (technique used in the record and the regeneration) of these kinds, the same technique is mutually used in e.g., the techniques of the error correction and the channel restricting code, etc. Therefore, in such a device, the circuit scale can be reduced by commonly using (interchanging) a part for fulfilling the functions of these techniques even in a device having interchangeability and able to get access to each of these kinds. For the same reasons, the present invention is not limited to the rewritable memory medium, but may be also embodied even when the memory medium able to make only one record and the memory medium for only regeneration are used.

As mentioned above, for example, when data stored to adjacent positions of the memory medium mutually have a bad influence in the recording and regenerating processes, a seed for reducing this influence is selected in consideration of the data stored to the adjacent positions of the memory medium, and the scramble is performed by using this seed, and its result may be also recorded. Further, for example, when the direct current component control of channel data, etc. are performed by the technique of a restricting code, the seed (for example, for further reducing the direct current component) for setting the final channel data to have a more suitable nature in the record and the regeneration is selected, and the scramble is performed by using this seed, and its result may be also recorded (by converting this result to the channel data). Therefore, the present invention is not limited to the increase in the rewritable number of the memory medium as the above main object of the present invention, but may be also applied to a case in which the memory medium able to make only one record and the memory medium for only regeneration are used.

Further, in the above interchangeable device, information showing whether the record is made by applying the present invention, the order M of its scramble polynomial and the scramble polynomial itself may be also recorded to a predetermined area of the memory medium for storing control information (e.g., the information of a conforming specification, characteristics of the memory medium such as light reflectivity, etc.) of the entire memory medium so as to recognize whether it is the memory medium recorded by applying the present invention. Further, similar to the explanation made in the above recording method, with respect to data addition of the techniques of the scramble and the channel restricting code of the present invention, the techniques of the scramble and the error correcting code of the present invention, the scramble and the second scramble of the present invention, and the techniques of the scramble and the error detection code of the present invention, etc., its application order and the bit number of connection can be naturally changed in the recorder. Further, in the process of transition of data until the data are recorded to the memory medium, the order of the data may be naturally rearranged by using a predetermined rule. In this rearrangement, for example, in the optical disk device 5301 of FIG. 53, the present invention can be embodied by outputting the data stored to the memory 5314 in conformity with this predetermined rule instead of the storing order.

The recorder in the twelfth embodiment mode has been explained as mentioned above.

The regenerating method and the regenerator corresponding to the above recording method and the recorder in the twelfth embodiment mode will next be explained. Here, the data of an object are data recorded and stored to the memory medium by the above recording method or the recorder. The regenerating method is constructed by the following steps 1 to 2.

Step 1 (regenerating step): Scrambled data are regenerated from the memory medium.

Step 2 (descramble step): The descramble is performed by the above scramble decoding method or its circuit with respect to the regenerated (scrambled) data.

When the memory device controls data of the host and a voice and a dynamic image and receives a logic address to be regenerated from the memory medium from a part for compressing information, the memory device recognizes a physical address corresponding to the logic address. Thus, the memory device regenerates the data recorded to the memory medium by the above recording method from an object position of the memory medium shown by the physical address in the step 1. Next, the memory device scrambles the regenerated data by the above scramble decoding method or its circuit in the step 2.

In the optical disk device of FIG. 53, the interface section 5311 within the optical disk device 5301 receives the logic address to be regenerated from the host 5303. When it is prepared that the optical head 5318 can get access to an object track 5321 (corresponding to this logic address) of the optical disk 5302 rotated by an unillustrated spindle motor, the optical head 5318 first regenerates a signal from the object track 5321 (corresponding to this logic address) of the optical disk 5302, and sends this signal to the signal processing section 5317. The signal processing section 5317 converts this signal to channel data by processing this signal. Next, the restriction coding-decoding section 5316 performs reverse conversion (decoding with respect to the channel restriction coding) with respect to the conversion in the record, and stores its result into the memory 5314. Next, the memory 5314 sends the stored and reversely converted data to the error correction coding-decoding section 5315. The error correction coding-decoding section 5315 makes an error correction (decoding with respect to the error correction coding) with respect to these data, and corrects the incorrect data within the memory 5314. Next, the memory 5314 sends the stored data made with respect to the error correction to the scramble coding-decoding section 5313. The scramble coding-decoding section 5313 descrambles these data by the above descramble decoding method, and stores its result into the memory 5314. Next, the descrambled data are stored into the memory 5314 as data to be regenerated. Thus, the optical disk device 5301 regenerates the received data of the logic address to be regenerated from the host 5303 from the optical disk 5302, and sends the data to be regenerated to the host 5303.

As explained above, in the regenerating method and the regenerator, the regeneration is performed by performing the decoding with respect to the coding in the reverse order with respect to each technique (data addition, the rearrangement of the data order, etc. in the techniques of the channel restricting code, the error correcting code, the second scramble, the error detection code, etc.) used in the process until the record to the memory medium in the above recording method and the recorder. Thus, it can be understood that the above effect of each kind in the present invention is obtained in the explanation from the scramble coding method to the recorder. In the above explanation with respect to FIG. 54, when data 5403 are descrambled to data. 5402, a first byte SD of the data 5402 is set to SD=D2[1]. With respect to 1≦i≦S1, an (i+1)-th byte D2[i] of the data 5402 is calculated as D2[i]=D2[i]+D2[i+1]. Thus, it can be understood that the present invention can be cheaply embodied in view of the calculating amount even when the present invention is embodied such that the descramble is performed by using a processor arranged in the general memory device.

If the scramble is performed by collectively treating plural sectors in the record, only a suitable sector among these sectors may be sent to the host as the data to be regenerated. Further, if the memory medium stores information showing whether the record is made by applying the present invention, the order M of its scramble polynomial and its scramble polynomial itself in an interchangeable device, the memory device first regenerates this information before the data are regenerated, and makes a judgment.

The regenerating method and the regenerator in the twelfth embodiment mode have been explained as mentioned above. The present invention is not limited to the above scramble coding-decoding method, the recording-regenerating method, and its device, but is also effective in the memory medium in which data are recorded and stored by the above recording method or its device.

As mentioned above, the scramble coding method, the scramble decoding method, the recording method and the regenerating method of the present invention have been explained with the respective basic embodiment modes as the twelfth embodiment mode together with circuits and devices for embodying these methods.

There is a thesis (hereinafter called a first literature) of title “Optical Disc System for Digital Video Recording”, on pp. 912 to 919 of Vol. 39 of Japanese Journal of Applied Physics (Jpn. J. Appl. Phys.) published in February, 2000. The first literature relates to an optical disk device using a blue purple laser. Hereinafter, a mode applying the present invention thereto in the optical disk device shown in the first literature as a more concrete embodiment mode of the present invention will be explained as a ninth embodiment mode.

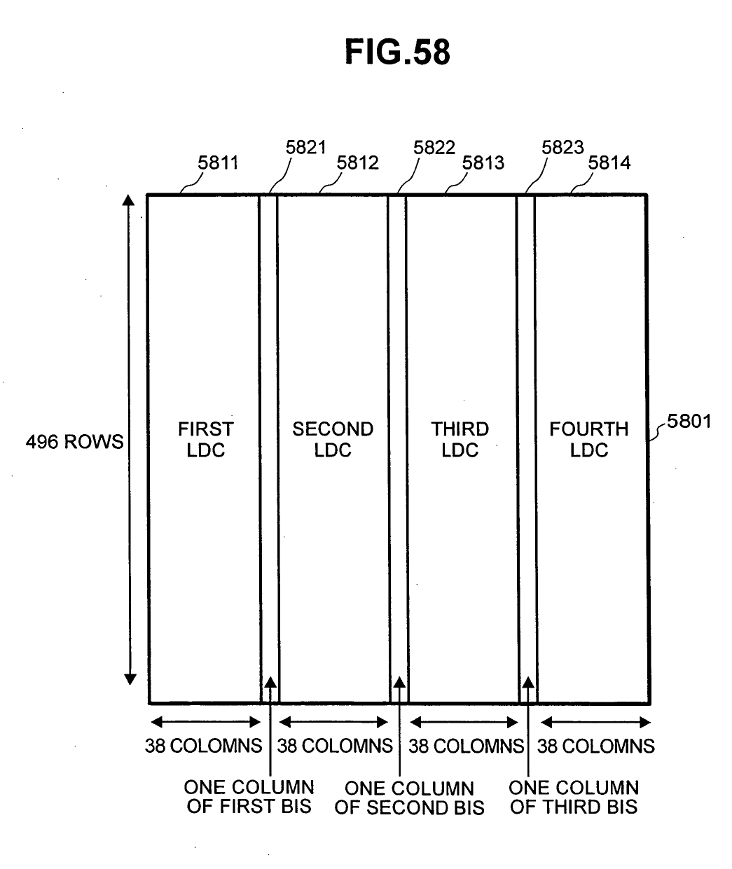

First, the format of the first literature will be explained. FIG. 58 is a view showing a data arrangement in the optical disk device of the first literature (FIG. 2 on page 914 in the first literature). In FIG. 58, an ECC (Error Correction Code) data structure 5801 is constructed by 496 rows and 155 columns, and a portion of one row and one column is constructed by data of 1 byte. Namely, the ECC data structure 5801 is constructed by 76880 bytes. The ECC data structure 5801 is divided into an area of a first LDC (Long Distance Code) 5811, a second LDC 5812, a third LDC 5813 and a fourth LDC 5814 respectively constructed by 496 rows and 38 columns (18848 bytes), and an area of a first BIS (Burst Indicator Subcode) 5821, a second BIS 5822 and a third BIS 5823 respectively constructed by 496 rows and one column (496 bytes).

In the first literature, 32 sectors are treated as one block in the data of sectors of 2048 bytes in size. 4 bytes as an EDC are added to each sector. All data of 65664 (=32·(2048+4)) bytes are arranged in the area (432·152=65664) of each LDC of all 152 (=4·38) columns every 432 bytes, and these 432 bytes of each column of the area of each LDC are further divided into two pieces of 216 bytes each and are arranged. At this time, the arrangement is performed such that 9.5 pieces of the data of these 216 bytes constitute one sector and its EDC. With respect to the data of each 216 bytes of two pieces in each column of the area of each LDC, the error correction coding is performed by using GF(2ˆ8)(248, 216) RS codes so that data of each 248 bytes every two pieces in each column of the area of each LDC, i.e., data of 496 bytes in total in each column of the area of each LDC are obtained. Here, the GF (2ˆ8)(248, 216) RS codes mean Reed-Solomon codes of all 248 symbols (i.e., adding a redundant portion 32 symbols) including an information portion 216 symbols treated with 8 bits=1 byte as one symbol. Thus, the area of each LDC is constructed.

On the other hand, with respect to the respective data of 240 bytes, these 240 bytes are further divided into 8 pieces of 30 bytes each and are arranged in each BIS area of three columns in total. With respect to the data of each 30 bytes of 8 pieces in each column of each BIS area, the error correction coding is performed by using the GF (2ˆ8)(62, 30) RS codes, and data of each 62 bytes of 8 pieces in each column of each BIS area, i.e., data of 496 bytes in total in each column of each BIS area are obtained. 720 bytes in total before the error correction coding of all the BIS areas are constructed by addresses and copyright management and a spare (preliminary) area with respect to this ECC data structure 5801.

The ECC data structure 5801 is constructed in this way. With respect to this ECC data structure 5801, the optical disk device sequentially records each byte of the rows in FIG. 58 to the optical disk from leftward to rightward. After the right-hand end of this row, the optical disc unit also sequentially records each byte to the optical disk from leftward to rightward from the byte at the left-hand end of the next row. In reality, each byte is not recorded as it is, but is converted to channel data by the technique of a predetermined channel restricting code, and these channel data are recorded A pattern called SYNC and designed so as to perform synchronization by the optical disk device at the regenerating time is added just before a first byte of each row of the ECC data structure 5801, and is also recorded. Further, information designed so as to recognize an access position by the optical disk device is recorded to the memory medium at an interval every 31 rows of the ECC data structure 5801.

Hereinafter, a mode applying the present invention thereto in the optical disk device shown in the first literature will be explained. Here, it is supposed that the bit number of a treated seed is set to 8 bits (L=8). A required memory area is increased by the seed at its minimum, i.e., 8 bits=1 byte by applying the present invention. However, this memory area is arranged in the spare area of 720 bytes in total before the error correction coding of all the BIS areas is performed. In the following explanation, the seed used in the scramble is set so as to be already selected. In the following description, 6 kinds of-main application examples are shown.

### APPLICATION EXAMPLE 1

When 32 sectors constituting this ECC data structure 5801 are sequentially set to first to 32nd sectors, the seed of 1 byte and the first to 32nd sectors of each 2048 bytes are continuously connected and are scrambled. A first byte of the data of this scramble result is arranged in the spare area. With respect to 1≦i≦32, 2048 bytes of (2048·(i−1)+2)-th to (2048·(i−1)+2049)-th bytes of the data of this result are treated as an i-th sector after the scramble, and 4 bytes of its EDC are added and these added data are arranged in a place for originally arranging the data of the i-th sector and its EDC (by the optical disk device of the first literature) in the ECC data structure 5801. Namely, with respect to 1≦i≦(32·2048), an (i+1)-th byte of the data of this result is arranged in a place in which the (i+1)-th byte of the data before the scramble should be originally arranged. A generated EDC is then added to this result (sector after the scramble). Next, similar to the original case, the error correction coding is performed in both the BIS area and the LDC area, and the ECC data structure 5801 obtained by this error correction coding is recorded similarly to the original case.

### APPLICATION EXAMPLE 2

The seed of 1 byte, and 720 bytes before the error correction coding of the BIS area except for an arranging portion of the seed after the scramble described later (i.e., 719 bytes if the seed is arranged in 1 byte of the spare area, and plural bytes are removed from 720 bytes if the seed is arranged in the plural bytes), and first to 32nd sectors of each 2048 bytes are continuously connected and are scrambled. A first byte of the data of this scramble result is arranged in the spare area as the seed after the scramble. With respect to 1≦i≦(719+32 2048), an (i+1)-th byte of the data of this result is arranged in a place in which the (i+1)-th byte of the data before the scramble should be originally arranged, and an EDC generated with respect to this result is added. Next, similar to the original case, the error correction coding is performed in both the BIS area and the LDC area, and the ECC data structure 5801 obtained by this error correction coding is recorded similarly to the original case.

### APPLICATION EXAMPLE 3

The seed of 1 byte and first to 32nd sectors of each 2052 bytes after the addition of the EDC are continuously connected and are scrambled. A first byte of the data of this scramble result is arranged in the spare area. With respect to 1≦i≦(32·2052), an (i+1)-th byte of the data of this result is arranged in a place in which the (i+1)-th byte of the data before the scramble should be originally arranged. Next, similar to the original case, the error correction coding is performed in both the BIS area and the LDC area, and the ECC data structure 5801 obtained by this error correction coding is recorded similarly to the original case.

### APPLICATION EXAMPLE 4

With respect to the seed of 1 byte and the bytes of 432 rows and 152 columns of all the LDC areas before the error correction coding is performed (after the addition of the EDC), each byte in FIG. 58 is sequentially continuously connected from leftward to rightward. After the right-hand end of this row, each byte is sequentially continuously connected from leftward to rightward from the byte at the left-hand end of the next row, and is scrambled. A first byte of the data of this scramble result is arranged in the spare area. With respect to 1≦i≦(432·152), an (i+1)-th byte of the data of this result is arranged in a place in which the (i+1)-th byte of the data before the scramble should be originally arranged. Next, similar to the original case, the error correction coding is performed in both the BIS area and the LDC area, and the ECC data structure 5801 obtained by this error correction coding is recorded similarly to the original case.

### APPLICATION EXAMPLE 5

With respect to the seed of 1 byte and the bytes of 432 rows and 152 columns of all the LDC areas before the error correction coding is performed (after the addition of the EDC), each byte in FIG. 58 is sequentially continuously connected from upward to downward. After the lower end of this column, each byte is sequentially continuously connected from upward to downward from the byte at the upper end of the next column, and is scrambled. A first byte of the data of this scramble result is arranged in the spare area. With respect to 1≦i≦(432·152), an (i+1)-th byte of the data of this result is arranged in a place in which the (i+l)-th byte of the data before the scramble should be originally arranged. Next, similar to the original case, the error correction coding is performed in both the BIS area and the LDC area, and the ECC data structure 5801 obtained by this error-correction coding is recorded similarly to the original case.

### APPLICATION EXAMPLE 6

With respect to 1≦i≦32, the same seed of 1 byte and the i-th sector of 2048 bytes are continuously connected and are scrambled. A first byte of the data of the scramble result is the same value with respect to all the values of i as mentioned above. Accordingly, the value of i is not limited to all the values, but one or required numbers of the value i are arranged in the spare area. Further, the 2048 bytes of second to 2049th bytes of the data of these results are treated as an i-th sector after the scramble, and 4 bytes of its EDC are added, and the added data are arranged in a place for originally arranging the data of the i-th sector and its EDC (by the optical disk device of the first literature) in the ECC data structure 5801. Next, similar to the original case, the error correction coding is performed in both the BIS area and the LDC area, and the ECC data structure 5801 obtained by this error correction coding is recorded similarly to the original case.

In all the above application examples of six kinds, no spare area for arranging the seed of 1 byte is limited to one place. If there is no margin in the memory area, the seed may be arranged in only one place, and may be also arranged in plural places if reliability is improved.

The main difference between the application examples 1 and 2 is whether 720 bytes before the error correction coding of the BIS area except for the arranging portion of the seed after the scramble are set to a scramble object or not. Namely, in the application example 1, these 720 bytes are not set to the scramble object. In contrast to this, in the application example 2, these 720 bytes are set to the scramble object. In addition to these, for example, the treatment of data of the scramble object can be variously embodied as in a case in which only the first sector is scrambled and the second to 32nd sectors are not scrambled

The main difference between the application examples 1 and 3 is the order of the scramble and the EDC generation and addition. Namely, in the application example 1, the EDC is generated and added to data after the scramble. In contrast to this, in the application example 3, the scramble is performed with respect to the data adding the EDC thereto by including the portion of the EDC. In addition to these, for example, the application order of the scramble and the other techniques can be variously embodied as in a case in which the data after the error correction coding are scrambled.

The main difference between the application examples 3 and 4 is the order of data of the scramble object. Namely, in the application example 3, the data of the scramble object are constructed by continuously connecting the data in the order of the sector. In contrast to this, in the application example 4, the data of the scramble object are constructed by continuously connecting the data in the order of the arrangement of the ECC data structure 5801. Further, the main difference between the application examples 4 and 5 is the order of the data of the scramble object in the ECC data structure 5801. Namely, in the application example 4, the data of the scramble object are constructed by continuously connecting the data in the order of the transversal direction in FIG. 58. In contrast to this, in the application example 5, the data of the scramble object are constructed by continuously connecting the data in the order of the longitudinal direction in FIG. 58. In addition to these, the order of the data of the scramble object can be variously embodied.

The main difference between the application examples 1 and 6 is the number of times of the scramble and the byte number of data as an object. Namely, in the application example 1, the scramble is performed once with respect to data in which all 32 sectors are continuously connected. In contrast to this, in the application example 6, the scramble is performed with respect to each of the 32 sectors. In addition to these, the number of times of the scramble and the byte number of the data as the object can be variously embodied as in a case in which the scramble is performed with respect to the area of each LDC.

As mentioned above, the explanation is made by supposing that the bit number of the seed is 8 bits. However, this bit number can be naturally changed. Further, the order M of the scramble polynomial and the scramble polynomial F(x) can be also variously embodied.

As mentioned above, the mode applying the present invention thereto in the optical disk device shown in the first literature is explained as the ninth embodiment mode.

The present invention is not limited to the above embodiment modes, but can be modified and embodied in the scope not departing from the features of the invention irrespective of the application field.

The main effect of the present invention is that the rewritable number of the memory medium can be increased by a slight reduction in format efficiency, and an error in the data of a descramble object is diffused to only finite slight data by the descramble even when this error exists in the descramble. Accordingly, the present invention can be cheaply embodied in view of the calculating amount and the circuit scale.

In accordance with the present invention, the random seed scramble able to prevent medium deterioration can be applied to the next generation optical disk by adding arbitrary seed data to the original data to be recorded onto the disk and scrambling these data. Further, regeneration can be performed without any problem even when a sector applying the random seed scramble thereto and a sector not applying the random seed scramble thereto are mixed and exist in one optical disk. Further, reading and writing operations can be performed with respect to the same disk even in a device adopting no random seed scramble.

What is claimed is:

1. A data randomizing method, comprising the steps of:
adding seed data used for randomization to data;
determining randomized data of at least one bit that is obtained by an operation using data of at least one bit and randomized data of plural bits, said data of at least one bit being included in the data to which the seed data is added, and writing the randomized data of one bit on a recording medium; and
using a different value for said seed data every time a rewriting process is performed, wherein
a part of the seed data includes a part of a sector number, or a track number.

2. A recording and reproducing apparatus, comprising:
operation means for determining randomized data of at least one bit that is obtained by an operation using data of at least one bit and randomized data of plural bits, said data of at least one bit being included in the data to which seed data for randomization is added; and
write means for writing the randomized data of one bit on a recording medium, wherein
a different value is used for said seed data every time a rewriting process is performed, and a part of the seed data includes a part of a sector number, or a track number.

3. A data randomizing method, comprising the steps of:
adding seed data used for randomization to data;
determining randomized data of at least one bit that is obtained by an operation using data of at least one bit and randomized data of plural bits, said data of at least one bit being included in the data to which the seed data is added,
and writing the randomized data of one bit on a recording medium, and
using a different value for said seed data every time a rewriting process is performed, wherein
a part of the seed data includes at least a part of the number of writing processes performed on an area of the recording medium on which said randomized data of one bit is written.

4. A recording and reproducing apparatus, comprising:
operation means for determining randomized data of at least one bit that is obtained by an operation using data of at least one bit and randomized data of plural bits, said data of at least one bit being included in the data to which seed data for randomization is added; and
write means for writing the randomized data of one bit on a recording medium, wherein
a different value is used for said seed data every time a rewriting process is performed, and a part of said seed data includes at lest a part of the number of writing processes performed on an area of the recording medium on which said randomized data of one bit is written.

5. The recording and reproducing apparatus according to claim 4, further comprising,
means which does not perform the writing process on the area of said recording medium where said number of writing processes reaches a certain value, and which writes the data to be written on the area of said recording medium where said number of writing processes reached the certain value, on an alternative area of said recording medium.

6. The recording and reproducing apparatus according to claim 5, further comprising,
means for storing the number of writing processes performed on a writing area basis on a memory of said recording and reproducing apparatus, and counting up the number of writing processes stored on said memory every time the writing process is performed.

7. The recording and reproducing apparatus according to claim 6, further comprising,
means for writing said number of writing processes performed on a recording area for the number of rewriting processes that is provided at the innermost circumference of the recording medium when the apparatus is turned off or the recording medium is exchanged for another.

8. A recording medium, on which:
seed data used for randomization is added to data;
randomized data of at least one bit is determined by an operation using data of at least one bit and randomized data of plural bits, said data of at least one bit being included in the data to which the seed data is added; and
said randomized data is stored every time the rewriting process is performed, wherein
a part of said seed data includes at least a part of the number of writing processes performed on an area of the recording medium on which said randomized data of one bit is written, and the area for storing the number of writing processes is secured.

9. A recording medium, on which:
seed data used for randomization is added to data;
randomized data of at least one bit is determined by an operation using data of at least one bit and randomized data of plural bits, said data of at least one bit being included in the data to which the seed data is added; and
said randomized data being determined by an operation using the different value seed is stored every time the rewriting process is performed, wherein
an area of information for indicating that said randomized data of one bit is written.

10. A reproducing apparatus for adding seed data used for randomization to data;
determining randomized data of sat least one bit that is obtained by an operation using data of at least one bit and randomized data of plural bits, said data of at least one bit being included in the data to which the seed data is added; and
reproducing said data from a recording medium on which said randomized data is stored, which is randomized by using a different seed data every time are writing process is performed, said apparatus comprising:
operation means for computing derandomization data of one bit by an operation using the randomized data of plural bits; and
read means for reading information for indicating whether or not said randomized data of one bit is written, said information being stored on said recording medium, wherein
the randomization is released using said operation means in the case where the information indicates that said randomized data of one bit is written.

11. A reproducing apparatus for adding seed data used for randomization to data;
determining randomized data of at least one bit that is obtained by an operation using data of at least one bit and randomized data of plural bits, said data of at least one bit being included in the data to which the seed data is added; and
reproducing said data from a recording medium on which said randomized data is stored, which is randomized using a different seed data every time a rewriting process is performed, said apparatus comprising:
operation means for computing derandomization data of one bit by an operation using the randomized data of plural bits, wherein:
said data includes at least an ID and user data;
there is provided determination means for reproducing data without using said operation means and determining whether or not the ID of the reproduced data is the desired ID to be read;
when the ID of the reproduced data is the desired ID to be read, the data is reproduced as it is; and
when the ID of the reproduced data is not the desired ID to be read, the data is reproduced by using said operation means.

12. A reproducing apparatus for adding seed data used for randomization to data;
determining randomized data of at least one bit that is obtained by an operation using data of at least one bit and randomized data of plural bits, said data of at least one bit being included in the data to which the seed data is added; and
reproducing said data from a recording medium on which said randomized data is stored, which is randomized by using a different seed data very time a rewriting process is performed, said apparatus comprising:
operation means for computing derandomization data of one bit by an operation using the randomized data of plural bits, wherein:
said data includes at least user data and an error detecting code:
there is provided error detecting means for reproducing data without using said operation means and detecting an error of the reproduced data by using the error detecting code;
when the error is not detected, the data is reproduced as it is; and
when the error is detected, the data is reproduced by using said operation means.

13. A data randomizing method, comprising the steps of:
adding seed data used for randomization to data;
determining randomized data of at least one bit that is obtained by an operation using data of at lest one bit and randomized data of plural bits, said data of at least one bit being included in the data to which the seed data is added, and writing the randomized data of one bit on a recording medium; and
using a different value for said seed data every time a rewriting process is performed, wherein:
said data is error detecting coded while separating an EDC unit for storing at least user data and a BIS unit for storing at least an address; and
said seed data is stored on said BIS unit.

14. A data randomizing method, comprising the steps of:
adding seed data used for randomization to data;
determining randomized data of at least one bit that is obtained by an operation using data of at least one bit and randomized data of plural bits, said data of at least one bit being included in the data to which the seed data is added, and writing the randomized data of one bit on a recording medium; and
using a different value for said seed data every time a rewriting process is performed, wherein
plural pieces of seed data are prepared with respect to one writing process, and a run length limit code having a most preferable characteristic is selected among plural pieces of run length limit coded data into which plural pieces of randomized data with the plural pieces of seed data added are converted.

15. A semiconductor circuit, comprising:
an input interface circuit for inputting data;
a seed generator;
a scramble circuit for determining randomized data of at least one bit for randomization by an operation using data of at least one bit and randomized data of plural bits, said data of at least one bit being included in the data to which the seed data generated by the seed generator is added; and
an output interface circuit for outputting the randomized data, wherein
ID being input from the input interface circuit is output to the output interface circuit as it is, user data is subject to said randomization, and the randomized user data except the first byte is output from the output interface circuit.

16. A semiconductor circuit, comprising:
an input interface circuit for inputting data;
a descramble circuit for computing derandomization data of one bit by an operation using randomized data of plural bits; and
an output interface circuit for outputting the derandomized data, wherein
said descramble circuit performs derandomization by adding data given from a microcomputer for controlling the semiconductor circuit to said data.

17. A semiconductor circuit, comprising:
a decoding circuit for inputting run length limit coded data and decoding the run length limit coded data;
a seed generator;
a scramble circuit for determining randomized data of at least one bit for randomization by an operation using data of at least one bit and the randomized data of plural bits, said data of at least one bit being included in the data which is decoded by said decoding circuit and to which the seed data generated by the seed generator is added; and
an encoding circuit for converting the randomized data into the length limit coded data for output.

18. A semiconductor circuit, comprising:
a decoding circuit for inputting run length limit coded data and decoding the run length limit coded data to decode randomized data;
a descramble circuit for computing derandomization data of one bit that is obtained by an operation using randomized data of plural bits, and deleting a seed which is added to the top of the data; and
an output interface circuit for outputting the derandomized data generated by the descramble circuit.

19. The recording and reproducing apparatus according to claim 2, further comprising:
file management information generating means for generating a first file management information to be written without scrambling and a second file management information to be written by scrambling;
write means for simultaneously updating said first file management information and said second file management information at the time of writing data;
read means for reading data using only said first file management information at the time of reading data, and reading the file management information from the second file management information when an error occurs in the first file management information; and
file-management-information storing area generating means for generating a storing area for the first file management information in an area different from the area where said first file management information is stored.

20. A recording medium according to claim 9 wherein:
said recording medium is an optical disk, and said optical disk has n recording layers;
a value for indicating that said randomized data is written in said information area is written on the layer nearest to the reflective layer using metal of the n layers; and
a value for indicating that said unrandomized data is written on the other layers of the n layers.

21. The recording and reproducing apparatus according to claim 2, further comprising:
a central processing device for controlling the whole recording and reproducing apparatus;
a storing device for temporarily storing data to be written; and
a error-correcting encoding/decoding circuit, wherein
said central processing device reads the data to be written which is stored in said storing device, generates the seed data, and stores the data randomized by said operation unit in an area different from the area where said data is stored in said storing device.
